(19) United States
(12) Patent Application Publication
(10) Pub. No.: US 2003/0214326 A1
(43) Pub. Date: Nov. 20, 2003

(54) Distributed dynamically optimizable processing communications and storage system

(76) Inventor: Stephen G. Craimer, Jerusalem (IL)

Correspondence Address: JOHN ALEXANDER GALBREATH, 2516 CHESTNUT WOODS CT, REISTERSTOWN, MD, 21136, US

(21) Appl. No.: 10/365,139

(22) Filed: Feb. 11, 2003

Related U.S. Application Data
(60) Provisional application No. 60/354,941, filed on Feb. 11, 2002.

(51) Int. Cl. H03K 19/00

(52) U.S. Cl. 326/101

(57) ABSTRACT

A distributed dynamically optimizable processing, communications, and storage system (DD0PCASS), and the system includes: (A) a queue based processing and communications hardware environment, said environment maintaining, in a large address space, (first) at least three general purpose logical queues, and (second) an at least minimum connective communications topology distributed there-between; and (B) substantially-hierarchically above said queue based processing and communications hardware environment, another processing and communications hardware environment having (first) an input/process/output capability, and (second) data-communications linked to the queue based processing and communications hardware environment, and (third) a resource tracker operating task-specifically.

This application claims priority to provisional U.S. Application Ser. No. 60/354,941, filed Feb. 11, 2002—which was likewise titled “Distributed dynamically optimizable processing communications and storage system”.

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### FIELD OF THE INVENTION

The present invention generally relates to electronic computing systems. More particularly, the present inventions especially relates to electronic computing systems, per se, having about at least 100,000 logic gates—or equivalent; and to “systems” for the design of same.

### BACKGROUND OF THE INVENTION

There is an ongoing need to be able to design and develop high complexity devices and networks of devices (large-scale digital electronic systems) in order to enable improvement in human productivity—the original, real-time, or occasional users of those devices. Furthermore, there is an ongoing need to enable migration and integration of current software and/or hardware driven solutions—and specifically, to provide a platform for advanced (often higher complexity) applications. Therefore, any improvement providing advancement over the existing state and in the direction of this ongoing need is beneficial, particularly if it could lower the design costs.

Looking deeper into the matter, there is a longstanding problem to build large-scale digital electronic systems; for example, routers, printers, personal computers, game systems, simulators, mainframe computers, super-computers, and the likes. While, for the designer, the problem focuses on best management of resources, from a corporate perspective, the cost efficiency of designing large systems has been slow-to-improve, even while simultaneously great improvements have been forthcoming in the manufacture of designed and tested systems. Simply stated, without substantially degrading the quality of design efforts, goals, and results, there is a need for a system that will facilitate lower cost and complexity for the design process. Notwithstanding all of the aforesaid, a resultant design that improves throughput and/or appurtenance resource utilization would likewise constitute progress in the related arts.

### BRIEF SUMMARY OF THE INVENTION

Substantially, in compliance with the need for progress according to the aforementioned needs, the instant invention generally relates a distributed dynamically optimizable processing, communications, and storage system (DDOPCASS) wherein a preponderance of data processing operations/functions are occurring in respective queues of a generally large plurality of queues (rather than in traditional typical stacks); the DDOPCASS being a general-purpose computer-type system usable for small, medium, large, and very large-scale applications—and preferably having therein a value management method for preserving intellectual property rights. It is the perspective of the inventor that the preferred use of the instant systems considers (1) software developers as value producers and (2) software users as value consumers and (3) the instant system as a facile mechanism for the economic management of complex, often interdependent interests therein, e.g. downloading and uploading of software, documents, music, mixed media, control signals, etc. Nevertheless, this appreciation of the economic management potential of the instant invention is a preferred use of the instant invention, while the basic generic invention, per se, relates to embodiments that are potentially somewhat insensitive to abuses of intellectual property rights.

Conceptually, wherein an embodiment of DDOPCASS, per se, is an evolving state space of a global queue, nevertheless each “processor inclusive” in that space sees (relates to) the global data space as a function of that processor's respective physical, infrastructure, and logical communications distances—and the space is preferably managed accordingly with de-facto collision resolution handling in the improbable event of collision occurrences between state spaces of local processor queue “clusters”.

Furthermore, generally the instant invention is primarily using queue-based processors, rather than typical stack-architecture-oriented general-purpose sequential processors or special-purpose parallel processors or combinations thereof. In the instant invention, in order to maintain the stability of operation of the DDOPCASS, one must insure that virtually all resources are adequately tracked using a consistent set of rules. In order to dynamically implement a DDOPCASS performance rule set, one should have an accurate evaluation function. The best currently enabled rules for DDOPCASS will be described in detail in the Detailed Description section in conjunction with the figures and the CD-ROM Appendix materials.

Now, specifically, the instant invention relates to embodiments of a distributed dynamically optimizable processing, communications, and storage system (DDOPCASS), (see FIG. 1)—substantially useful anywhere that software, digital hardware, or imbedded systems are presently used—in that DDOPCASS typically contributes to lowering the cost of developing products for software, digital hardware, or imbedded systems and also typically contributed to a more cost-effective use of resources, peripherals, and related appurtenances.

Preferred embodiments of the DDOPCASS system include:

(A) a queue (“Qu”) based processing and communications hardware environment (110), capable of emulating sequential and parallel processing, said environment maintaining, in a large address space,

(first) at least three general purpose logical queues wherein the at least three general purpose logical queues are special purpose allocated to be (i) at least one input-storage queue and (ii) at least one processing queue having therein at least one processing element and (iii) at least one output-storage queue, and

(second) an at least minimum connective communications topology distributed there-between, whereby each of the queues has at least one interconnection to at least one of the other queues and the communications topology is capable of interface with communications topologies of at least one input device and of at least one output device; and

(B) substantially-hierarchically above said queue based processing and communications hardware environment, another processing and communications hardware environment (100) having

(first) an input/process/output capability, and

(second) data-communications linked to the queue based processing and communications hardware environment, and

(third) a resource tracker operating task-specifically,

(i) said resource tracker operating being substantially in compliance with an accessible current set of user contracts,

wherein the current user contracts specify virtual payment requirements for each use of a respective subset of allocated resources, and

wherein said resources are in the queue based processing and communications hardware environment, and therein said resources are selected from the list: queues, devices, interconnections, interfaces, functional clusters of the aforesaid, and administrative clusters of the aforesaid, and

(ii) said resource tracker coordinating queue-to-queue communications interconnections and queue-with-device interfaces over the topology by allocation from the current potential set of users to a substantially current set of resources—in accordance with respective resource availability and current user respective contract states.

According to a variation of the distributed dynamically optimizable processing, communications, and storage system, substantially each of the queues is a range of logically substantially-contiguous addresses in address space of the environment.

According to another variation of the distributed dynamically optimizable processing, communications, and storage system, substantially each of the queues has at least three possible states:

(i) at least one state of the three possible states being selected from the list: undefined (UDF), allocated for later use (BSY), and initialized/write-only (INI);

(ii) another state of the three possible states being read/modify/write (MTR); and

(iii) a further at least one state of the three possible states being selected from the list: read-only (FIX), and cancel (CAN).

According to a further variation of the distributed dynamically optimizable processing, communications, and storage system, said another processing and communications hardware environment is substantially a queue based processing and communications hardware environment. On the one hand this allows DDOPCASS to implement recursively according to the reality of the order of magnitude of its processors (Queues) and on the other hand notes that classical or alternative electronic computation architectures may be used to actualize DDOPCASS management functions.

According to yet another variation of the distributed dynamically optimizable processing, communications, and storage system, the processing element is an arithmetic logic unit. Nevertheless, other style digital and even peculiar analog transformation elements are conceptually useful here too.

According to an additional variation of the distributed dynamically optimizable processing, communications, and storage system, a preponderance of the interconnections in the communications topology are encrypted. This variation, in conjunction with the address space that is generally sparse and predominantly virtual, helps to insure the robustness of DDOPCASS security.

According to another additional variation of the distributed dynamically optimizable processing, communications, and storage system, allocated resources are substantially proximate to their respective queue. This variation in generally concerned with communications lag and latency times—but also relates to cases where there is an appreciable difference in use of remote resources—such as the difference between trying to print out the encyclopedia on a nearby table top printer versus using a for-contract commercial printing service, etc.

The instant invention also relates to embodiments of a queue (Qu) based processing and communications hardware environment appurtenance (see FIG. 2), in compliance with the abovementioned embodiments and variations, the appurtenance comprising at least one functional cluster (200) of resources, and said resources include: at least three general purpose logical queues wherein the at least three general purpose logical queues are special purpose allocated to be (i) at least one input-storage queue and (ii) at least one processing queue having therein at least one processing element and (iii) at least one output-storage queue; and interconnections therebetween; and at least one device (210) interface thereto. Generally, an appurtenance is an embedded system driven device (or interfaced collection of same) such as (in the area of computer peripherals) a printer, scanner, modem, data storage device, or the likes. Nevertheless, the instant appearances truly relate to any device having an embedded DDOPCASS compatible processor—such as a HVAC controller, or a diesel locomotive, or a communications satellite, or a microwave oven, or a personal communications device, or a hand held video-style game machine, or the likes—to list but a paltry few.

The instant invention furthermore relates to embodiments of an article (300) of manufacture (see FIG. 3) including a computer usable medium having computer readable program code embodied therein for coordinating operations between a plurality of queue (Qu) based processing and communications hardware modules including therein at least one minimum connective communications topology distributed there-between and therewith at least one module operating task-specifically as a resource tracker.

The instant invention in addition relates to embodiments of a program storage device (400) (see FIG. 4) readable by a machine, tangibly embodying a program of instructions executable by the machine to perform, in a distributed dynamically optimizable processing, communications, and storage system, method steps for task-specific resource tracking by coordinating queue-to-queue communications interfaces over a topology by allocation, according to resource availability and current user respective contract states, from a current potential set of users to the resources—according to the current user contracts requiring virtual payment for use of a respective subset of allocated resources, and the steps include, in a large queue processing machine wherein substantially each of the queues therein has at least three possible states, at least one step corresponding to: (i) at least one state of the three possible states being selected from the list: undefined (UDF), allocated for later use (BSY), initialized/write-only (INI), (ii) another state of the three possible states being read/modify/write (MTR), and (iii) a further at least one state of the three possible states being selected from the list: read-only (FIX), and cancel (CAN).

Now, the instant invention substantially also relates to embodiments of a program storage device (500) (see FIG. 5) readable by a machine, tangibly embodying a program of instructions executable by the machine to perform, in a distributed dynamically optimizable processing, communications, and storage system, said method steps including collectively at least ten operation-functions (or the likes—such as reduced instruction set emulations of same) selected from at least one of the lists:

A Qu Location States operation-function selected from the list:

(UDF) undefined for an indefinite period,

(BSY) inaccesible for a specific period,

(INI) iniitialised to a default value, and may be written but not read,

(MTR) readable and writeable,

(FIX) only readable,

(CAN) undefined indefinitely;

A Qu Bounds Groups Qu Locations Before After operation-function selected from the list:

(BOA) Beggining Of Allocation start of region of Qu mapped to physical Memory UDF UDF/BSY,

(EOA) End Of Allocation end of region of Qu mapped to physical Memory FIX/CAN CAN,

(BOW) Beggining Of Write BSY INI,

(EOW) End Of Write MTR FIX,

(BOR) Beggining Of Read BSY/INI MTR,

(EOR) End Of Read FIX CAN;

A Qu Miscellaneous operation-function selected from the list:

(SIQ) Mechanism to provide the advantages of a stack and a Qu.,

(BOQ) default location of primary source of data for Qu processor,

(FOQ) default alternate source primary Destination of data for Qu processor,

(CHQ) encrypted access token for service or resource under specific contract;

A Communications operation-function selected from the list:

(AoI) new ATM over IP implementation of ATM over UDP/IP to implement circuits;

A Control operation-function selected from the list:

Drone basic deployable unit with TOL,

Drone basic deployable unit with JAG,

Drone basic deployable unit with CPA,

Drone basic deployable unit with COO,

(ver) version direct user initiated change event,

(rev) mechanically (often timed) initiated change event,

(IOU) Indebt On Use payment expected only for use,

(TOL) The Owner Link Direct connection to the owner of the unit,

(JAG) Drone Module responsible for permissions,

(CPA) CHQ Processing Arbiter Module responsible for operation finance,

(COO) Module responsible for organization and optimization,

(JOB) General Application module in a drone,

(TSK) General Application module in a drone;

An Implementation operation-function selected from the list:

(add) addition of 2 or more itms such as either nbr or nbr and ref, includes handling for item typically selected from the list: udf, inf, eps;

(by) list vector operator,

(mpy) multiplication of 2 or more itms such as either nbr or nbr and ref, includes handling for item typically selected from the list: udf, inf, eps;

(in) default input sub-context,

(out) default output sub-context,

(and) bit wise and of 2 or more itms such as either nbr or nbr and ref, includes handling for item typically selected from the list: udf, inf, eps, scaled;

(or) bit wise or of 2 or more itms such as either nbr or nbr and ref, includes handling for item typically selected from the list: udf, inf, eps, scaled;

(xor) bit wise exclusive or of 2 or more itms such as either nbr or nbr and ref, includes handling for item typically selected from the list: udf, inf, eps, scaled;

(run) the next position in a sequence,

(axn) default action upon entering a context,

(cxu) C execution Unit Implementation of a Qu processing unit configured to execute C derived code,

(sxu) Sequence execution Unit Implementation of a Qu processing unit configured to execute typical sequences,

(“@” alternately “at.”) synchronization in time and time shift alignment,

(iff) if and only if execute only while conditions persists,

(run) next sequence;

A Types operation-function selected from the list:

(itm) universal data type,

(tag) the code for the type of an itm or derived type,

(ixx) Integer type derived from itm where xx=24, 25, 26, 28, 32, 40, 48, 56, 64, 80;

(lbl) label in a sequence,

(vip) very important point co-ordination point for multiple sequences,

(bct) binary coded thousands number format which represents values as groups of 10 bits,

(nbr) derived from itm specifically for arithmetic type operations,

(rel) Operation which produces a relational type of same name comparing two ranges,

(rng) start and size type,

(lst) list of ranges and references,

(cde) context dependent data type which uses position and value to produce usable result,

(fmt) a collection of variables in a specific format,

(seq) a set of operations executed in sequence,

(ctx) an execution context,

(typ) the type of an itm,

(ref) a reference to a variable or value,

(irf) an indirect reference which is transparent,

A “values”—special values operation-function selected from the list:

(inf) infinity a value which behaves like infinity, always greater than the maximum value,

(eps) epsilon a value which behaves like epsilon, always less than the minimum representable value,

(udf) undefined an undefined value,

(can) canceled an inaccessible value,

(abs) absolute the practically infinite address space of DDOPCASS,

(std) standard the default value after a change,

(ini) initial the default value never written,

(bsy) busy value which will be valid soon;

A memstates operation-function selected from the list:

(ABA) Action Before Access Occurs before obtaining the address of a location prior to AOR,

(AOA) Action On Access provides at least the address of a location prior to AAA and ABR or ABW,

(AAA) Action After Access side effect of requesting address,

(ABR) Action Before Read Occurs before getting the value of a location prior to AOR,

(AOR) Action On Read provides at least a value for a location prior to AAR,

(AAR) Action After Read side effect of read,

(ABW) Action Before Write Occurs before setting the value of a location prior to AOW,

(AOW) Action On Write intended to update the value for a location prior to AAW,

(AAW) Action After Write side effect of write,

(AOX) Action On eXception Invitation to retry access after failure,

(AOT) Action On TimeOut complete failure of access,

A Miscallaneous operation-function selected from the list:

(SIDE) Serial IDE simple low code modification of standard IDE/ATA to use fewer wires and increase functionality,

(IDES) IDE Serial inverse of SIDE,

(Cache) DRAM Memory Cell of n bits DRAM and 1 bit SRAM which is refreshed under external control (typically JAG)—Disk Access Optimized Repeated Writing to reduce rotational latency; and

A Security operation-function selected from the list:

(TXP) Terminate eXtreme Prejudice Unit designated as harmful, to be destroyed,

(CAP) Cease All Processing Unit must freeze,

(DevCon1) Defence Condition 1 Units must identify and CAP, TXP may follow,

(DevCon2) Defence Condition 2 Units must identify, TXP on Warning,

(DevCon3) Defence Condition 3 Units must identify, CAP on Warning else TXP,

(DevCon4) Defence Condition 4 Units must identify, possible TXP/CAP on recognition,

(DevCOn5) Defence Condition 5 Units must identify, possible CAP on recognition.

Furthermore, according to preferred variations of any of the aforementioned program storage devices, the device temporarily resides on a carrier signal (such as is typical in wired and wireless downloading and uploading) and the signal is located on a media selected from the list:

(a) a connective communications topology distributed between a plurality of queues of a distributed dynamically optimizable processing, communications, and storage system;

(b) an interface with a communications topology of an input device;

(c) an interface with a communications topology of an output device; and

(d) a subset of any of the aforesaid.

For convenience, the aforesaid summary details generally refer to communications topology to mean electronic interconnections between hardware components—including physical connections such as solder joints, plugs & sockets, common busses and the likes, and to virtual connections such as radio links by mutually compatible antennas, protocols, gateways, combinations of these, and the likes. These and other features of the instant invention will be discussed in greater detail in the sections that follow, the related figures, and the CD-ROM Appendix. It is pragmatic for the reader to review the current section inclusive of its figures and the Brief Description Of The Drawing with the figures related to therein—before proceeding to the Detailed Description Of The Invention section and the design instruction guides of the Appendix.

### BRIEF DESCRIPTION OF THE DRAWINGS

A more complete understanding of the present invention and the advantages thereof may be acquired by referring to the following description in consideration of the accompanying drawings, in which like reference numbers indicate like features and wherein:

FIGS. 1-5 relate to principle DDOPCASS embodiments, wherein

FIG. 1 shows a schematic view of a DDOPCASS;

FIG. 2 shows a schematic view of a DDOPCASS appurtenance;

FIG. 3 shows a schematic view of a DDOPCASS related article of manufacture;

FIG. 4 shows a schematic view of a DDOPCASS related program storage device; and

FIG. 5 shows a schematic view of another DDOPCASS related program storage device;

FIGS. 6-8 relate to slides illustrating the reasons driving the creation of DDOPCAS/TMX architecture;

FIGS. 9 to 15 relate to slides defining the initial best application of TMX Architecture, wherein:

FIG. 16 to 37 relate to slides of an overview of the logical architecture.

FIGS. 38 to 55 Relate to an implementation of the architecture most closely realted to classical systems.

FIGS. 56 to 60 relate to typical Complex systems and Appendix 1 is a CD-ROM having recorded thereon the following files:

In the HTML directory are more explanations of typical implementations using DDOPCAS/TmX principals. Because of the system nature of the system it is far beyond of the scope of this patent to present any particular path of implementation.

Directory of html\Users\worknew\Specification_Zest\General Logs

The progress logs for 2002. Gives details of development progression

| | |
|---|---|
| 03/18/02 12:13a | 52,581 B02Log02Jan5th.html |
| 04/21/02 06.40p | 40,253 B03Log02Mar5th.html |
| 05/05/02 2:43p | 61,493 B04Log02Apr7th.html |
| 06/16/02 09:01a | 66,216 B05Log02May5th.html |
| 08/18/02 02:36p | 60,208 B06Log02Junel6th.html |
| 09/18/02 06:57p | 36,790 B07Log02Aug16th.html |
| 12/15/02 10:06a | 82,849 B08Log02Augl4th.html |
| 02/07/03 01.28a | 28,619 B09Log02Dec15th.html |

Directory of html\Users\worknew\Specification_Zest\Iterations\Iteration2\Specifications

The descriptions of types and components

| | | |
|---|---|---|
| 04/10/02 12:41p | 11,740 | BasicTypes.html |
| 03/06/02 04:10p | 16,504 | CEOcode_CSL.html |
| 02/10/02 10:52a | 10,174 | CodeGenerator1.html |
| 03/20/02 09:40p | 3,709 | CodeGeneratorImplementation.html |
| 05/03/02 07:40p | 33,087 | CXU_top.html |
| 05/02/02 05:34p | 4,373 | CXU_top_info.html |
| 05/03/02 07:39p | 31,917 | DualCXU_Unit.html |
| 04/29/02 01:27p | 7,079 | DualCXU_Unit_Info.html |
| 06/07/02 04:28p | 4,417 | Overview Of TmX Public Service System.html |
| 03/10/02 02:07a | 1,579 | ReferemceIndex.html |
| 05/06/02 07:21p | 36,499 | SIDE_CXU.html |
| 04/29/02 03:02a | 6,394 | SIDE_CXU_info.html |
| 07/10/02 08:27p | 2,691 | TmXonHigh.html |

Directory of html\Users\worknew\Specification_Zest\Iterations\Iteration2\Specifications\CQL_spec

| | |
|---|---|
| 05/31/02 07:52p | 24,399 BaiscBootSystem.html |
| 05/10/02 09:41a | 13,180 Keywords and operators.html |

Directory of html\Users\worknew\Specification_Zest\Iterations\Iteration2\Specifications\The TmX Road Show

| | |
|---|---|
| 07/11/02 08:21p | 6,228 Data_Type_Overview.html |

Directory of html\Users\worknew\Specification_Zest\Iterations\Iteration2\Specifications\TheFirstSystem

| | |
|---|---|
| 02/10/03 06:06p | <DIR> . |
| 02/10/03 06:06p | <DIR> .. |
| 06/12/02 10:39a | 17,727 Basic Types.html |
| i. 3 File(s) | 17,727 bytes |

Directory of html\Users\worknew\Specification_Zest\Iterations\Iteration3\Specifications

| | |
|---|---|
| 12/17/02 09:58p | 17,558 Note_On_Builder_Projects2.html |

Qopl—the assembly equivalent laguage

| | |
|---|---|
| 11/29/02 12:01a | 27,157 QopL_Specifications_Notes1.html |
| 11/22/02 03:19p | 3,724 TmXProgMan1.html |

Directory of html\Users\worknew\Specification_Zest\Iterations\Iteration3\Specifications\QuOpLanguage

| | |
|---|---|
| 11/21/02 12:41a | 48,954 bobs_reply1.htm |
| 11/21/02 11:59p | 70,386 bobs_reply2.htm |
| 12/27/02 12:53p | 65,972 ProgRef_-_TmX_Data_types.html |
| 11/29/02 12:03a | 6,978 Qopl_HTML_Parserl.html |
| 11/15/02 01:12p | 25,623 Qopl_SGC_to_Bob_1_confidential_TmX.html |

Directory of html\Users\worknew\Specification_Zest\Iterations\Iteration3\Specifications\SXU_Hardware

| | |
|---|---|
| 12/02/02 08:27p | 4,622 SXU_Implementation_Details1.html |

Directory of html\Users\worknew\Specification_Zest\Iterations\Iteration3\Specifications\TmX Overview

| | |
|---|---|
| 12/13/02 05:52p | 9,293 TmX_Overview_Notes_Basics.html |
| 11/01/02 05:57p | 4,022 Trade_Force_Components.html |

Directory of html\Users\worknew\Specification_Zest\Iterations\patent_print_html\Users

02/10/03 06:06p <DIR> Specification_Zest

02/10/03 06:06p <DIR> TeamWork

Directory of html\Users\worknew\Specification_Zest\Iterations\patent_print_html\Users\worknew\Specification_Zest

Directory of html\Users\worknew\Specification_Zest\Iterations\patent_print_html\Users\worknew\Specification_Zest\General Logs

| | | |
|---|---|---|
| 12/02/01 | 09:47a | 37,469 B00Log01Nov6th.html |
| 01/04/02 | 05:17a | 44,089 B01Log01Dec2nd.html |
| 02/08/02 | 05:07a | 51,714 B02Log02Jan5th.html |
| 09/25/01 | 11:16p | 9,747 Log Aug 28th.html |
| 09/25/01 | 11:20p | 73,459 Log Aug 6th.html |
| 12/21/00 | 05:47a | 6,093 Log Dec 20th bad.html |
| 03/12/01 | 09:26a | 49,976 Log Dec 20th.html |
| 12/26/00 | 06:51a | 27,010 Log Dec 20thx.html |
| 01/01/01 | 05:22p | 31,366 Log Dec 9th.html |
| 12/11/00 | 11:11p | 3,681 Log Dec 9thOld.html |
| 02/28/01 | 08:09p | 24,451 Log Feb 18th.html |
| 03/04/01 | 10:50a | 16,327 Log Feb 25th.html |
| 03/04/01 | 11:07a | 20,142 Log Feb 4th.html |
| 01/22/01 | 04:29p | 11,518 Log Jan 14th.html |
| 01/08/01 | 01:45a | 32,313 Log Jan 1st.html |
| 01/28/01 | 03:10p | 19,950 Log Jan 22nd.html |
| 03/04/01 | 11:09a | 18,176 Log Jan 28th.html |
| 01/15/01 | 01:04a | 20,342 Log Jan 7th.html |
| 08/06/01 | 06:10p | 33,192 Log Jul 23rd.html |
| 08/06/01 | 06:11p | 4,893 Log Jul 8th.html |
| 07/18/01 | 12:35p | 4,377 LogJul 8th 0.html |
| 07/09/01 | 03:34p | 35,588 Log Jun 5th.html |
| 03/25/01 | 01:13p | 19,585 Log Mar 11th.html |
| 03/25/01 | 01:25p | 1,280 Log Mar 15th.html |
| 03/28/01 | 11:31a | 1,502 Log Mar 18th.html |
| 04/26/01 | 02:03p | 12,816 Log Mar 25th.html |
| 03/11/01 | 02:36p | 12,421 LogMar4th.html |
| 05/24/01 | 11:38p | 19,248 Log May 06th.html |
| 06/08/01 | 09:41a | 5,458 Log May 20th.html |
| 01/01/01 | 05:58p | 23,314 Log Nov 25th.html |
| 01/01/01 | 12:59p | 5,176 Log Nov 2nd.html |
| 01/01/01 | 06:15p | 20,186 Log Nov 6th.html |
| 12/02/01 | 08:44a | 39,481 Log Oct 3rd.html |
| 12/02/01 | 08:20a | 73,264 Log Sep 02.html |

Directory of html\Users\worknew\Specification_Zest\Iterations\patent_print_html\Users\worknew\Specification_Zest\Iterations

Directory of html\Users\worknew\Specification_Zest\Iterations\patent_print_html\Users\worknew\Specification_Zest\Iterations\Iteration1

| | | |
|---|---|---|
| 08/17/00 | 05:21p | 2,755 ComController.html |
| 08/12/00 | 11:22p | 17,429 Interface Blocks Description.htm |
| 11/12/00 | 04:25p | 25,129 Specfications And Examples.html |
| 08/15/00 | 01:33a | 6,669 The Basic VMC types.html |

Directory of html\Users\worknew\Specification_Zest\Iterations\patent_print_html\Users\worknew\Specification_Zest\Iterations\Iteration1\CQLCompilerSpecs

CQL an alternate equivalent to assembly laguage

| | | |
|---|---|---|
| 03/18/01 | 03:46p | 23,388 CQL_Version 1 .html |

Directory of html\Users\worknew\Specification_Zest\Iterations\patent_print_html\Users\worknew\Specification_Zest\Iterations\Iteration1\DemoAppSort

| | | |
|---|---|---|
| 04/11/01 | 12:34a | 4,071 ItmMtrEng_c.html |
| 03/28/01 | 11:17a | 8,509 Qcalc1_c.html |
| 03/28/01 | 11:24a | 2,825 Qcalc1_h.html |
| 03/15/01 | 09:25p | 528 Seng2Seq_C.html |
| 03/15/01 | 05:25p | 1,778 test1_c.html |
| 03/30/01 | 02:47a | 5,985 TmX_memory_c.html |
| 04/11/01 | 12:32a | 2,857 TmX_Qu0_c.html |
| 04/04/01 | 03:28p | 4,148 TmX_stdio_c.html |
| 03/28/01 | 11:21a | 3,496 TmX_stdio_h.html |
| 03/28/01 | 12:23p | 13,450 TmX_types_h.html |

Directory of html\Users\worknew\Specification_Zest\Iterations\patent_print_html\Users\worknew\Specification_Zest\Iterations\Iteration1\LCC_related

| | | |
|---|---|---|
| 09/17/00 | 01:10a | 3,121 New86Assembler_and_notes.html |

Directory of html\Users\worknew\Specification_Zest\Iterations\patent_print_html\Users\worknew\Specification_Zest\Iterations\Iteration1\NumberType

| | | |
|---|---|---|
| 11/05/00 | 12:22p | 9,162 Number Types.html |

Directory of html\Users\worknew\Specification_Zest\Iterations\patent_print_html\Users\worknew\Specification_Zest\Iterations\Iteration1\Planning

| | | |
|---|---|---|
| 10/13/00 | 03:50p | 10,117 VGAProject.html |
| 10/15/00 | 12:10p | 9,851 VGAProjectAndMpeg4.html |

Directory of html\Users\worknew\Specification_Zest\Iterations\patent_print_html\Users\worknew\Specification_Zest\Iterations\Iteration1\SegmentAndChipParts

Design and implementation in Verilog HDL of the basic boot element of an early TmX attempt.

| | | |
|---|---|---|
| 10/25/00 | 05:41p | 15,461 L2SRAM Interface.html |
| 10/27/00 | 02:02p | 6,894 LEM_codes.html |
| 09/01/00 | 01:20a | 17,073 Notesl.html |
| 09/01/00 | 12:31a | 14,966 TestNodeNotes.html |

Directory of html\Users\worknew\Specification_Zest\Iterations\patent_print_html\Users\worknew\Specification_Zest\Iterations\Iteration1\SegmentAndChipParts\Verilog

| | | |
|---|---|---|
| 09/21/00 | 12:43p | 916 Version Notes.html |

Directory of html\Users\worknew\Specification_Zest\Iterations\patent_print_html\Users\worknew\Specification_Zest\Iterations\Iteration1\temp

| | | |
|---|---|---|
| 09/08/00 | 12:42p | 625 testbackwmf.html |

Directory of html\Users\worknew\Specification_Zest\Iterations\patent_print_html\Users\worknew\Specification_Zest\Iterations\Iteration1\TmXComponents

| | | |
|---|---|---|
| 11/1/00 | 09:48p | 2,491 TextInABox.html |

Directory of html\Users\worknew\Specification_Zest\Iterations\patent_print_html\Users\worknew\Specification_Zest\Iterations\Iteration1\VidComponent

Test vector generator for first video based unit of TmX

| | | |
|---|---|---|
| 09/8/00 | 06:09p | 943 SeqGenerator.html |

Directory of html\Users\worknew\Specification_Zest\Iterations\patent_print_html\Users\worknew\Specification_Zest\Iterations\Iteration1\WhitePapers

VMC the earliest Assembhler equivalent.

| | | |
|---|---|---|
| 11/7/00 | 12:45a | 8,060 Data Types.html |
| 11/12/00 | 04:24p | 11,041 The basic parts of TmX.html |
| 08/15/00 | 02:56p | 20,190 VMC_root A tutorial.html |

Directory of html\Users\worknew\Specification_Zest\Iterations\patent_print_html\Users\worknew\Specification_Zest\Iterations\Iteration2\CXU

| | | |
|---|---|---|
| 11/5/01 | 01:03p | 17,933 CXU_TheoryOfOperation.html |
| 11/13/01 | 06:43a | 19,737 rcd1.html |
| 12/14/01 | 08:39a | 10,319 ServerDroid_Overview.html |
| 12/17/01 | 01:53p | 1,565 ServerDroid_TofOP.html |
| 12/27/01 | 02:22p | 12,889 SystemExplanationLiterate1.html |
| 11/5/01 | 12:45a | 29,889 tt4.html |

Directory of html\Users\worknew\Specification_Zest\Iterations\patent_print_html\Users\worknew\Specification_Zest\Iterations\Iteration2\Examples

02/10/03 06:06p <DIR> Demo1

Directory of html\Users\worknew\Specification_Zest\Iterations\patent_print_html\Users\worknew\Specification_Zest\Iterations\Iteration2\Examples\Demo1

| | | |
|---|---|---|
| 06/18/01 | 10:44a | 7,078 Itm_I_O.html |
| 06/17/01 | 06:17p | 11,602 Output Display.html |
| 06/18/01 | 10:48p | 2,304 Overview.html |

Directory of html\Users\worknew\Specification_Zest\Iterations\patent_print_html\Users\worknew\Specification_Zest\Iterations\Iteration2\HelloWorld

| | | |
|---|---|---|
| 12/18/01 | 05:34a | 2,867 AHelloWorldDrone.html |
| 12/20/01 | 10:54a | 6,869 TmX Drones-An introduction.html |

Directory of html\Users\worknew\Specification_Zest\Iterations\patent_print_html\Users\worknew\Specification_Zest\Iterations\Iteration2\IDESIDE

| | | |
|---|---|---|
| 10/18/01 | 01:49a | 1,740 pge4k_io_wr_c.html |

Directory of html\Users\worknew\Specification_Zest\Iterations\patent_print_html\Users\worknew\Specification_Zest\Iterations\Iteration2\Specifications

| | | | |
|---|---|---|---|
| 01/20/02 | 04:15a | 7,828 | ArchitectureAbstracts.html |
| 01/25/02 | 06:04a | 7,896 | BasicTypes.html |
| 01/18/02 | 05:55a | 16,458 | CEOcode_CSL.html |
| 01/24/02 | 09:44a | 35,934 | CXU Nano Architecture.html |
| 01/28/02 | 07:36a | 18,214 | CXU Nano ArchitecturePatch1Bob. |
| | | | html |
| 11/17/01 | 01:12a | 35,847 | CXU Nano ArchitectureRev1.0.html |
| 06/11/01 | 03:22p | 1,323 | DcdMtrl.html |
| 02/04/02 | 01:17a | 4,548 | Investor System Interface Unit.html |
| 02/04/02 | 01:04a | 5,673 | ModuleTemplates.html |
| 02/07/02 | 02:39p | 7,573 | Notes To CEO's.html |
| 02/04/02 | 09:27a | 72,589 | NotesOnCpp.html |
| 02/07/02 | 08:25p | 2,218 | ObjectTest1.html |
| 06/21/01 | 09:42p | 21,102 | QuBasics.html |
| 06/19/01 | 10:26p | 15,398 | QuBasics_rev0.html |
| 01/24/02 | 10:07a | 43,061 | SIDE_task.html |
| 01/20/02 | 04:27a | 69,831 | Source for link.html |
| 02/04/02 | 12:09a | 1,859 | SpecTemplate.html |
| 01/22/02 | 04:41a | 12,854 | testMacros1.html |
| 01/31/02 | 03:07p | 5,179 | The AMI pitch.html |
| 01/24/02 | 12:11p | 5,723 | TmX Summary.html |

Directory of html\Users\worknew\Specification_Zest\Iterations\patent_print_html\Users\worknew\Specification_Zest\Iterations\Iteration2\TextExperiments

| | | | |
|---|---|---|---|
| 09/24/01 | 10:28p | 40,623 | temp1.html |
| 10/27/01 | 12:52a | 2,058 | TestArrows.html |

Directory of html\Users\worknew\Specification_Zest\Iterations\patent_print_html\Users\worknew\Specification_Zest\Iterations\Iteration2\TmX\itm\FQM

| | | | |
|---|---|---|---|
| 06/08/01 | 04:08p | 3,050 | cmd_dcd_blk.html |
| 05/04/01 | 06:24a | 8,923 | ItmMtr_h.html |
| 05/06/01 | 01:55p | 2,514 | ItmMtr_tst_gtor1_c.html |
| 06/06/01 | 02:07p | 372 | maintable.html |
| 05/07/01 | 12:48p | 2,983 | SeqDcd2_c.html |
| 05/01/01 | 10:17a | 7,239 | split_Itm_c.html |
| 06/05/01 | 04:14p | 20,217 | TestNested.html |
| 05/06/01 | 01:49p | 1,519 | tst_gtor_main1_c.html |

Directory of html\Users\worknew\Specification_Zest\Iterations\patent_print_html\Users\worknew\Specification_Zest\Iterations\Iteration2\TmX\itm\Vlog

| | | |
|---|---|---|
| 06/07/01 08:41p | 20,549 | Seng3_blocks.html |

Directory of html\Users\worknew\Specification_Zest\Iterations\patent_print_html\Users\worknew\Specification_Zest\Welder\Iteration1

| | | |
|---|---|---|
| 10/17/00 12:55a | 18,479 | FunctionalDesign.html |
| 10/18/00 10:48p | 1,759 | LEM-backendNotes.html |
| 11/10/00 02:42p | 13,788 | The Sheet called a plan.html |
| 11/14/00 11:13a | 4,786 | Tutorial In TmX programming.html |
| 10/18/00 12:03p | 9,843 | UI_ImplementationNotes1.html |
| 10/23/00 03:13p | 7,011 | Welders_C.html |
| 10/23/00 03:13p | 1,227 | WelderTOC.html |
| 10/18/00 10:44p | 534 | Welder_Test&Experiments.html |

Directory of html\Users\worknew\Specification_Zest\Iterations\patent_print_html\Users\worknew\TeamWork\Banker

Directory of html\Users\worknew\Specification_Zest\Iterations\patent_print_html\Users\worknew\TeamWork\Banker\Stephen

| | | |
|---|---|---|
| 12/29/01 01:43a | 5,780 | Notes On Banker.html |

Directory of html\Users\worknew\Specification_Zest\Iterations\patent_print_html\Users\worknew\TeamWork\LiteratePrograming

| | | |
|---|---|---|
| 01/11/02 05:26a | 68,544 | Source for link.html |

In the WMF directory are auxiliary diagrams in the Windows metafile fornmat which can be viewed in any windows office application, and almost all graphic display programs.

wmf

Diagrams to assist understanding the system

Compatible with office and most windows applications.

.wmf is windows metafiles

.emf is enhanced windows metafiles

| | | |
|---|---|---|
| 02/10/03 11:52a | 5,744 | ATM Circuits.wmf |
| 02/10/03 11:52a | 4,100 | ATM_on_UDP_messagting1.wmf |
| 02/10/03 11:53a | 11,578 | Banker.wmf |
| 02/10/03 11:47a | 5,594 | DroidActors.wmf |
| 02/10/03 11:47a | 1,932 | Droid_AOU.wmf |
| 02/10/03 11:48a | 3,300 | DroneTemplate1.wmf |
| 02/10/03 11:48a | 3,978 | FileSystemStructure.wmf |
| 02/10/03 11:49a | 3,636 | HelloWorldDrone.wmf |
| 02/10/03 11:51a | 5,754 | Implementation Details Stage 1.wmf |
| 02/10/03 11:49a | 5,910 | mtr_rx_tx1.wmf |
| 02/10/03 11:50a | 5,556 | NanoProcessor.wmf |
| 02/10/03 11:51a | 3,090 | TmXGo.wmf |
| 02/10/03 01:41p | 23,716 | uniplex.emf |
| 02/10/03 11:46a | 7,940 | UseDiagram.wmf |

In The Source Directory

The following files types are used

.C—is a c source file

.v—is a verilog source file

.cpp—is a C++ builder source file version 3

.h are C or C++ include files

.awk are awk source files processable by gnu awk.

Directory of source\Users\worknew\CbuilderWork

These are related to the debug support tools

| | | |
|---|---|---|
| 11/08/99 10:31p | 655 | DemoStep_prj.cpp |
| 11/08/99 10:31p | 761 | LinkedImage_prj.cpp |
| 11/08/99 10:31p | 13,504 | linked_image_UI.cpp |
| 11/08/99 10:31p | 3,842 | linked_image_UI.h |
| 11/08/99 10:31p | 1,823 | Load_SaveUI.cpp |
| 11/08/99 10:31p | 1,138 | Load_SaveUI.h |
| 11/08/99 10:31p | 523 | StepperView1.cpp |
| 11/08/99 10:31p | 953 | StepperView1.h |
| 11 File(s) | 23,199 | bytes |

Directory of source\Users\worknew\CbuilderWork{cube root}MyWorkSheet

This is related to the spreadsheet based control tools

| | | |
|---|---|---|
| 11/29/01 10:09a | 14,442 | AwkFEWorkSheet1_UI.cpp |
| 11/23/01 01:48p | 3,392 | AwkFEWorkSheet1_UI.h |
| 11/23/01 10:11a | 724 | AwkUI1_prj.cpp |
| 01/16/01 07:31p | 712 | DynamicSheets_prj.cpp |
| 01/17/01 12:23p | 2,597 | dynamic_sheetsUI.cpp |
| 01/16/01 11:28p | 1,377 | dynamic_sheetsUI.h |

| | | |
|---|---|---|
| 02/16/03 06:08p | <DIR> | externals |

| | | |
|---|---|---|
| 10/07/00 11:16p | 3,160 | IndexedTables.cpp |
| 10/07/00 10:27p | 214 | IndexedTables.h |
| 01/10/00 11:54a | 722 | MyWorkSheetV1.cpp |
| 06/04/00 10:17a | 14,985 | ParserPlusWorkSheet1_UI.cpp |
| 06/04/00 07:32a | 3,113 | ParserPlusWorkSheet1_UI.h |
| 06/02/00 09:34a | 740 | ParserPlusWorkSheetV1.cpp |
| 10/07/00 10:27p | 963 | SpreadSheetToSrc.cpp |
| 11/10/00 12:16p | 9,311 | SpreadSheetToTxTSrcUI.cpp |
| 10/08/00 11:52a | 4,596 | SpreadSheetToTxTSrcUI.h |
| 10/06/00 03:30p | 10,058 | TmXBlocks.cpp |
| 10/06/00 12:27p | 206 | TmXBlocks.h |
| 11/10/00 11:37a | 11,642 | vlogtst1.v |
| 10/12/00 10:53p | 12,468 | WorkSheet1_UI.cpp |
| 10/12/00 12:50p | 3,214 | WorkSheet1_UI.h |

Directory of source\Users\worknew\CbuilderWork\MyWorkSheet\externals

| | | |
|---|---|---|
| 01/10/00 11:45a | 433 | look_and_feel_xtras.cpp |
| 01/10/00 11:45a | 1,063 | look_and_feel_xtras.h |

Directory of source\Users\worknew\Specification_Zest\IGOR\Models

Early simulators

| | | |
|---|---|---|
| 11/08/99 10:31p | 3,645 | FirmWareModels1.cpp |
| 11/08/99 10:31p | 218 | FirmWareModels1.h |
| 11/08/99 10:31p | 1,067 | MemoryModels.cpp |
| 11/08/99 10:31p | 212 | MemoryModels.h |

Directory of source\Users\worknew\Specification_Zest\IGOR\monitor_tests

The basic debug monitor

| | | |
|---|---|---|
| Nov. 8, 1999 10:31 p | 937 | DebugGrid0.cpp |
| Nov. 8, 1999 10:31 p | 1,996 | debug_grid_UI.cpp |
| Nov. 8, 1999 10:31 p | 1,709 | debug_grid_UI.h |
| Nov. 8, 1999 10:31 p | 2,003 | design_entry_grid_UI.cpp |
| Nov. 8, 1999 10:31 p | 1,752 | design_entry_grid_UI.h |
| Nov. 8, 1999 10:31 p | 1,121 | GridTopForm.cpp |
| Nov. 8, 1999 10:31 p | 1,186 | GridTopForm.h |
| Nov. 8, 1999 10:31 p | 4,937 | look_and_feel_xtras.cpp |
| Nov. 8, 1999 10:31 p | 1,338 | look_and_feel_xtras.h |
| Nov. 8, 1999 10:31 p | 1,829 | monitor_scratch_pad_UI.cpp |
| Nov. 8, 1999 10:31 p | 1,483 | monitor_scratch_pad_UI.h |
| Nov. 8, 1999 10:31 p | 1,2l9 | monitor_test1.cpp |
| Nov. 8, 1999 10:31 p | 1,492 | unit_spec_UI.cpp |
| Nov. 8, 1999 10:31 p | 2,322 | unit_spec_UI.h |
| Nov. 8, 1999 10:31 p | 4,849 | wrk_area_frm_UI1.cpp |
| Nov. 8, 1999 10:31 p | 3,356 | wrk_area_frm_UI1.h |

Directory of source\Users\worknew\Specification_Zest\IGOR\RegionGrid

| | | | |
|---|---|---|---|
| Dec. 28, 1999 01:57 p | | 666 | RegionGridTest1_prj.cpp |
| Dec. 30, 1999 08:52 a | | 10,685 | RegionGridTestUI.cpp |
| Dec. 30, 1999 06:41 a | | 3,508 | RegionGridTestUI.h |
| Feb. 10, 2003 06:08 p | <DIR> | | externals |
| May 26, 2000 01:47 p | | 11,143 | SImpleTextInput.cpp |
| May 21, 2000 04:36 p | | 4,367 | SImpleTextInput.h |
| Feb. 10, 2003 06:08 p | <DIR> | | Structual |
| Feb. 10, 2003 06:08 p | <DIR> | | TextInputUnits |
| Feb. 10, 2003 06:08 p | <DIR> | | TokenThreading |

Directory of source\Users\worknew\Specification_Zest\IGOR\SmallVersion1\externals

| | | |
|---|---|---|
| May 28, 2000 06:27 p | 1,863 | DDE_Netscape_UI.cpp |
| May 28, 2000 07:32 p | 1,255 | DDE_Netscape_UI.h |
| Dec. 10, 1999 02:50 a | 417 | look_and_feel_xtras.cpp |
| Dec. 10, 1999 02:52 a | 1,047 | look_and_feel_xtras.h |

Directory of source\Users\worknew\Specification_Zest\IGOR\SmallVersion1\Structual

| | | |
|---|---|---|
| Jan. 30, 2000 12:49 a | 329 | TextStreamInput.cpp |
| Jan. 30, 2000 11:17 a | 831 | TextStreamInput.h |
| Jan. 30, 2000 12:49 a | 329 | TextStreamInput0.cpp |
| Jan. 29, 2000 10:51 p | 816 | TextStreamInput0.h |

Directory of source\Users\worknew\Specification_Zest\IGOR\SmallVersion1\TextInputUnits

| | | |
|---|---|---|
| May 21, 2000 04:30 p | 1,268 | InterpreterTraceVu.cpp |
| May 21, 2000 04:30 p | 1,623 | InterpreterTraceVu.h |
| May 21, 2000 04:33 p | 482 | LogList.cpp |
| May 21, 2000 04:34 p | 397 | LogList.h |
| Feb. 23, 2000 04:21 a | 6,729 | module_compiler0.cpp |
| May 11, 2000 11:22 a | 9,256 | module_compiler0.h |
| May 28, 2000 09:37 p | 11,244 | NumericHostNode.cpp |
| Nov. 9, 2000 03:45 p | 6,892 | NumericHostNode.h |
| May 14, 2000 09:23 a | 5,353 | SimpleSymbols.cpp |
| Feb. 23, 2000 04:18 a | 7,899 | SimpleSymbols.h |
| Jan. 30, 2000 11:25 a | 4,984 | SImpleTextInput0.cpp |
| Jan. 30, 2000 11:26 a | 2,001 | SImpleTextInput0.h |
| May 21, 2000 04:30 p | 1,311 | SimpleTextTest_prj.cpp |
| May 28, 2000 09:32 p | 665 | system_startup1.cpp |
| Feb. 14, 2000 09:24 p | 218 | system_startup1.h |
| Feb. 23, 2000 04:21 a | 4,771 | TestSymbolUI.cpp |
| Feb. 21, 2000 03:01 a | 2,784 | TestSymbolUI.h |
| Jun. 5, 2000 08:51 p | 557 | VMC_ROOT_blk_PUI.cpp |
| Jun. 5, 2000 05:17 p | 1,847 | VMC_ROOT_blk_PUI.h |
| Jun. 5, 2000 05:16 p | 523 | VMC_Root_IDE.cpp |
| Jun. 5, 2000 05:16 p | 808 | VMC_Root_IDE.h |
| Jun. 5, 2000 05:17 p | 556 | VMC_ROOT_IDE_dm.cpp |
| Jun. 5, 2000 05:17 p | 941 | VMC_ROOT_IDE_dm.h |
| Jun. 5, 2000 05:18 p | 1,057 | VMC_ROOT_prj.cpp |
| Jun. 5, 2000 08:51 p | 564 | VMC_ROOT_Unit4.cpp |
| Jun. 5, 2000 05:18 p | 1,013 | VMC_ROOT_Unit4.h |

Directory of source\Users\worknew\Specification_Zest\IGOR{cube root}SmallVersion1\TokenThreading

| | | |
|---|---|---|
| May 28, 2000 09:27 p | 1,544 | TokenThreadingUI.cpp |
| May 28, 2000 06:27 p | 1,629 | TokenThreadingUI.h |
| May 28, 2000 08:16 p | 868 | TokenThreading_prj.cpp |
| 5 File(s) | 4,041 | bytes |

Directory of source\Users\worknew\Specification_Zest\IGOR\SporeLab

| | | |
|---|---|---|
| Dec. 1, 1999 05:15 a | 520 | floating1.cpp |
| Dec. 1, 1999 05:15 a | 751 | floating1.h |
| Dec. 12, 1999 06:50 p | 1,756 | regex_tester_UI.cpp |
| Dec. 12, 1999 06:49 p | 1,375 | regex_tester_UI.h |
| Dec. 11, 1999 08:26 p | 2,453 | SaveModifiedDialiog.cpp |
| Dec. 11, 1999 08:26 p | 1,480 | SaveModifiedDialiog.h |
| Dec. 12, 1999 06:48 p | 1,014 | SporeLabTst1_prj.cpp |
| Dec. 13, 1999 02:54 p | 9,640 | SystemDesigner0_UI.cpp |
| Dec. 13, 1999 02:45 p | 3,246 | SystemDesigner0_UI.h |

Directory of source\Users\worknew\Specification_Zest\IGOR\SporeLab\externals

| | | |
|---|---|---|
| Dec. 10, 1999 02:50 a | 417 | look_and_feel_xtras.cpp |
| Dec. 10, 1999 02:52 a | 1,047 | look_and_feel_xtras.h |

Directory of source\Users\worknew\Specification_Zest\IGOR\TextStreamer

| | | |
|---|---|---|
| Jan. 6, 2000 11:04 a | 686 | TextStreamerTest_prj.cpp |
| Jan. 6, 2000 12:01 p | 1,228 | TextStreamerUI.cpp |
| Jan. 6, 2000 11:59 a | 1,630 | TextStreamerUI.h |

Directory of source\Users\worknew\Specification_Zest\IGOR\TxUVerifier_Pkt40Gen

The explorer version of the SXU

| | | |
|---|---|---|
| Nov. 8, 1999 10:31 p | 1,476 | DPUoverview_UI.cpp |
| Nov. 8, 1999 10:31 p | 1,533 | DPUoverview_UI.h |
| Nov. 8, 1999 11:24 p | 1,142 | Pkt40GenUI.cpp |
| Nov. 9, 1999 12:13 p | 4,590 | Pkt40Utils.cpp |
| Apr. 18, 2000 04:56 p | 4,597 | Pkt40Utils.h |
| Nov. 10, 1999 12:46 p | 1,234 | TxUTesterUI.cpp |
| Nov. 10, 1999 12:46 p | 1,252 | TxUTesterUI.h |
| Nov. 10, 1999 12:46 p | 7,903 | TxUVerifierAndPkt40Gen.cpp |
| Nov. 10, 1999 12:46 p | 2,677 | TxUVerifierAndPkt40Gen.h |

Directory of source\Users\worknew\Specification_Zest\IGOR\UnitCapture

| | | | |
|---|---|---|---|
| Nov. 08, 1999 | 10:31 p | 6,915 | DBC0nnectionUI.cpp |
| Nov. 08, 1999 | 10:31 p | 1,768 | DBC0nnectionUI.h |
| Dec. 22, 1999 | 09:47 a | 3,029 | DumpForm1.cpp |
| Nov. 08, 1999 | 10:31 p | 1,286 | DumpForm1.h |
| Jan. 04, 2000 | 04:05 p | 1,756 | LogFormUI.cpp |
| Jan. 04, 2000 | 04:05 p | 1,487 | LogFormUI.h |
| Dec. 22, 1999 | 09:49 a | 973 | NetDumpListingUI.cpp |
| Nov. 08, 1999 | 10:31 p | 1,169 | NetDumpListingUI.h |
| Nov. 08, 1999 | 10:31 p | 1,408 | ScehmaCapture.cpp |
| Jan. 04, 2000 | 05:18 p | 45,457 | SchemaBuild UI.cpp |
| Jan. 04, 2000 | 03:20 p | 5,884 | SchemaBuild_UI.h |
| Nov. 08, 1999 | 10:31 p | 5,479 | SchemaBuild_UI0.h |
| Nov. 08, 1999 | 10:31 p | 41,884 | SchemaBuild_UIx0.cpp |
| Dec. 12, 1999 | 09:56 a | 2,870 | SchematicMasterUI.cpp |
| Nov. 08, 1999 | 10:31 p | 1,573 | SchematicMasterUI.h |
| Nov. 08, 1999 | 10:31 p | 1,129 | sketchUI.cpp |
| Nov. 08, 1999 | 10:31 p | 941 | sketchUI.h |
| Dec. 24, 1999 | 02:18 p | 521 | SystemForm.cpp |
| Dec. 24, 1999 | 02:18 p | 753 | SystemForm.h |
| Dec. 24, 1999 | 02:18 p | 1,253 | UnitCaptureTst1_prj.cpp |

Directory of source\Users\worknew\Specification_Zest\Iterations\Iteration1\BootStrap1

| | | | |
|---|---|---|---|
| Feb. 04, 2000 | 03:55 p | 137 | lcc_defs.h |
| Nov. 03, 2000 | 12:00 p | 3,104 | region_tools.c |
| Nov. 03, 2000 | 11:32 a | 6,342 | region_tools.h |
| Nov. 02, 2000 | 11:48 a | 517 | Unit1.cpp |
| Nov. 02, 2000 | 11:48 a | 744 | Unit1.h |

Directory of source\Users\worknew\Specification_Zest\Iterations\Iteration1\BootStrap 1 CodeGen

Early code generator

| | | | |
|---|---|---|---|
| Nov. 23, 2000 | 04:45 p | 7,784 | ActionsArgs.c |
| Nov. 23, 2000 | 10:28 a | 210 | ActionsArgs.h |
| Nov. 23, 2000 | 10:45 a | 1,761 | action_code_iface.h |
| Dec. 04, 2000 | 11:32 a | 5,427 | bootrun01.c |
| Feb. 18, 2001 | 03:26 p | 5,427 | bootrun1.c |
| Dec. 04, 2000 | 03:24 p | 666 | btst1.c |
| Dec. 31, 2000 | 12:09 p | 9,499 | dbg_dump.c |
| Nov. 23, 2000 | 10:39 a | 2,144 | not_used_yet.c |
| Nov. 24, 2000 | 11:12 a | 7,495 | Phase1SymDef.c |
| Nov. 22, 2000 | 09:39 p | 212 | Phase1SymDef.h |
| Dec. 01, 2000 | 01:30 p | 6,583 | phase1_template.c |
| Nov. 22, 2000 | 10:58 p | 218 | phase1_template.h |
| Dec. 13, 2000 | 12:39 p | 2,504 | simple_test1.c |
| Nov. 24, 2000 | 11:39 p | 6,850 | symbolic_to_c.h |
| Nov. 23, 2000 | 06:45 a | 256 | symbol_iface.c |
| Nov. 23, 2000 | 06:47 a | 676 | symbol_iface.h |

11/24/00 11:20a 6,850 symbolic_to_c.h

Directory of source\Users\worknew\Specification_Zest\Iterations\Iteration1\BootStrap1\drones

| | | | |
|---|---|---|---|
| Feb. 02, 2001 | 01:31 p | 658 | drone1_prj.cpp |
| Feb. 02, 2001 | 01:49 p | 1,557 | drone_view_UI.cpp |
| Feb. 02, 2001 | 01:30 p | 998 | drone_view_UI.h |

Directory of source\Users\worknew\Specification_Zest\Iterations\Iteration1\BootStrap1\FirstDrive

| | | | |
|---|---|---|---|
| Dec. 05, 2000 | 02:00 p | 8,826 | FirstCdriverUI.cpp |
| Dec. 05, 2000 | 01:58 p | 1,287 | FirstCdriverUI.h |
| Nov. 23, 2000 | 10:28 a | 1,010 | FirstDriver_prj.cpp |
| Nov. 22, 2000 | 08:58 p | 429 | SkeletonLib.c |
| Nov. 22, 2000 | 09:01 p | 1,034 | SkeletonLib.h |
| Nov. 23, 2000 | 08:12 a | 5,543 | SymTable1.c |
| Nov. 23, 2000 | 09:42 a | 1,987 | SymTable1.h |
| Nov. 19, 2000 | 08:46 p | 247 | Unit1.c |
| Nov. 19, 2000 | 08:47 p | 203 | Unit1.h |

Directory of source\Users\worknew\Specification_Zest\Iterations\Iteration1\BootStrap1\FirstRows

| | | | |
|---|---|---|---|
| Jan. 11, 2001 | 08:07 a | 4,006 | Itm16_rows.c |
| Jan. 08, 2001 | 12:27 a | 208 | Itm16_rows.h |
| Jan. 07, 2001 | 10:48 p | 3,783 | Itm16_rowsOld.c |
| Jan. 08, 2001 | 12:27 a | 758 | Itm64_rows16_tst1_prj.cpp |
| Jan. 07, 2001 | 11:54 p | 994 | Itm64_rows16_tst_UI.cpp |
| Jan. 08, 2001 | 12:06 a | 1,080 | Itm64_rows16_tst_UI.h |
| Jan. 08, 2001 | 12:22 a | 333 | Itm_vals.c |
| Jan. 08, 2001 | 12:21 a | 666 | Itm_vals.h |

Directory of source\Users\worknew\Specification_Zest\Iterations\Iteration1\BootStrap1\Q_testing

| | | | | |
|---|---|---|---|---|
| Jan. 26, 2001 | 11:45 a | | 712 | Qtest1_prj.cpp |
| Jan. 26, 2001 | 01:03 p | | 3,930 | Qtest1_UI.cpp |
| Jan. 26, 2001 | 12:43 p | | 1,524 | Qtest1_UI.h |
| Feb. 10, 2003 | 06:08 p | <DIR> | | TmX |

Directory of source\Users\worknew\Specification_Zest\Iterations\Iteration1\BootStrap1\Q_jesting\TmX

| | | | |
|---|---|---|---|
| Jan. 26, 2001 | 11:44 a | 252 | sheet_range.cpp |
| Jan. 26, 2001 | 11:44 a | 210 | sheet_range.h |
| Jan. 30, 2001 | 02:03 p | 11,625 | sync_range.cpp |
| Jan. 30, 2001 | 02:08 p | 2,586 | sync_range.h |
| Jan. 30, 2001 | 03:56 p | 6,171 | XnX1.cpp |
| Jan. 30, 2001 | 03:55 p | 4,575 | XnX1.h |

Directory of source\Users\worknew\Specification_Zest\Iterations\Iteration1\BootStrap1\RegionOn Disk

| | | | |
|---|---|---|---|
| Nov. 3, 2000 | 01:11p | 849 | RegionOnDisk_prj.cpp |
| Nov. 3, 2000 | 03:34a | 3,001 | RegionOnDisk_UI.cpp |
| Nov. 2, 2000 | 06:00p | 2,195 | RegionOnDisk_UI.h |
| Nov. 3, 2000 | 01:59p | 2,010 | SheetTextToRegion.cpp |
| Nov. 3, 2000 | 01:23p | 1,055 | SheetTextToRegion.h |
| Nov. 3, 2000 | 12:27p | 1,540 | TextToRegion.cpp |
| Nov. 3, 2000 | 12:04p | 212 | TextToRegion.h |

Directory of source\Users\worknew\Specification_Zest\Iterations\Iteration1\BootStrap1\Simulator

| | | | |
|---|---|---|---|
| Jan. 19, 1001 | 11:37 a | 3,075 | root_operations.c |

Directory of source\Users\worknew\Specification_Zest\Iterations\Iteration1\BootStrap1\TIG1

Basic data types

| | | | |
|---|---|---|---|
| Nov. 15, 2000 | 02:26 a | 2,629 | cell_editor.c |
| Nov. 14, 2000 | 11:49 a | 210 | cell_editor.h |
| Nov. 21, 2000 | 04:38 a | 2,937 | Number.c |
| Nov. 20, 2000 | 09:26 p | 5,547 | Number.h |
| Nov. 14, 2000 | 11:49 a | 752 | TIG1.cpp |
| Nov. 12, 2000 | 08:55 p | 2,466 | TIG1_syms.c |
| Nov. 12, 2000 | 02:48 p | 522 | TIG1_top_UI.cpp |
| Nov. 12, 2000 | 08:57 p | 1,923 | TIG1_top_UI.h |
| Nov. 15, 2000 | 02:04 p | 1,468 | TmXStrearnIO.c |
| Nov. 12, 2000 | 09:05 p | 210 | TmXStreamIO.h |
| Nov. 14, 2000 | 03:39 a | 7,734 | TmX_string.c |

Directory of source\Users\worknew\Specification_Zest\Iterations\Iteration1\BootStrap1\TmX.System

| | |
|---|---|
| Mar. 06, 2000 10:53 a | 3,716 codes_etc_gen.c |
| Mar. 06, 2000 10:40 a | 1,356 tmp1.c |

Directory of source\Users\worknew\Specification_Zest\Iterations\Iteration1\DemoAppSort

Demostration application to drive initial versions

| | | |
|---|---|---|
| Mar. 16, 2001 03:19 p | 13,961 | dbg_dump.c |
| Feb. 20, 2001 06:13 p | 24,115 | DemoAppSortCMIF.c |
| Feb. 14, 2001 02:02 p | 9,827 | DumpnList.c |
| Mar. 16, 2001 08:32 a | 2,447 | Function_lib.c |
| Feb. 25, 2001 11:30 p | 432 | GenCode1.c |
| Feb. 26, 2001 08:54 p | 9,238 | gen_fcn.c |
| Apr. 11, 2001 08:31 p | 13,830 | ItmMtrEng.c |
| Mar. 20, 2001 11:00 a | 1,839 | QCa1c1.c |
| Mar. 18, 2001 02:30 p | 473 | QCa1c1.h |
| Mar. 15, 2001 10:16 p | 79 | Seng2Seq.c |
| Feb. 26, 2001 12:01 a | 767 | stab_util.c |
| Mar. 15, 2001 07:33 p | 97 | stdio.c |
| Mar. 12, 2001 08:13 a | 5,412 | symbolic_to_c2.h |
| Mar. 20, 2001 05:24 p | 319 | TmX.memory.c |
| Mar. 20, 2001 04:10 p | 71 | TmX.memory.h |
| Apr. 12, 2001 01:12 a | 7,020 | TmX.Qu0.c |
| Apr. 12, 2001 01:07 a | 1,252 | TmX.Qu0.h |
| Mar. 16, 2001 12:05 p | 104 | TmX.stdio.c |
| Mar. 21, 2001 10:37 p | 1,351 | TmX.stdio.h |
| Apr. 05, 2001 11:30 a | 9,438 | TmX.types.c |
| Apr. 03, 2001 03:30 a | 13,871 | TmX.types.gtor.c |
| Apr. 11, 2001 06:35 a | 11,055 | TmX.types.h |
| Mar. 20, 2001 04:08 p | 62 | TmX.types.nbr.h |
| Dec. 14, 2001 07:47 a | 2,170 | TmX_Util.h |
| Feb. 14, 2001 02:48 p | 18,031 | xx1.c |

Directory of source\Users\worknew\Specification_Zest\Iterations\Iteration1\DemoAppSort\auto

| | |
|---|---|
| Apr. 03, 2001 05:12 a | 4,654 tmx.types.h |

Directory of source\Users\worknew\Specification_Zest\Iterations\Iteration1\DemoAppSort\FQM

| | |
|---|---|
| Mar. 03, 2001 10:21 a | 615 Qca1c1.c |

Directory of source\Users\worknew\Specification_Zest\Iterations\Iteration1\DemoAppSort\TmX.types.uses

| | |
|---|---|
| Apr. 03, 2001 05:04 a | 5,281 ItmMtrEng.Types.h |

Directory of source\Users\worknew\Specification_Zest\Iterations\Iteration1\externals

| | | |
|---|---|---|
| May 28, 2000 06:27 p | 1,863 | DDE_Netscape_UI.cpp |
| May 28, 2000 07:32 p | 1,255 | DDE_Netscape_UI.h |
| Dec. 10, 1999 02:50 a | 417 | look_and_feel_xtras.cpp |
| Dec. 10, 1999 02:52 a | 1,047 | look_and_feel_xtras.h |

Directory of source\Users\worknew\Specification_Zest\Iterations\Iteration1\GTORsheet

| | | | |
|---|---|---|---|
| Mar. 6, 2001 | 12:25p | 1,036 | CalcSheetUI.cpp |
| Mar. 6, 2001 | 11:59a | 1,259 | CalcSheetUI.h |
| Mar. 7, 2001 | 01:09p | 1,513 | DrawSheetUI.cpp |
| Mar. 7, 2001 | 12:48p | 1,238 | DrawSheetUI.h |
| Mar. 7, 2001 | 01:05p | 3,105 | DraWUtils.cpp |
| Mar. 6, 2001 | 12:36p | 206 | DraWUtils.h |
| Mar. 6, 2001 | 12:36p | 804 | GTORsheet1_prj.cpp |

Directory of source\Users\worknew\Specification_Zest\Iterations\Iteration1\NewSchemaModel

| | | |
|---|---|---|
| Aug. 11, 2000 03:51 p | 526 | AsmWorkGrid.cpp |
| Aug. 11, 2000 03:51 p | 816 | AsmWorkGrid.h |
| Jun. 06, 2000 10:06 p | 1,238 | ComponentEditor1.cpp |
| Jun. 06, 2000 10:06 p | 1,198 | ComponentEditor1.h |
| Aug. 11, 2000 01:59 p | 918 | ComponentSheet.cpp |
| Aug. 11, 2000 10:48 p | 2,881 | ComponentSheet.h |
| Aug. 11, 2000 02:44 p | 8,721 | DBTables.cpp |
| Aug. 11, 2000 01:31 p | 5,705 | DBTables.h |
| Dec. 26, 2000 06:11 p | 1,250 | ObjCapture1_prj.cpp |
| Nov. 09, 2000 02:21 p | 42,102 | ObjCapture1_UI.cpp |
| Nov. 09, 2000 01:52 p | 9,194 | ObjCapture1_UI.h |
| Aug. 11, 2000 08:25 a | 797 | QuickScanPrj.cpp |
| Sep. 15, 2000 02:27 p | 10,983 | QuickScanUI.cpp |
| Sep. 15, 2000 01:48 a | 3,254 | QuickScanUI.hp |
| Jun. 28, 2000 11:30 a | 5,672 | Sheet2SQL_UI.cpp |
| Jun. 06, 2000 11:30 a | 2,352 | Sheet2SQL_UI.h |
| Nov. 09, 2000 02:23 p | 6,352 | SheetUti1s.cpp |
| Nov. 09, 2000 02:21 p | 3,821 | SheetUti1s.h |
| Dec. 26, 2000 05:21 p | 5,861 | TableSheet1_UI.cpp |
| Dec. 26, 2000 05:21 p | 2,593 | TableSheet1_UI.h |
| Jun. 06, 2000 10:05 p | 258 | VMC_sheet_def_hdr.cpp |
| Jun. 06, 2000 10:57 p | 742 | VMC_sheet_def_hdr.h |
| Dec. 29, 2000 06:22 a | 8,870 | VuQ_itm_editor.cpp |
| Dec. 26, 2000 06:11 p | 216 | VuQ_itm_editor.h |
| Jun. 06, 2000 01:14 p | 5,860 | WorkSheet1_UI.cpp |
| Apr. 16, 2000 04:48 p | 2,591 | WorkSheet1_UI.h |

Directory of source\Users\worknew\Specification_Zest\Iterations\Iteration1\SegmentAndChipParts\Ccode

Interface to drive the simulator

| | | |
|---|---|---|
| Aug. 08, 2000 03:31 p | 722 | TestSiloPLI_prj.cpp |
| Aug. 08, 2000 07:10 p | 533 | TestSilosPLI.cpp |
| Aug. 08, 2000 07:15 p | 1,022 | TestSilosPLI.h |

Directory of source\Users\worknew\Specification_Zest\Iterations\Iteration1\SegmentAndChipParts\Verilog

The verlog defining the recodable SXU

| | | |
|---|---|---|
| Aug. 07, 2000 08:04 p | 3,106 | AGEN.v |
| Aug. 06, 2000 11:59 p | 5,219 | DtaGEN.v |
| Aug. 26, 2000 10:49 p | 2,172 | Fiz_tst1.v |
| Aug. 26, 2000 07:16 p | 18,196 | 11_L2_RAM.v |
| Aug. 27, 2000 06:01 a | 2,297 | L1_RAM.v |
| Sep. 19, 2000 03:03 p | 10,946 | L2_SeqReg8_v00.v |
| Sep. 15, 2000 02:49 p | 561 | L2_SequencerQ1.v |
| Sep. 18, 2000 09:59 a | 2,705 | L2_StubSeq.v |
| Sep. 04, 2000 12:17 p | 7,217 | L2_tester_sim.v |
| Jul. 27, 2000 11:53 a | 3,436 | LineManagerSMUStuff.v |
| Aug. 06, 2000 02:26 p | 678 | PLI01.V |
| Jul. 21, 2000 11:01 a | 5,941 | PortsRegFiles.v |
| Nov. 10, 2000 12:59 p | 27.234 | SMU_ct1l.v |
| Jul. 21, 2000 10:50 a | 1,267 | Ternplate1.v |
| Jul. 20, 2000 07:56 p | 2,703 | template_DtaHldCt1.v |
| Aug. 09, 2000 09:28 a | 7,200 | TEST_SEngi_sim.v |
| Jul. 27, 2000 09:13 p | 2,140 | TEST_SMTJ1.v |
| Sep. 22, 2000 01:39 p | 2,058 | VIDIO_stub.v |

Directory of source\Users\worknew\Specification_Zest\Iterations\Iteration1\SegmentAndChipParts\Verilog\VidTest_{—}1

| | | |
|---|---|---|
| Sep. 22, 2000 03:41 p | 14,547 | Copy ofL2_SeqReg8.v |
| Sep. 24, 2000 10:51 a | 3,611 | L2_iface.v |
| Sep. 29, 2000 07:14 a | 18,310 | L2_SeqReg8.v |
| Sep. 22, 2000 02:36 p | 14,280 | L2_SeqReg8PreSim1.v |
| Sep. 24, 2000 02:09 p | 14,628 | L2_SeqReg8Rev2.v |
| Sep. 26, 2000 10:10 p | 16,750 | L2_SeqReg8Rev3.v |
| Sep. 27, 2000 07:15 a | 17,074 | L2_SeqReg8Rev4.v |
| Sep. 28, 2000 11:01 p | 17,766 | L2_SeqReg8Rev5.v |
| Sep. 26, 2000 08:15 a | 15,357 | L2_SeqReg8TueAM.v |
| Sep. 26, 2000 08:18 a | 2,918 | L2_SeqReg8_template.v |
| Jul. 21, 2000 11:01 a | 5,941 | PortsRegFiles.v |
| Sep. 24, 2000 10:57 a | 4,601 | Stubs1.v |
| Sep. 29, 2000 01:41 p | 9,333 | TestJtag1_sim.v |
| Sep. 22, 2000 0l:471p | 2,138 | VIDIO_stub.v |

Directory of source\Users\worknew\Specification_Zest\Iterations\Iteration1\SegmentAndChipParts\Verilog\VidTest_Z1

| | | |
|---|---|---|
| 09/21/00 03:17a | 3,279 | L2_iface.v |
| 09/21/00 07:59a | 12,342 | L2_SeqReg8.v |
| 07/21/00 11:01a | 5,941 | PortsRegFiles.v |
| 09/21/00 06:27a | 4,418 | Stubs1.v |
| 09/20/00 03:18p | 6,016 | TestJtag1_sim.v |

Directory of source\Users\worknew\Specification_Zest\Iterations\Iteration1\SegmentAndChipParts\Verilog\VidTest_Z2

| | | |
|---|---|---|
| 09/24/00 10:51a | 3,611 | L2_iface.v |
| 09/24/00 02:22p | 14,935 | L2_SeqReg8.v |
| 09/24/00 04:40a | 2,720 | L2_SeqReg8_template.v |
| 07/21.00 11:01a | 5,941 | PortsRegFiles.v |
| 09/24/00 10:57a | 4,601 | Stubs1.v |
| 09/24/00 08:49a | 7,092 | TestJtag1_sim.v |
| 09/22/00 01:47p | 2,138 | VIDIO_stub.v |

Directory of source\Users\worknew\Specification_Zest\Iterations\Iteration1\Simulation

| | | |
|---|---|---|
| 02/09/00 09:36p | 8,928 | SimpleSegment1.cpp |
| 02/16/00 07:46p | 5,334 | SimpleSegment1.h |
| 02/09/00 02:21a | 698 | SimpleSegment1_prj.cpp |
| 02/09/00 02:20a | 528 | SimpleSegment1_UI.cpp |
| 02/09/00 02:20a | 767 | simpleSegment1_UI.h |

Directory of source\Users\worknew\Specification_Zest\Iterations\Iteration1\SupportModules

| | | |
|---|---|---|
| 08/15/00 07:11p | 530 | ChannelTesterUI.cpp |
| 08/15/00 07:11p | 767 | ChannelTesterUI.h |
| 08/15/00 07:11p | 759 | ChannelTester_prj.cpp |
| 08/16/00 07:06p | 6,840 | MemoryImageXfr.cpp |
| 08/16/00 09:41p | 6,121 | MemoryImageXfr.h |

Directory of source\Users\worknew\Specification_Zest\Iterations\Iteration1\SymTreeDump

| | | |
|---|---|---|
| 05/29/00 09:42p | 4,529 | SymTreeDumpUI.cpp |
| 05/29/00 06:09p | 2,012 | SymTreeDumpUI.h |
| 05/29/00 05:33p | 659 | SymTreeDump_prj.cpp |

Directory of source\Users\worknew\Specification_Zest\Iterations\Iteration1\TargetControlPanel

| | | |
|---|---|---|
| 05/15/00 09:34 p | 697 | LoadingFromFile1_prj.cpp |
| 05/15/00 10:01 p | 2,911 | TargetControlPanel_UI.cpp |
| 05/15/00 10:01 p | 1,693 | TargetControlPanel_UI.h |
| 05/15/00 10:00 p | 1,695 | Targets.cpp |
| 05/15/00 09:34 p | 202 | Targets.h |

Directory of source\Users\worknew\Specification_Zest\Iterations\Iteration1\temp

| | | |
|---|---|---|
| 10/02/00 06:23a | 7,494 | binsrch.c |

Directory of source\Users\worknew\Specification_Zest\Iterations\Iteration1\VidComponent

| | | |
|---|---|---|
| 10/26/00 04:59p | 6,560 | ImageGenerator.cpp |
| 09/03/00 03:54p | 3,106 | ImageGenerator.h |
| 08/25/00 12:30p | 592 | MemoryPlacement.cpp |
| 08/25/00 03:11p | 1,161 | MemoryPlacement.h |
| 12/26/00 05:52a | 29,819 | SEng2Gentor_UI.cpp |
| 12/18/00 03:00p | 931 | SEng2Gentor_UI.h |
| 09/29/00 02:45p | 14,307 | SeqGenDbg_UI.cpp |
| 10/18/00 09:52a | 3,220 | SeqGenDbg_UI.h |
| 10/26/00 08:11p | 16,887 | SeqGenerator.cpp |
| 10/10/00 10:54p | 8,683 | SeqGenerator.h |
| 09/01/00 12:07p | 2,962 | SequencerL2.cpp |
| 10/10/00 10:19p | 4,505 | SequencerL2.h |
| 08/25/00 11:13a | 9,627 | TmXStorageClasses.cpp |
| 08/25/00 11:58a | 8,410 | TmXStorageClasses.h |
| 10/10/00 10:17p | 16,442 | VidCompDbgUI.cpp |
| 09/25/00 05:29p | 5,460 | VidCompDbgUI.h |
| 08/25/00 01:18a | 3,879 | VidComponent.hc.cpp |
| 08/24/00 06:39p | 218 | VidComponent.hc.h |
| 12/18/00 03:00p | 1,233 | VidComponentOnPC_prj.cpp |
| 09/25/00 06:02a | 1,971 | VidComponentRefresh_UI.cpp |
| 09/25/00 06:02a | 1,541 | VidComponentRefresh_UI.h |
| 09/01/00 12:17p | 4,170 | VidOut.cpp |
| 09/04/00 09:15a | 1,600 | VidOut.h |

Directory of source\Users\worknew\Specification_Zest\Iterations\Iteration2\AStdQuTyp1

| | | |
|---|---|---|
| 12/21/01 11:48a | 116 | AnItmQuVersion1.c |
| 12/27/01 02:27p | 1,545 | AnItmVersion2.h |
| 01/02/02 08:23a | 4,815 | AStdQuTyp1.c |
| 01/02/02 11:47p | 836 | generator1.awk |
| 12/21/01 09:22a | 1,062 | HelloWorld.app.c |
| 01/02/02 11:16a | 2,439 | QuickFilter.c |

Directory of source\Users\worknew\Specification_Zest\Iterations\Iteration2\AStdQuTyp1\CMS

| | | |
|---|---|---|
| 12/15/01 02:22a | 1,838 | AStdQuTyp1.c |

Directory of source\Users\worknew\Specification_Zest\Iterations\Iteration2\AStdQuTyp1\lcc

| | |
|---|---|
| 01/02/02 08:51a | 1,991 QuickFilter.c |

Directory of source\Users\worknew\Specification_Zest\Iterations\Iteration2\CompileLink1

| | |
|---|---|
| 11/22/01 06:28a | 2,049 COMIPILELINK1.C |
| 11/19/01 10:01a | 1,513 compilerlink1.c |
| 11/21/01 08:23p | 6,084 QU86_T.C |
| 11/21/01 05:14a | 779 Qu86_t.h |
| 12/13/01 11:49a | 4,542 Quterp1.c |
| 12/03/01 08:26a | 1,573 quterp1.h |
| 11/22/01 06:08a | 4,103 SEQUENCE.C |
| 11/22/01 06:08a | 349 sequence.h |
| 11/30/01 06:43a | 591 SimpleFillSequence.c |

Directory of source\Users\worknew\Specification_Zest\Iterations\Iteration2\CompileLink1\CMS

| | |
|---|---|
| 11/20/01 04:03a | 1,837 COMPILELNK1.C |
| 11/19/01 10:02a | 1,838 compilerlink1.c |
| 11/20/01 04:03a | 3,469 QU86_T.C |
| 11/20/01 04:03a | 6,459 SEQUENCE.C |

Directory of source\Users\worknew\Specification_Zest\Iterations\Iteration2\CXU

Simulation generation and documentation automation using awk.

| | |
|---|---|
| 11/16/01 08:20a | 5,487 BlkDwgGen1.awk |
| 10/22/01 11:21p | 773 BuildCxu.awk |
| 10/31/01 09:23p | 4,573 BuildCxu1.awk |
| 11/01/01 05:50a | 5,904 BuildCxu1_fcn.awk |
| 11/04/01 10:41p | 924 BuildCxu1_rcd.awk |
| 10/24/01 03:43a | 7,544 CdeCtlRun1.awk |
| 12/02/01 10:34a | 554 CHilite.awk |
| 12/22/01 02:45a | 2,451 cost_prediction.awk |
| 12/18/01 01:22a | 1,933 CXU1.C |
| 09/12/01 12:45p | 3,511 CXU1_imp.c |
| 09/10/01 10:48a | 3,532 CXU_def.h |
| 11/05/01 10:40p | 1,368 domain_utils1.awk |
| 10/02/01 10:24p | 14,199 Gtor1.c |
| 09/17/01 12:07p | 3,106 gtor1.h |
| 11/04/01 10:39p | 261 htmlgen1.awk |
| 09/17/01 12:15p | 890 modop_cdes.h |
| 10/02/01 10:18p | 934 ofs_op_cdes.h |
| 09/20/01 09:07a | 1,887 QsortBsearchInx.c |
| 09/20/01 07:54a | 1,036 QsortBsearchInx.h |
| 09/15/01 11:14p | 7,573 QuItm86.c |
| 09/15/01 11:16p | 3,762 QUITM86.H |
| 11/13/01 04:32a | 2,708 record_utils1.awk |
| 12/08/01 02:37a | 4,396 Simulator1.awk |
| 09/16/01 10:23a | 772 src1_cdes.h |
| 09/22/01 09:53p | 8,483 SymbolTable.c |
| 09/22/01 09:55p | 1,676 SymbolTable.h |
| 11/03/01 02:56a | 1,549 table_in1.awk |
| 12/11/01 08:10p | 3,365 test_compile1.awk |

Directory of source\Users\worknew\Specification_Zest\Iterations\Iteration2\Examples

| | |
|---|---|
| 04/26/01 11:58a | 5,496 QuikScan1.c |
| 04/19/01 08:55a | 109 simple_calc1.c |

Directory of source\Users\worknew\Specification_Zest\Iterations\Iteration2\Examples\Misc

| | |
|---|---|
| 05/17/01 12:16p | 1,752 general_c_tests.c |

Directory of source\Users\worknew\Specification_Zest\Iterations\Iteration2\Examples\titler

| | |
|---|---|
| 09/29/01 07:56p | 330 TITLERMAIN.C |

Directory of source\Users\worknew\Specification_Zest\Iterations\Iteration2\HTML_gen

| | |
|---|---|
| 07/24/01 09:48a | 4,235 html_gen.c |
| 11/10/01 02:56a | 3,843 FCNTST4K_IO.C |
| 10/14/01 07:45p | 17,017 itms_simpleIO.c |
| 10/14/01 07:30p | 4,396 itms_simpleIO.h |
| 10/08/01 04:57a | 703 itms_simpleio_dbg.c |
| 10/19/01 03:45p | 3,807 ITM_fileio.c |
| 10/17/01 07:15p | 728 ITM_fileio.h |
| 10/14/01 07:42p | 1,675 itm_hdr1.h |
| 10/17/01 07:02p | 2,275 nonstdio.h |
| 10/11/01 03:40p | 4,110 pge4k_io.c |
| 10/17/01 06:34p | 1,424 pge4k_io.h |
| 10/17/01 08:08p | 20,180 pge4k_io_wr.c |
| 10/16/01 03:01p | 5,238 SIDE1MAIN.C |
| 10/14/01 06:56p | 3,507 SIDEcomp.h |
| 10/17/01 12:15p | 283 temp.c |
| 10/17/01 12:23p | 283 temp1.c |
| 09/30/01 05:25p | 798 TestSIDE.c |
| 10/01/01 04:41p | 732 XfrLoop1.c |

Directory of source\Users\worknew\Specification_Zest\Iterations\Iteration2\ItmQu64

| | |
|---|---|
| 02/10/03 06:08p | <DIR> |
| 02/10/03 06:08p | <DIR> |
| 08/05/01 06:48p | 9,125 ItmQu64_stub1.c |
| 08/03/01 02:50p | 7,425 QUICKTEST.C |
| 08/03/01 01:37p | 163 qVuBase.h |

Directory of source\Users\worknew\Specification_Zest\Iterations\Iteration2\proxy1

| | |
|---|---|
| 07/10/01 09:14p | 5,688 accept.c |
| 07/10/01 07:11p | 22,532 getopt.c |
| 07/10/01 09:30p | 2,407 GETTIMEOFDAY.C |
| 07/10/01 09:30p | 9,752 HTTP.C |
| 07/10/01 09:10p | 12,407 MAIN.C |
| 07/10/01 09:04p | 3,933 MSG.C |
| 07/10/01 09:01p | 9,690 SEND.C |
| 07/27/01 05:17p | 4,695 sockettestbed.c |
| 07/10/01 09:27p | 1,140 stubs.c |
| 07/10/01 08:59p | 1,711 TCP.C |
| 07/10/01 09:32p | 5,539 wcol.h |
| 07/24/01 10:02p | 1,473 WinClient.c |
| 07/24/01 10:03p | 170 winclient.h |

Directory of source\Users\worknew\Specification_Zest\Iterations\Iteration2\proxy1\CMS

| | | |
|---|---|---|
| 07/10/01 09:16p | 6,228 | ACCEPT.C |
| 07/10/01 12:43p | 15,962 | BASE.C |
| 07/10/01 12:43p | 3,991 | CONV.C |
| 07/10/01 03:26p | 1,118 | conv.h |
| 07/10/01 12:43p | 2,132 | GET.C |
| 07/10/01 08:53p | 22,858 | GETOPT.C |
| 07/10/01 08:53p | 4,892 | getopt.h |
| 07/10/01 08:53p | 2,733 | GETTIMEOFDAY.C |
| 07/10/01 09:16p | 11,150 | HTTP.C |
| 07/10/01 09:16p | 13,700 | MAIN.C |
| 07/10/01 09:16p | 5,068 | MSG.C |
| 07/10/01 09:16p | 10,756 | SEND.C |
| 07/24/01 05:57p | 1,838 | sockettestbed.c |
| 07/10/01 08:53p | 1,965 | STUBS.C |
| 07/10/01 09:16p | 2,269 | TCP.C |
| 07/10/01 09:16p | 6,511 | wcol.h |

Directory of source\Users\worknew\Specification_Zest\Iterations\Iteration2\SchemaBuild2

| | | |
|---|---|---|
| 01/20/02 05:38p | 1,109 | BlockDiagram_pr.cpp |

Directory of source\Users\worknew\Specification_Zest\Iterations\Iteration2\SchemaBuild2\VC_develop

| | | |
|---|---|---|
| 01/20/02 05:25p | 3,039 | DumpForm1.cpp |
| 11/08/99 10:31p | 1,286 | DumpForm1.h |
| 12/16/99 06:08p | 1,455 | LogFormUI.cpp |
| 12/16/99 06:05p | 1,399 | LogFormUI.h |
| 05/25/01 10:58a | 444 | look_and_feel_xtras.cpp |
| 05/25/01 10:54a | 1,074 | look_and_feel_xtras.h |
| 01/20/02 05:31p | 976 | NetDumpListingUI.cpp |
| 11/08/99 10:31p | 1,169 | NetDumpListingUI.h |
| 11/08/99 10:31p | 1,408 | ScehmaCapture.cpp |
| 01/20/02 08:24p | 42,407 | SchemaBuild_UI.cpp |
| 06/08/00 02:19a | 5,824 | SchemaBuild_UI.h |
| 11/08/99 10:31p | 5,479 | SchemaBuild_UI0.h |
| 01/20/02 05:26p | 3,560 | SchematicMasterUI.cpp |
| 06/08/00 01:35a | 1,995 | SchematicMasterUI.h |
| 11/08/99 10:31p | 1,129 | sketchUI.cpp |
| 11/08/99 10:31p | 941 | sketchUI.h |

Directory of source\Users\worknew\Specification_Zest\Iterations\Iteration2\SchemaBuild2\VC_develop\Tests

| | | |
|---|---|---|
| 11/08/99 10:31p | 1,688 | DualVF1.cpp |
| 11/08/99 10:31p | 1,382 | DualVF1.h |
| 11/08/99 10:31p | 652 | MultiView1_prj.cpp |

Directory of source\Users\worknew\Specification_Zest\Iterations\Iteration2\Specifications

| | | |
|---|---|---|
| 01/06/02 10:32a | 5,318 | CandML1.awk |
| 01/16/02 12:35p | 572 | get_uniq.awk |
| 01/14/02 07:48a | 7,306 | SortTypeDefs.awk |
| 01/16/02 08:15a | 557 | test_makespace.awk |
| 01/18/02 03:50a | 657 | uniq_words.awk |

Directory of source\Users\worknew\Specification_Zest\Iterations\Iteration2\stdio1

| | | |
|---|---|---|
| 11/05/01 09:30a | 10,423 | SPRINTF.C |

Directory of source\Users\worknew\Specification_Zest\Iterations\Iteration2\Tests

| | | |
|---|---|---|
| 05/21/01 10:16a | 4,516 | string.c |

Directory of source\Users\worknew\Specification_Zest\Iterations\Iteration2\Tests\StringQ

| | | |
|---|---|---|
| 05/21/01 10:59a | 2,617 | alloc.c |
| 05/21/01 10:55a | 18,253 | c_for_str.h |
| 05/21/01 10:42a | 3,081 | error.c |
| 05/21/01 10:39a | 4,526 | string.c |

Directory of source\Users\worknew\Specification_Zest\Iterations\Iteration2\testSocket

| | | |
|---|---|---|
| 07/10/01 11:28a | 2,119 | testsocket.c |

Directory of source\Users\worknew\Specification_Zest\Iterations\Iteration2\TextExperiments

| | | |
|---|---|---|
| 09/23/01 05:55p | 1,348 | ContextScan.c |
| 09/24/01 08:28p | 1,969 | gendir1.awk |
| 09/23/01 05:58p | 2,134 | TEXTEXPERIMENTS.C |

Directory of source\Users\worknew\Specification_Zest\Iterations\Iteration2\TextTo_CQL

| | |
|---|---|
| 08/30/01 02:21p | 546 TextTo_CQL.c |

Directory of source\Users\worknew\Specification_Zest\Iterations\Iteration2\TmX\itm

| | |
|---|---|
| 07/06/01 02:51a | 12,982 Itm.h |
| 02/10/03 06:09p | <DIR> w321cc |

Directory of source\Users\worknew\Specification_Zest\Iterations\Iteration2\TmX\itm\cel_t

| | | |
|---|---|---|
| 01/09/02 08:51a | 6,670 | CEL_ADD.C |
| 08/28/01 07:07a | 7,377 | cel_core.c |
| 08/27/01 11:12a | 4,554 | Cel_mpy.c |
| 08/28/01 12:33p | 892 | cel_t.h |
| 08/27/01 10:09a | 406 | cel_test_add.h |
| 08/27/01 07:18a | 2,012 | cel_t_testing.c |
| 11/21/01 05:14a | 779 | Qu86_t.h |
| 01/09/02 07:12a | 6,338 | Sequence.c |

Directory of source\Users\worknew\Specification_Zest\Iterations\Iteration2\TmX\itm\cel_t\CMS

| | | |
|---|---|---|
| 08/27/01 08:42a | 6,512 | CEL_ADD.C |
| 08/27/01 08:42a | 1,944 | cel_core.c |
| 08/27/01 01:40p | 4,868 | Cel_mpy.c |
| 08/27/01 08:42a | 774 | cel_t.h |
| 08/27/01 08:42a | 598 | cel_test_add.h |
| 08/27/01 08:42a | 2,698 | CEL_T_TESTING.C |

Directory of source\Users\worknew\Specification_Zest\Iterations\Iteration2\TmX\itm\d48

| | |
|---|---|
| 09/10/01 06:26p | 3,350 d48_spec1.c |

Directory of source\Users\worknew\Specification_Zest\Iterations\Iteration2\TmX\itm\FQM

Itms the basic TmX type

| | | |
|---|---|---|
| 05/17/01 04:02p | 21,147 | asm.c |
| 05/04/01 01:48a | 256 | FQMSE2.c |
| 05/22/01 09:43a | 12,877 | ItmMtr.c |
| 05/20/01 02:57p | 1,903 | ItmMtr.h |
| 05/20/01 03:25p | 1,125 | ItmMtrTst.c |
| 05/08/01 08:44a | 6,188 | ItmMtr_tst_gtor1.c |
| 05/06/01 08:06a | 376 | ItmMtr_tst_gtor1.h |
| 05/20/01 01:17p | 5,955 | MtrLdr.c |
| 05/11/01 12:26p | 1,584 | MtrLdr.h |
| 05/14/01 08:59a | 10,910 | QuLnk.c |
| 05/17/01 11:21a | 4,462 | QuLnk.h |
| 06/21/01 10:34p | 971 | QuOut0.c |
| 05/20/01 01:20p | 7,288 | SeqDcd2.c |
| 05/23/01 05:13p | 1,289 | SeqDcd2.h |
| 06/21/01 11:11a | 7,288 | SeqDcd3.c |
| 06/21/01 11:31a | 1,479 | SeqDcd3.h |
| 08/16/01 02:43p | 20,059 | SPLIT_ITM.C |
| 05/19/01 09:42p | 946 | split_Itm.h |
| 05/22/01 01:19p | 19,949 | split_itm.old.c |
| 05/17/01 11:23a | 14,074 | TPort1.c |
| 05/06/01 12:04p | 2,713 | tst_gtor_main1.c |
| 05/04/01 01:50a | 316 | Xfer2.c |

Directory of source\Users\worknew\Specification_Zest\Iterations\Iteration2\TmX\itm\FQM\UI_stuff

| | | |
|---|---|---|
| 05/20/01 02:28p | 749 | AltStdOutUI.cpp |
| 05/20/01 02:28p | 1,117 | AltStdOutUI.h |
| 06/01/01 04:06p | 13,978 | ExpectedGtorUI.cpp |
| 06/01/01 02:31p | 2,269 | ExpectedGtorUI.h |
| 05/26/01 09:08p | 8,740 | FQMtstUI.cpp |
| 05/26/01 08:49p | 2,505 | FQMtstUI.h |
| 05/27/01 10:19a | 1,096 | FQMtst_prj.cpp |
| 01/10/00 11:54a | 722 | MyWorkSheetV1.cpp |
| 06/04/01 08:26p | 17,782 | WorkSheet1_UI.cpp |
| 06/04/01 07:56p | 4,064 | WorkSheet1_UI.h |

Directory of source\Users\worknew\Specification_Zest\Iterations\Iteration2\TmX\itm\FQM\UI_stuff\externals

| | | |
|---|---|---|
| 05/25/01 10:58a | 444 | look_and_feel_xtras.cpp |
| 05/25/01 10:54a | 1,074 | look_and_feel_xtras.h |

Directory of source\Users\worknew\Specification_Zest\Iterations\Iteration2{cube root}TmX\itm\w32lcc

| | | |
|---|---|---|
| 07/06/01 03:08a | 354 | error_in_lil.c |
| 07/06/01 03:06a | 881 | itmtypetest1.C |
| 07/05/01 04:45p | 216 | itmtypetest1.h |
| 07/05/01 04:32p | 2,603 | TestItmW321cc.c |
| 07/06/01 02:43p | 66 | ToItm.c |

Directory of source\Users\worknew\Specification_Zest\Iterations\Iteration2\Tools

| | |
|---|---|
| 06/12/01 02:07p | 1,053 Unit1.cpp |
| 06/12/01 02:08p | 2,324 Unit1.h |

Directory of source\Users\worknew\Specification_Zest\Iterations\Iteration2\Tools\QuEditors

| | | |
|---|---|---|
| 06/12/01 10:08p | 3,908 | ItmQuUI.cpp |
| 06/12/01 10:00p | 2,577 | ItmQuUI.h |
| 06/12/01 02:10p | 655 | TestQuEditor1_prj.cpp |

Directory of source\Users\worknew\Specification_Zest\MTU_related

| | | |
|---|---|---|
| 11/08/99 10:31p | 3,945 | mover_as_slave_mode.cpp |
| 11/08/99 10:31p | 226 | mover_as_slave_mode.h |
| 11/08/99 10:31p | 522 | MTU_globals.cpp |
| 11/08/99 10:31p | 755 | MTU_globals.h |
| 11/08/99 10:31p | 718 | MTU_main.cpp |
| 11/08/99 10:31p | 2,565 | MTU_POST_self.cpp |
| 11/08/99 10:31p | 214 | MTU_POST_self.h |
| 11/08/99 10:31p | 666 | ParsedToBinary_prj.cpp |
| 11/08/99 10:31p | 728 | ParsedToBinary_UI.cpp |
| 11/08/99 10:31p | 1,482 | ParsedToBinary_UI.h |
| 11/08/99 10:32p | 525 | XL_MemoryMapUI.cpp |
| 11/08/99 10:32p | 830 | XL_MemoryMapUI.h |
| 11/08/99 10:32p | 662 | XL_memory_map_prj.cpp |

Directory of source\Users\worknew\Specification_Zest\MTU_related\TestVectors

| | |
|---|---|
| 11/08/99 10:31p | 2,273 ExportToDbaseUI.cpp |
| 11/08/99 10:31p | 1,347 ExxportToDbaseUI.h16403X |
| 11/08/99 10:31p | 663 ExportToDbase_prj.cpp |

Directory of source\Users\worknew\Specification_Zest\MTU_related\VC_develop

| | | |
|---|---|---|
| 06/08/00 01:11a | 6,917 | DBC0nnectionUI.cpp |
| 06/08/00 01:11a | 1,774 | DBC0nnectionUI.h |
| 11/08/99 10:31p | 3,026 | DumpForm1.cpp |
| 11/08/99 10:31p | 1,286 | DumpForm1.h |
| 12/16/99 06:08p | 1,455 | LogFormUI.cpp |
| 12/16/99 06:05p | 1,399 | LogFormUI.h |
| 11/08/99 10:31p | 970 | NetDumpListingUI.cpp |
| 11/08/99 10:31p | 1,169 | NetDumpListingUl.h |
| 11/08/99 10:31p | 1,408 | ScehmaCapture.cpp |
| 06/08/00 02:19a | 42,850 | SchemaBuild_UI.cpp |
| 06/08/00 02:19a | 5,824 | SchemaBuild_UI.h |
| 11/08/99 10:31p | 5,479 | SchemaBuild_UI0.h |
| 11/08/99 10:31p | 41,884 | SchemaBuild_UIx0.cpp |
| 06/08/00 01:35a | 3,494 | SchematicMasterUI.cpp |
| 06/08/00 01:35a | 1,995 | SchematicMasterUI.h |
| 11/08/99 10:31p | 1,129 | sketchUI.cpp |
| 11/08/99 10:31p | 941 | sketchUI.h |

Directory of source\Users\worknew\Specification_Zest\MTU_related\VC_develop\Tests

| | |
|---|---|
| 11/08/99 10:31p | 1,688 DualVF1.cpp |
| 11/08/99 10:31p | 1,382 DualVF1.h |
| 11/08/99 10:31p | 652 MultiView1_prj.cpp |

Directory of source\Users\worknew\Specification_Zest\MTU_related\Verilog

MTU verilog implentation

| | | |
|---|---|---|
| 11/08/99 10:32p | 3,240 | ALU1664.v |
| 11/08/99 10:32p | 3,612 | DPU_1664.v |
| 11/14/99 08:51a | 1,254 | DPU_1664_include.v |
| 11/14/99 09:13a | 2,959 | DPU_AGEN.v |
| 11/14/99 02:06p | 10,527 | DPU_CtlUnit.v |
| 11/14/99 11:07a | 9,208 | DPU_MISC.v |
| 11/11/99 05:30p | 3,906 | DPU_TEST_UNIT.v |
| 07/20/00 07:19p | 4,106 | DPU_TEST_UNIT_sim.v |
| 11/08/99 10:32p | 26,675 | DtaHldCtl..v |
| 11/08/99 10:32p | 3,884 | DtaOpUnit.v |
| 11/08/99 10:32p | 43,331 | eXecution_sequencer_comp.v |
| 11/08/99 10:32p | 5,972 | IfetchControl.v |
| 11/08/99 10:32p | 4,689 | OldTxUImplementation.v |
| 11/11/99 09:58a | 1,224 | Pkt40_include.v |
| 11/08/99 10:32p | 7,370 | Ref_DtaArbs.v |
| 11/08/99 10:32p | 1,858 | shifter.v |
| 06/29/00 10:08p | 2,514 | SimpleJTag1.v |
| 11/08/99 10:32p | 12,847 | SrcDcdModules.v |
| 11/08/99 10:32p | 2,923 | SrcDtaTester.v |
| 06/12/00 11:19a | 1,190 | template.v |
| 11/08/99 10:32p | 2,703 | template_DtaHldCtl..v |
| 11/08/99 10:32p | 8,595 | Tester_eXecution_sequencer.v |
| 11/08/99 10:32p | 50 | test_values.v |
| 11/08/99 10:32p | 2,743 | TxUCodeTester.v |
| 11/08/99 10:32p | 3,476 | TXU_ALU.v |
| 11/08/99 10:32p | 5,936 | TxU_BufAdr.v |
| 11/08/99 10:32p | 10,760 | TxU_cmd_module.v |
| 11/08/99 10:32p | 3,933 | TxU_DataPath.v |
| 11/08/99 10:32p | 22,207 | TxU_Decode_ver2.v |
| 11/08/99 10:32p | 3,884 | TXU_DtaBfBlk.v |
| 11/08/99 10:32p | 1,265 | TXU_external.v |
| 11/08/99 10:32p | 4,703 | TxU_FinalTestVersion.v |
| 11/08/99 10:32p | 4,494 | TXU_implemetation.v |
| 11/08/99 10:32p | 31,323 | TXU_implemetation_big0.v |
| 11/08/99 10:32p | 32,308 | TXU_implemetation_big0orig.v |
| 11/08/99 10:32p | 54,259 | TXU_implemetation_old.v |
| 11/08/99 10:32p | 43,245 | TXU_implemetation_preSymplify.v |
| 11/08/99 10:32p | 4,068 | TXU_imp_for_SrcDta_tester.v |
| 11/11/99 05:33p | 2,762 | TxU_RAMs.v |
| 11/08/99 10:32p | 790 | TXU_RAMs_mdl.v |
| 11/08/99 10:32p | 10,102 | TXU_reference_buffer with_logic.v |
| 11/08/99 10:32p | 1,607 | TXU_tester.v |
| 11/08/99 10:32p | 11,813 | TxU_unit.v |
| 11/08/99 10:32p | 12,608 | TxU_UnitTester.v |
| 11/08/99 10:32p | 2,518 | XinBlk0.v |
| 11/08/99 10:32p | 6,885 | Xtrnl_iface.v |

Directory of source\Users\worknew\Specification_Zest\MTU_related\Verilog\models

| | |
|---|---|
| 03/05/99 08:11a | 10,214 mt58164132f.v |
| 03/05/99 10:50a | 6,505 test.v |

Directory of source\Users\worknew\Specification_Zest\NewCpp

| | |
|---|---|
| 01/05/01 11:56a | 191 testcpp1.c |

Directory of source\Users\worknew\Specification_Zest\NewCpp\builderCpp

| | |
|---|---|
| 01/04/01 05:42p | 921 BlderUI.h |
| 01/04/01 03:46p | 136 testcpp1.c |

Directory of source\Users\worknew\Specification_Zest\NewCpp\cpp

| | | |
|---|---|---|
| 01/04/01 05:18p | 6,275 | cpp.c |
| 01/05/01 12:43a | 1,151 | getopt.c |
| 01/05/01 11:40a | 2,853 | include.c |
| 01/05/01 10:45a | 15,764 | lex.c |
| 01/05/01 12:57a | 143 | NewCpp.c |
| 01/04/01 05:23p | 76 | NewCpp.h |
| 01/05/01 12:50a | 2,701 | nlist.c |

Directory of source\Users\worknew\Specification_Zest\NewCpp\LCCcpp

| | | |
|---|---|---|
| Jan. 31, 2002 03:59 p | 6,493 | CPP.C |
| Feb. 04, 2002 07:14 a | 1,252 | CtoHtm11.awk |
| Feb. 04, 2002 05:00 a | 249 | FLEXC.h |
| Jan. 05, 2001 12:43 a | 1,151 | getopt.c |
| Jan. 05, 2001 11:40 a | 2,853 | include.c |
| Feb. 04, 2002 04:58 a | 158 | IvstSysIF_1_CSL.c |
| Feb. 04, 2002 07:25 a | 16,915 | lex.c |
| Jan. 05, 2001 12:57 a | 143 | NewCpp.c |
| Jan. 04, 2001 05:23 p | 76 | NewCpp.h |
| Jan. 05, 2001 12:50 a | 2,701 | nlist.c |
| Jan. 30, 2002 01:59 a | 648 | specdef.c |
| Jan. 30, 2002 10:59 p | 405 | temp1.c |

Directory of source\Users\worknew\Specification_Zest\SHRAM_related

| | |
|---|---|
| Nov. 08, 1999 10:32 p | 668 channel_master.v |

Directory of source\Users\worknew\Specification_Zest\Units

| | |
|---|---|
| Nov. 17, 1999 08:14 p | 525 UnitExplorerUI.cpp |
| Nov. 17, 1999 08:50 p | 810 UnitExplorerUI.h |
| Nov. 18, 1999 03:17 p | 527 UnitExplorer_prj.cpp |
| Nov. 18, 1999 03:17 p | 814 UnitExplorer_prj.h |
| Nov. 18, 1999 03:18 p | 664 UnitExplorer_Prj0.cpp |

Directory of source\Users\worknew\Specification_Zest\Verilog

| | |
|---|---|
| Feb. 10, 2003 06:09 p | <DIR> PLI |
| Nov. 08, 1999 10:32 p | 6,667 SimpleStimulus.v |

Directory of source\Users\worknew\Specification_Zest\Verilog\PLI

| | | |
|---|---|---|
| Nov. 08, 1999 10:32 p | 21,722 | ACC_USER.H |
| Nov. 08, 1999 10:32 p | 6,171 | EXT_USER.H |
| Nov. 08, 1999 10:32 p | 1,019 | PLI01.C |
| Nov. 08, 1999 10:32 p | 727 | PLI01.V |
| Nov. 08, 1999 10:32 p | 1,683 | PLI_tester.cpp |
| Nov. 08, 1999 10:32 p | 15,534 | VERIUSER.H |

Directory of source\Users\worknew\Specification_Zest\VMC_Related

| | | |
|---|---|---|
| Nov. 08, 1999 10:32 p | 578 | AddBlock_dmdl.cpp |
| Nov. 08, 1999 10:32 p | 929 | AddBlock_dmdl.h |
| Nov. 08, 1999 10:32 p | 5,848 | AddBlock_UI.cpp |
| Nov. 08, 1999 10:32 p | 1,665 | AddBlock_UI.h |
| Nov. 08, 1999 10:32 p | 2,808 | BitBlock.cpp |
| Nov. 08, 1999 10:32 p | 204 | BitBlock.h |
| Nov. 08, 1999 10:32 p | 566 | ComponentlnfoRpt.cpp |
| Nov. 08, 1999 10:32 p | 1,196 | ComponentInfoRpt.h |
| Nov. 08, 1999 10:32 p | 1,525 | ComponentInfoRpt.UI.dpppp |
| Nov. 08, 1999 10:32 p | 839 | ComponentInfo_prj.cpp |
| Nov. 08, 1999 10:32 p | 387 | RootsInC.cpp |
| Nov. 08, 1999 10:32 p | 480 | RootsInC.h |
| Nov. 08, 1999 10:32 p | 682 | RootTesterPrj.cpp |
| Nov. 08, 1999 10:32 p | 523 | RootTesterUI.cpp |
| Nov. 08, 1999 10:32 p | 757 | RootTesterUI.h |
| Nov. 08, 1999 10:32 p | 567 | SourceReport_QR.cpp |
| Nov. 08, 1999 10:32 p | 1,237 | SourceReport_QR.h |
| Nov. 08, 1999 10:32 p | 597 | source_block.cpp |
| Nov. 08, 1999 10:32 p | 1,005 | source_block.h |
| Nov. 08, 1999 10:32 p | 1,675 | source_block_dmdl.cpp |
| Nov. 08, 1999 10:32 p | 1,103 | source_block_dmdl.h |
| Nov. 08, 1999 10:32 p | 3,287 | source_block_editor.cpp |
| Nov. 08, 1999 10:32 p | 2,227 | source_block_editor.h |
| Nov. 08, 1999 10:32 p | 532 | Specification_Tool_UI.cpp |
| Nov. 08, 1999 10:32 p | 775 | Specification_Tool_UI.h |
| Nov. 08, 1999 10:32 p | 563 | VMC_block_browser_dmdl.cpp |
| Nov. 08, 1999 10:32 p | 1,587 | VMC_block_browser_dmdl.h |
| Nov. 08, 1999 10:32 p | 1,796 | VMC_block_browser_prj.cpp |
| Nov. 08, 1999 10:32 p | 801 | VMC_block_browser_QR.cpp |
| Nov. 08, 1999 10:32 p | 1,754 | VMC_block_browser_QR.h |
| Nov. 08, 1999 10:32 p | 1,493 | VMC_block_browser_UI.cpp |
| Nov. 08, 1999 10:32 p | 1,709 | VMC_block_browser_UI.h |
| Nov. 08, 1999 10:32 p | 5,071 | VMC_root_def.cpp |
| Nov. 08, 1999 10:32 p | 212 | VMC_root_def.h |
| Nov. 08, 1999 10:32 p | 708 | VMC_Specification_Tool_prj.cpp |

Directory of source\Users\worknew\Specification_Zest\VMC_Related\VMCtoDB\Source

| | | |
|---|---|---|
| Nov. 08, 1999 10:32 p | 4,248 | CopyToDB.cpp |
| Nov. 08, 1999 10:32 p | 1,821 | CopyToDB.h |
| Nov. 08, 1999 10:32 p | 546 | UnitPrintDB.cpp |
| Nov. 08, 1999 10:32 p | 1,299 | UnitPrintDB.h |
| Nov. 08, 1999 10:32 p | 536 | UnitSCode.cpp |
| Nov. 08, 1999 10:32 p | 914 | UnitSCode.h |
| Nov. 08, 1999 10:32 p | 916 | VMCtoDB.cpp |
| Nov. 08, 1999 10:32 p | 11,990 | VMCtoDBFuncs.cpp |
| Nov. 08, 1999 10:32 p | 487 | VMCtoDBFuncs.h |

Directory of source\Users\worknew\Specification_Zest\Welder\Iteration1\LccRelated\Symbols

| | | |
|---|---|---|
| Oct. 23, 2000 12:04 a | 1,966 | alloc.c |
| Oct. 23, 2000 12:46 a | 19,879 | c.h |
| Nov. 12, 2000 03:16 a | 22,945 | dag.c |
| Nov. 12, 2000 03:52 a | 53,898 | dagcheck.c |
| Oct. 23, 2000 12:46 a | 3,129 | error.c |
| Nov. 12, 2000 03:29 a | 23,064 | lex.c |
| Nov. 12, 2000 03:32 a | 352 | OtherPieces.cpp |
| Oct. 23, 2000 12:48 a | 3,503 | output.c |
| Oct. 23, 2000 12:01 a | 4,524 | string.c |
| Oct. 23, 2000 12:24 a | 7,429 | sym.c |
| Oct. 23, 2000 12:56 a | 868 | symbol_tst_prj.cpp |
| Oct. 23, 2000 01:15 a | 1,329 | symbol_tst_UI.cpp |
| Oct. 22, 2000 10:46 p | 987 | symbol_tst_UI.h |
| Oct. 23, 2000 12:35 a | 22,001 | types.c |

Directory of source\Users\worknew\Specification_Zest\Welder\Tests

| | |
|---|---|
| Oct. 18, 2000 01:30 p | 725 DrawTest_prj.cpp |
| Oct. 18, 2000 07:28 p | 1,936 draw_test_UI.cpp |
| Oct. 18, 2000 07:27 p | 1,182 draw_test_UI.h |

Directory of source\Users\worknew\SupportTools

| Nov. 08, 1999 10:32 p | 831 ReportViewImageMain0_prj.cpp |
|---|---|
| Nov. 08, 1999 10:32 p | 537 ReportViewImageQR.cpp |
| Nov. 08, 1999 10:32 p | 1,001 ReportViewImageQR.h |
| Nov. 08, 1999 10:32 p | 534 ReportViewWithDiagramUI.cpp |
| Nov. 08, 1999 10:32 p | 946 ReportViewWithDiagramUI.h |
| Directory of source\Users\worknew\TeamWork\cell_t\Stephen | |
| Jul. 06, 2001 02:51 a | 12,982 Itm.h |

Directory of source\Users\worknew\TeamWork\cell_t\stephen\cel_t

| | | |
|---|---|---|
| 08/27/01 06:36p | 6,618 | CEL_ADD.C |
| 08/28/01 07:07a | 7,377 | cel_core.c |
| 08/27/01 11:12a | 4,554 | Cel_mpy.c |
| 08/28/01 12:33p | 892 | cel_t.h |
| 08/27/01 10:09a | 406 | cel_test_add.h |
| 08/27/01 07:18a | 2,012 | cel_t_testing.c |
| 11/20/01 03:57a | 6,135 | sequence.c |

Directory of source\Users\worknew\TeamWork\LiteratePrograming

| | | |
|---|---|---|
| 01/06/02 10:32a | 5,318 | CandML1.awk |
| 01/14/02 07:48a | 7,306 | SortTypeDefs.awk |

Directory of source\Users\worknew\TestVectors\C_CodeVersion

| | | |
|---|---|---|
| 11/08/99 10:32p | 1,995 | spread_sheet_form.cpp |
| 11/08/99 10:32p | 1,274 | spread_sheet_form.h |
| 11/08/99 10:32p | 663 | Test_Vector_Run.cpp |

### DETAILED DESCRIPTION OF THE INVENTION

Embodiments and aspects of the invention may be embodied in various forms;

broadly as is presented in the Summary section, pedagogically as is presented in the remaining figures, and in actual best currently enabled form as is presented in the Appendix. Kindly note, the term “TmX”, as used herein, substantially relates to “some embodiments according to the present invention”.

Particularly, FIGS. 1-5 relate to principle DDOPCASS embodiments, wherein

FIG. 1 shows a schematic view of a DDOPCASS;

FIG. 2 shows a schematic view of a DDOPCASS appurtenance;

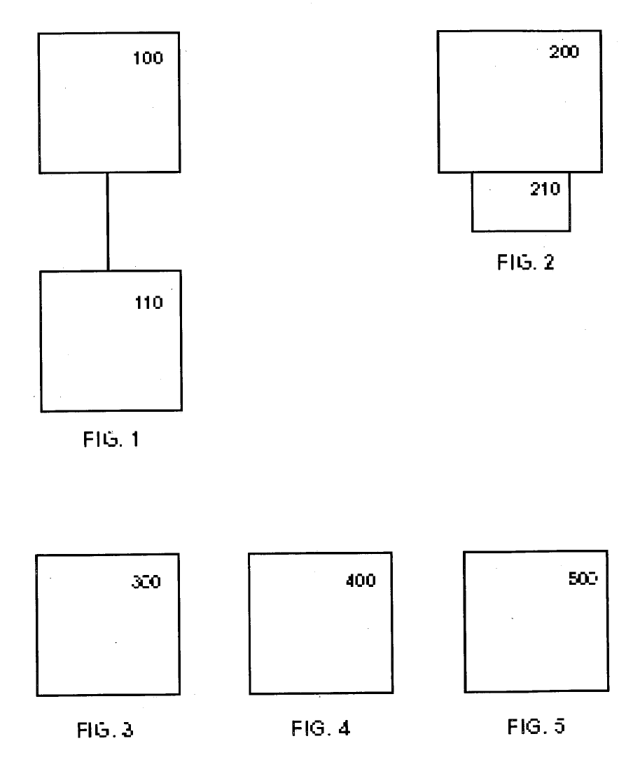

FIG. 3 shows a schematic view of a DDOPCASS related article of manufacture;

FIG. 4 shows a schematic view of a DDOPCASS related program storage device; and

FIG. 5 shows a schematic view of another DDOPCASS related program storage device;

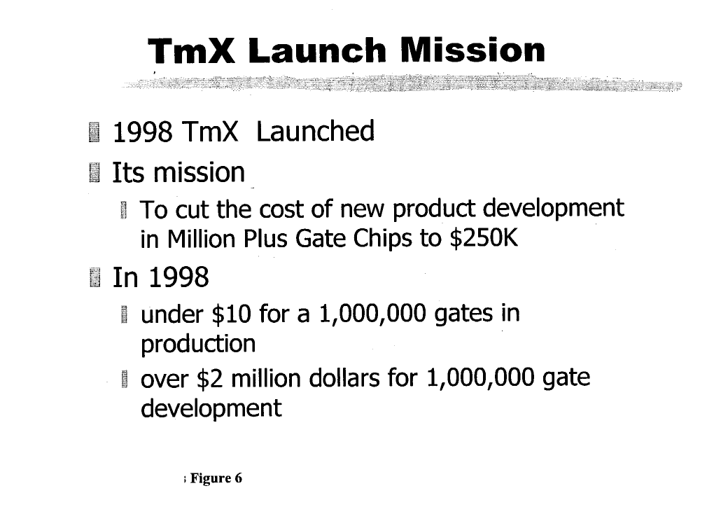

FIGS. 6-9 relate to slides illustrating the reasons driving the creation of DDOPCAS\TMX architecture, wherein:

FIG. 6 TmX Launch Mission

In 1996, the time of the start of TmX's architecture design , raw computing power was very cheap, and it has only gone down since then—it cost under $10 to produce a chip with 1 million logic gates. However, the cost of developing the same chip exceeded $2 million. The earliest ASICs were developed by teams that would now be considered small for even a software development team, let alone a hardware team, but the complexity of the new devices meant that not one but several hardware experts were needed, each with his own increasingly specialized field of knowledge and support team, in addition to the people who would somehow have to put it all together and make it work. Inevitably, with such complex chips, there were multiple bugs in the testing stage, and each bug took weeks to fix.

All of this was happening in a market where technology advances were constantly being made. With all the time and expense that went into developing a product, the product was likely to have a very short shelf life in which to earn back this investment—if it ever found a market at all.

Under these conditions, investment is perilous. A market where any product requires millions of dollars in investment before there is any chance of return is more friendly to monopolies than it is to competition, and more friendly to ultra-high volume than to niche market products. Ultimately, it will become a market unrewarding to real innovation.

TmX was founded in order to cut development time and costs. Our goal was to bring the advances in semiconductor manufacturing to a wider market by taking advantage of the wealth of raw processing power and storage which has arrived since 1998 and will only continue to expand.

The components and tools developed for TmX architecture will allow manufacturers to produce more powerful systems, and enable smaller teams to design more products in less time for less money. In addition to improving current systems, TmX technology has the potential to create new markets, and indeed, to initiate the next great stage in the evolution of computers.

The mission that TmX took upon itself in 1998 has become even more urgent. What was a $1 million development effort in 1995 cost $3 million by 2002, and is expected to rise to $7 million by 2005. The promise of Moore's law has become a trap—cuts in the cost of production are being equaled or exceeded by rises in the cost of development. If this continues, profitable innovation will become extremely elusive. If it can be reversed, the technology market will undergo a new renaissance.

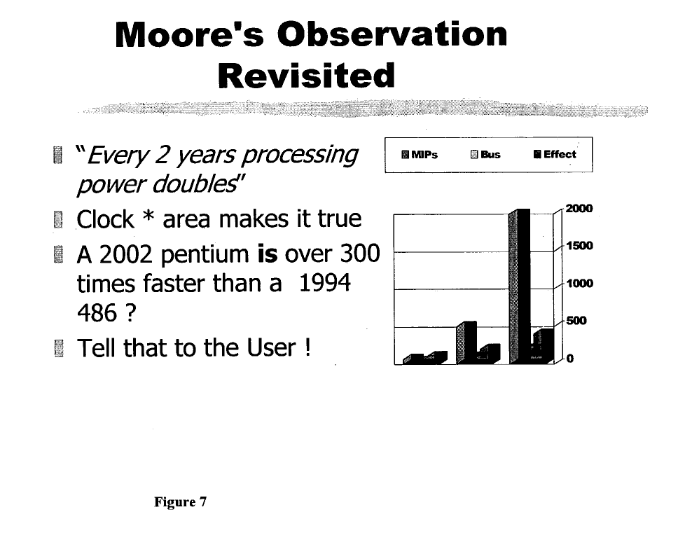

FIG. 7 Moore's Observation Revisited

In 1965, Gordon Moore, co-founder of Intel, stated that the number of transistors per square inch on integrated circuits had doubled every year since the integrated circuit was invented. What has by now come to be known as “Moore's Law” was originally intended only as an observation of the development in computers he had seen until that point. And yet, despite reformulations that now give an eighteen-month or two-year doubling time, it has held remarkably true. True, that is, in an absolute sense.

A 2002 pentium is over 300 times faster than a 1994 486. Meanwhile, the user of these computers could be excused for assuming that the improvement has been only one-hundredth of that. And if the user never sees the benefit from Moore's law, he will no longer continue to pay for the new products that fund the research that perpetuates that law.

Is Moore's law fated to hit a wall, not of physical impossibility, but of simple improfitability? Why does the giant leap explicit in Moore's law become a small step for the user?

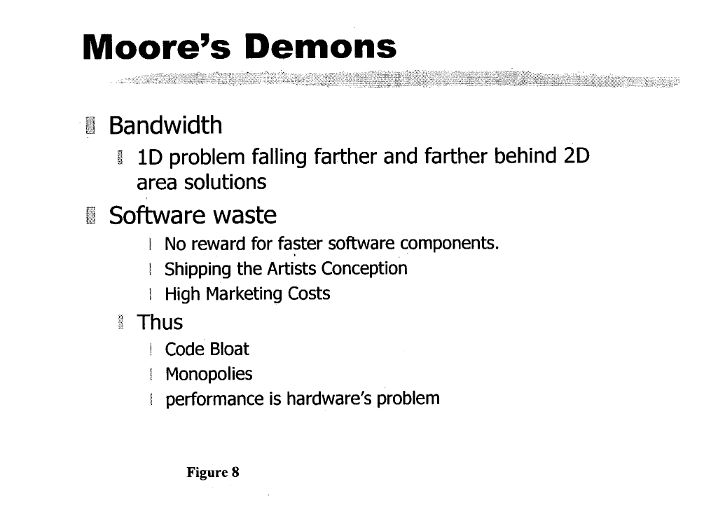

FIG. 8 Moore's Demons

One reason that Moore's law has not resulted in a corresponding increase in productivity is a simple, physical one. Moore's law relies on the doubling of the number of transistors per square inch, which is a property of area. But data is transferred along a one-dimensional path. Thus, while processing power has doubled every two years, the rate of data transfer has only gone up by the square root of two in a similar period. This means that the rate of data transfer has been falling farther and farther behind—and because of this, the gains' in processing power are significantly reduced. And if the improvements in the rate of transfer have been less than dramatic, the improvements in latency—the time it takes to locate a piece of information, before transfer can begin—have been even worse. The D-RAM cycle time, which is the dominant mass memory, has only improved by a factor of two or three in the last ten years.

Meanwhile, over the years, software development and the way it is funded has grown complacent in the performance increases guaranteed by hardware. Up to somewhere in the middle 1990's, software could safely rely on hardware to compensate for its deficiencies. However, with the widening gap between capacity and bandwidth, this complacency is no longer justified.

FIGS. 8 to 15 relate to slides defining the initial best application of TMX Architecture, wherein:

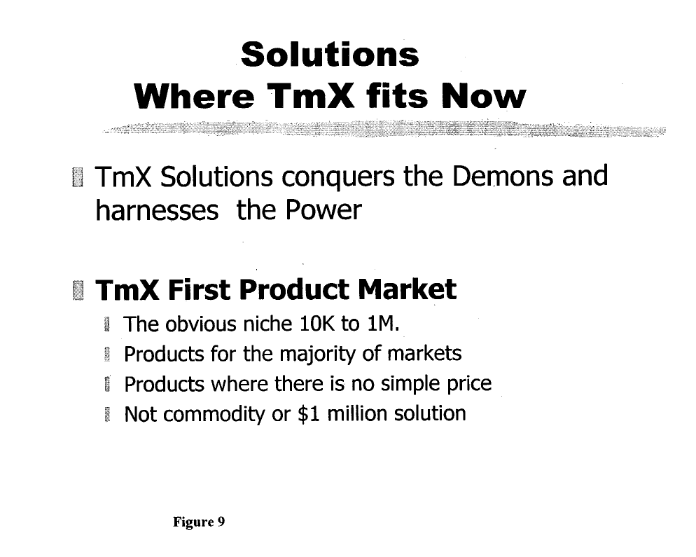

FIG. 9 Solutions—Where TmX Fits Now

TmX can, in a large part, solve these problems. In doing so, we have created hardware components and development tools for embedded systems that are highly programmable and yet are free of the price and performance issues that have limited the market for current programmable solutions.

The first market that we address is manufacturers of systems with 10K to 1 million product volume. Although this market is not the largest as far as dollars, or even number of products sold, nevertheless it is the largest as far as the number of distinct markets it encompasses. And it is precisely these markets which are the most threatened by increasing design costs for diminishing meaningful improvements.

For “commodity” products, even a very high development cost—when divided by the volume of products produced—becomes insignificant. In this market, the most important thing is keeping production cost down. On the other hand, very high-priced, low-volume products can swallow the high production cost of current programmable components with relative ease. It is in the majority of products, which find themselves between these two extremes, where TmX finds its niche. It is a niche which is increasingly becoming a chasm.

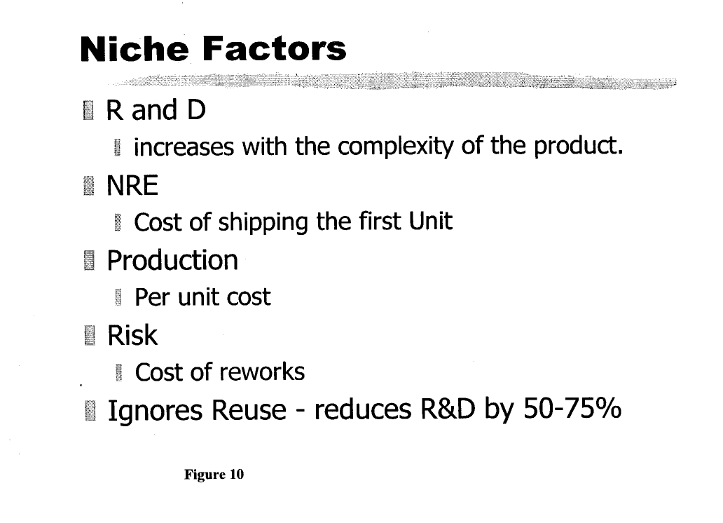

FIG. 10 Niche Factors

In analyzing how TmX compares to its competitors, we calculate how much it costs to develop and produce 10K, 100K, and 1M units of an x-gate system using ASICs, FPGAs, and TmX.

There are four factors factors which we will consider when calculating this cost. R&D comprises all the development necessary before a production version of the product can be made, and this cost rises with the complexity of the product. NRE includes all additional costs from the point where R&D ends until the first unit is actually shipped. The other factors we take into account are the production cost of each unit, and the cost of risk—that is, the cost of reworks made necessary by either defects in device operation or market changes.

One factor we do not take into account, in order to simplify our calculations, is the savings in development cost that becomes possible with reusing previous or external development. However, TmX components are especially designed to allow seamless integration of intellectual property from diverse sources even more easily than ASICs or FPGAs,

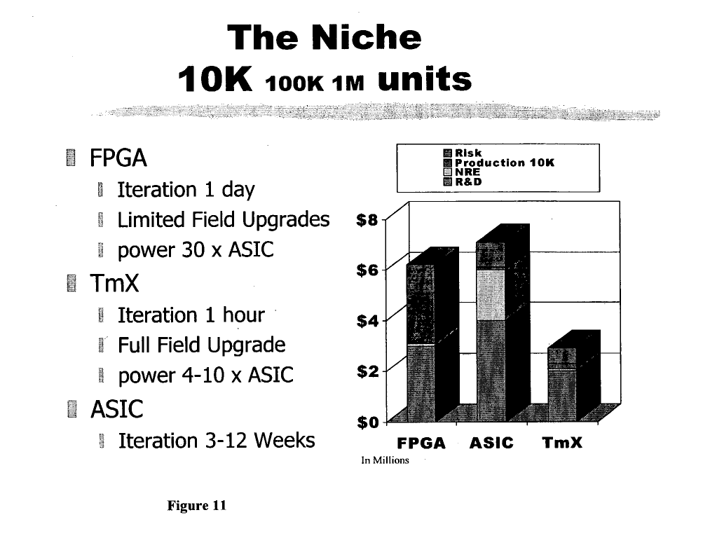

FIG. 11 The Niche—10K Units

On the 10K side of the niche, the FPGA emerges as the better of the existing solutions. The high production cost is offset by the low NRE and relatively low R&D costs. TmX, however, is the clear winner. With NRE costs comparable to those of an FPGA, production costs much closer to an ASIC, and R&D costs significantly lower than either, making 10K products with TmX is about half of the price of making them with FPGAs.

There are other factors to consider. For performance, an ASIC still beats either of the programmable solutions, but whereas an FPGA will use 30 times the power of an ASIC, TmX uses only 4-10 times. Furthermore, although FPGAs are touted as being field-programmable, the truth is that they can be only partially upgraded in the field, whereas TmX can be fully upgraded. ASICs, of course, cannot be upgraded at all.

One of the main factors which make development costly and time-consuming is the iteration time—that is, the amount of time it takes to correct a bug, add a feature, or make any change in a component. For an ASIC, this can take 3-12 weeks. For the FPGA, it takes a day. For TmX, only an hour.

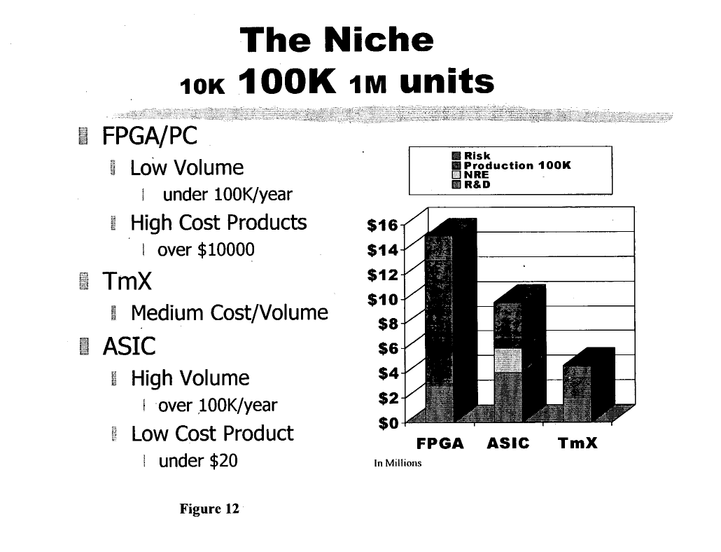

FIG. 12 The Niche—100K Units

Just as ASICs are the natural solution for a high-volume, low cost product, and FPGAs do reasonably well for low-volume, high cost products, the middle range is TmX's home territory. Looking at the figures for a 100K production, right in the middle of TmX's market niche, its advantages over the competitors are clear. The high cost of producing FPGAs, at this volume, eliminates them as serious competition. In the meantime, the ASIC's low production cost is still not enough to offset the high R&D and NRE costs. Another thing that makes ASICs impractical at this level is the risk—the cost of releasing a new version or update in response to market pressure.

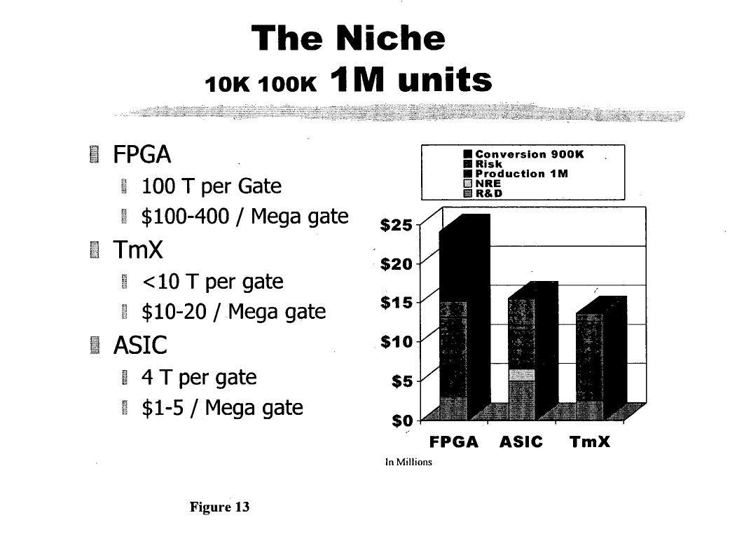

FIG. 13 The Niche—1M Units

When production volume reaches 1 million units, the factor that begins to assume primary importance is keeping down production costs. The critical factor is how many transistors are required to make a logic gate. This market is the beginning of ASIC territory, although at 1 million units, the risk is still enough of a factor to make TmX the winner even here. The only way that the FPGA can even be considered is to make only the first 100K units with FPGAs, and then make the conversion to ASICs.

Many products are indeed made this way, and this method can be applied to TmX, although the initial production with TmX would typically be higher. Once the first three million units are made with TmX, it would probably be time to make the conversion to ASICs.

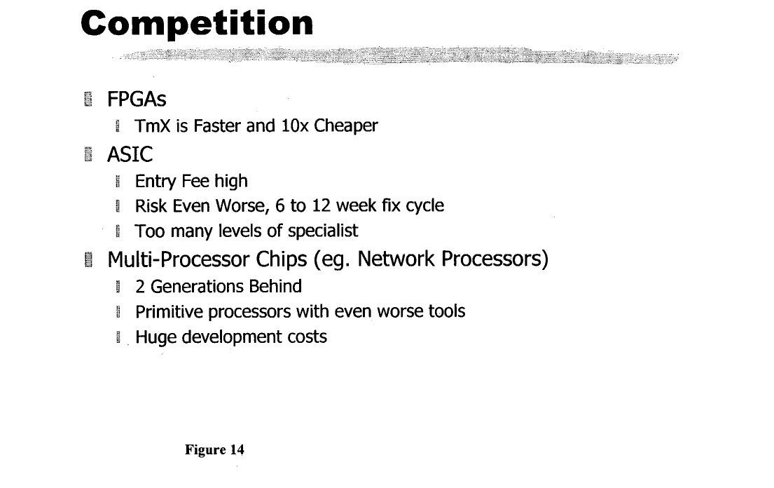

FIG. 14 Competition

In short, when we compare TmX to existing solutions, TmX's advantages immediately become clear.

FPGAs are plagued by high production costs and poor performance. Nevertheless, the market for programmable logic devices—of which FPGAs are the most prominent—was estimated at $3 billion in 2000, and has been growing steadily. This only indicates how hungry the market has been for solutions which can be produced at medium to low volume, which can be designed without massive R&D budgets, and which can be shipped quickly. TmX can deliver all of these things, at one-tenth of the cost of an FPGA, and with significantly better performance.

ASICs are very powerful and almost trivially cheap to produce. And yet, before even beginning production, the manufacturer must spend at least $5 million on R&D and NRE. In order to make back this investment, the product must be shipped, but any mistakes can set the release date back 6 to 12 weeks, not once but many times. Most markets cannot bear this sort of risk. TmX offers a solution to these problems, while remaining affordable and high-performance.

Another problem with ASICs is that, as they have gotten more complex, designing them has required ever-increasing specialization. Modem ASICs often require not one but several hardware experts, each with his own field of knowledge and support team. With TmX's simplified architecture and design tools, an entire system can be designed by a small, software-trained team. The result is lower development cost and improved product efficiency and focus. At the same time, specialists can make modifications on a hardware level without needing additional tools.

One competitor that has not been mentioned is the multi-processor chip. In some ways, the multi-processor chips currently available resemble TmX in both design and ambition. However, these chips are about two generations behind TmX, and have managed to combine the poor performance of FPGAs with the arcane design process of ASICs. Unable to reduce development costs, they have not been able to find much of a market.

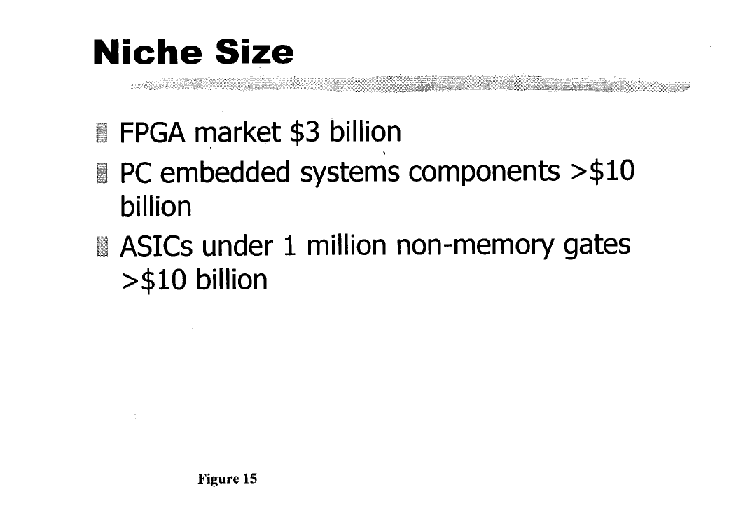

FIG. 15 Niche Size

We can estimate the size of TmX's niche based on the market size for the competitors listed above. The FPGA market has been estimated at $3 billion, whereas the markets for PCs in embedded systems and for ASICs under one billion non-memory gates are over $10 billion each. If we can capture just 10% of these markets, the word “niche” suddenly starts to-look inappropriately narrow.

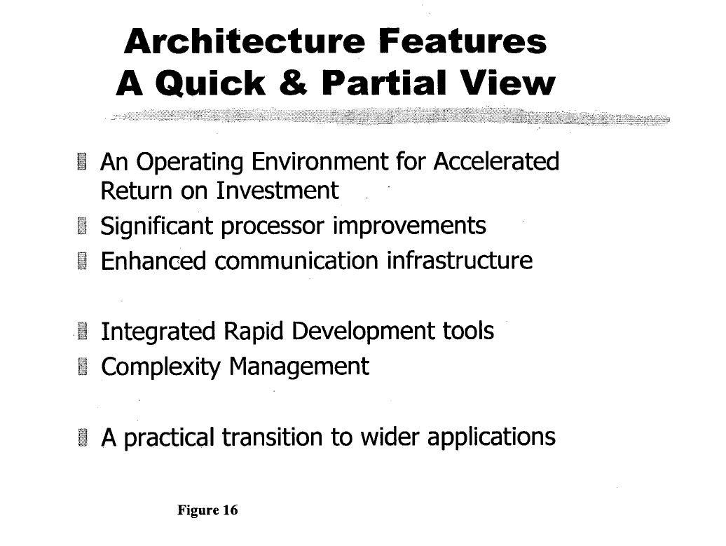

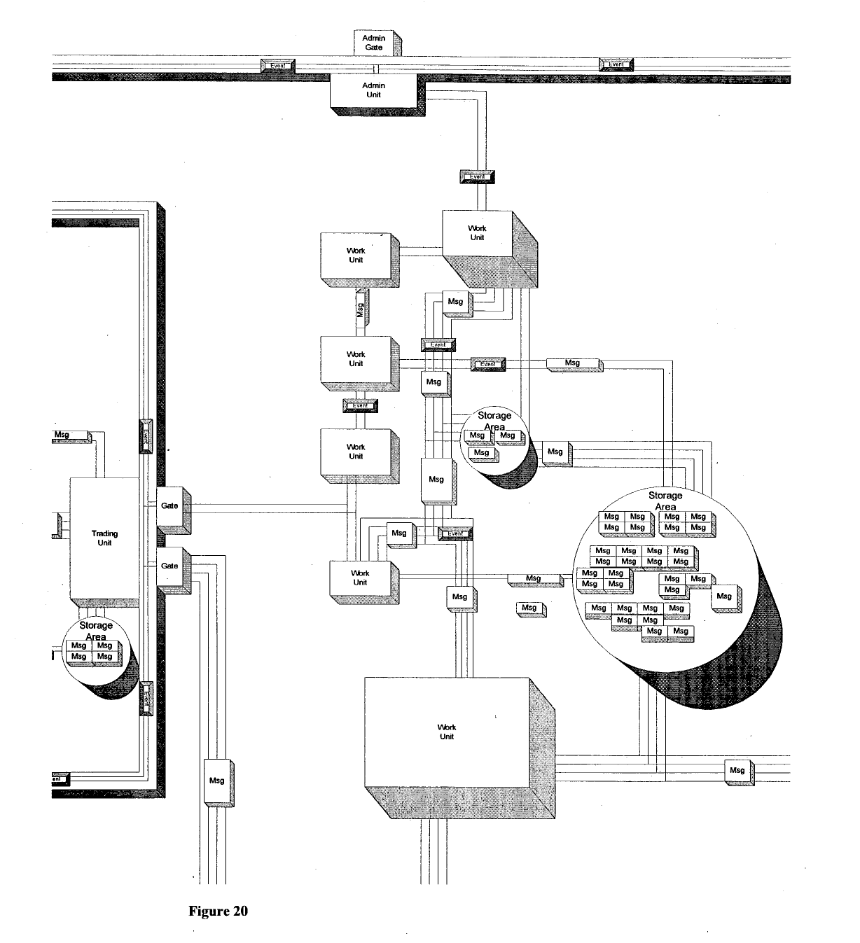

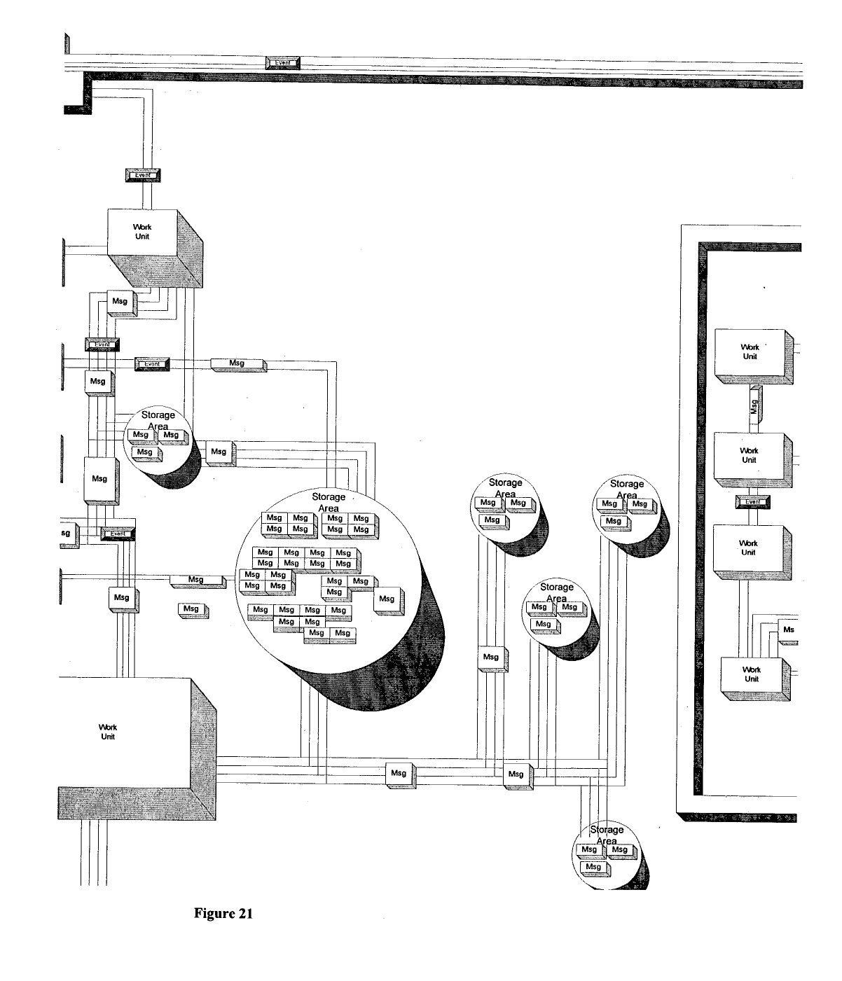

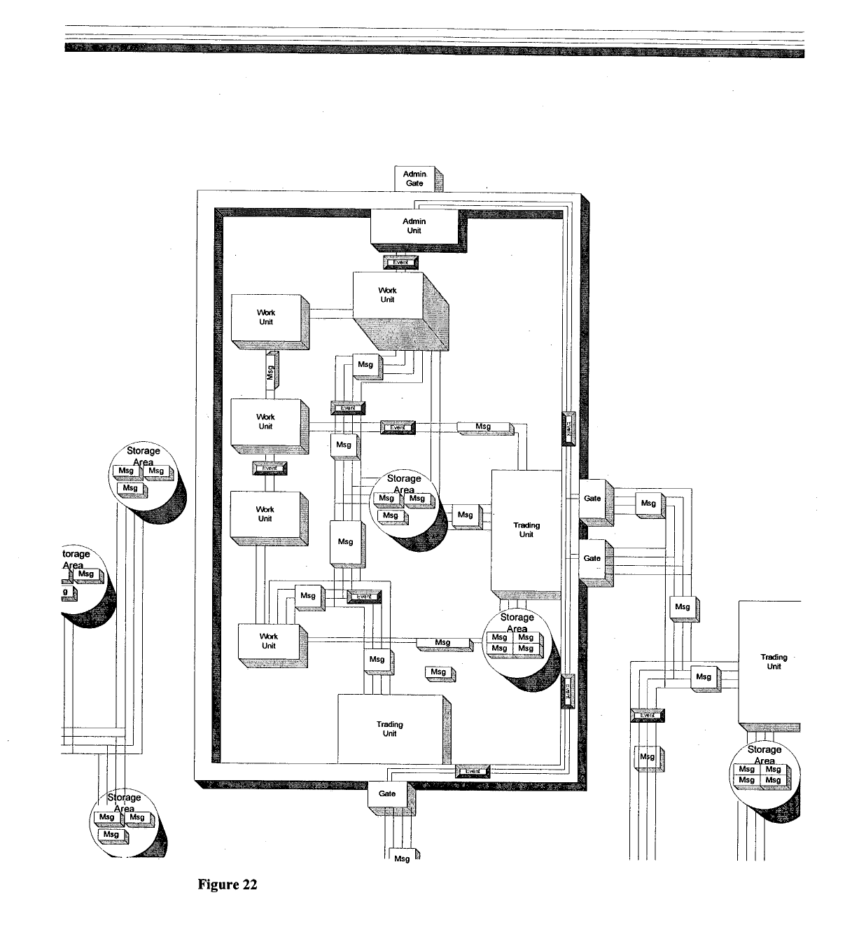

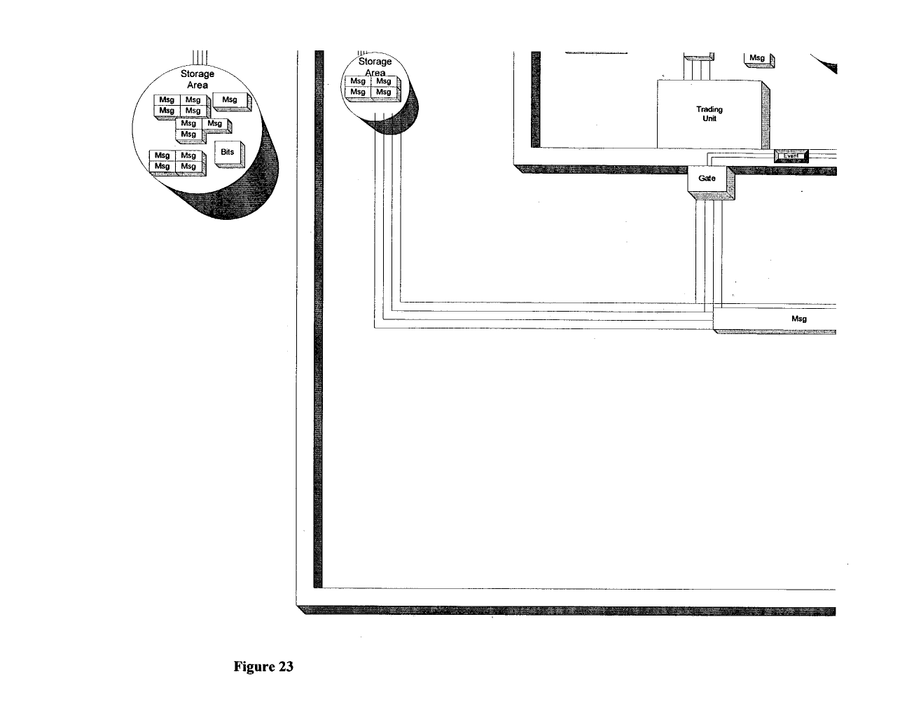

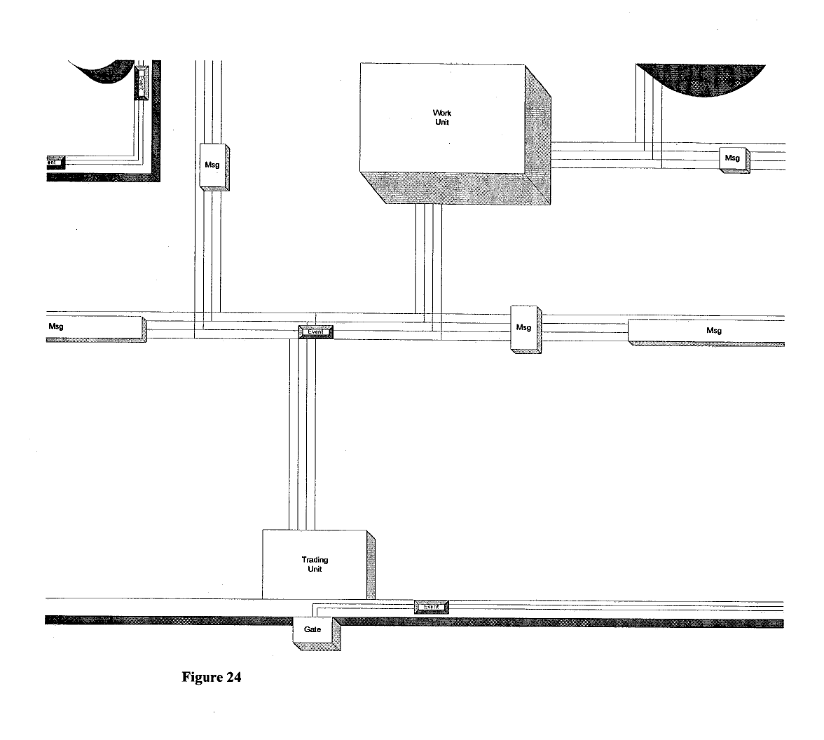

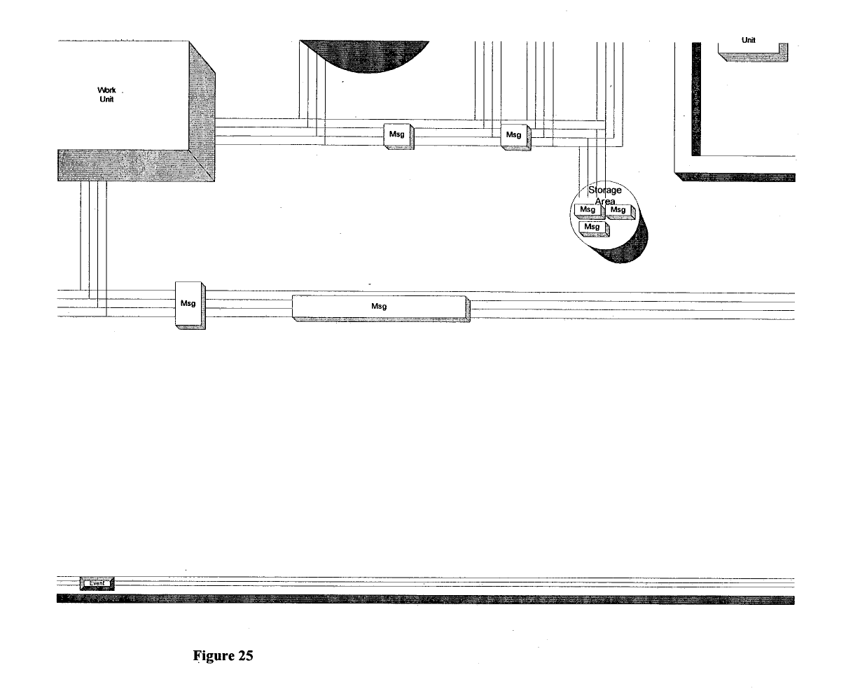

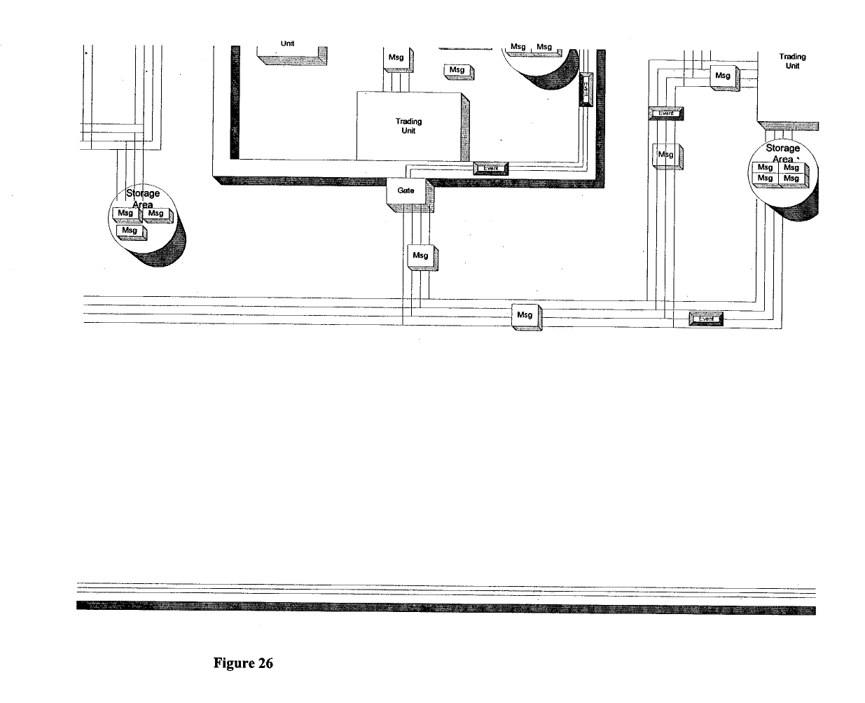

FIG. 16 to 37 relate to slides of an overview of the logical architecture.

FIG. 16 Architecture Features—A Quick & Partial View

Creating a successful new architecture is not just a case of producing a better CPU and assuming that the world will beat a path to your door. We have seen what happens when the focus in developing hardware tools is simply on increasing the available power and not on using that power intelligently. The features of TmX architecture—improved emulation of hardware in software, enhanced communications, quicker memory access—are focused on making development using TmX quicker, less expensive, and more profitable. What TmX provides is a mechanism by which every contributor to the system is able to gain. Our test for whether the architecture we had created was truly an improvement was whether it increased the return on investment for all parties. Our architecture passes this test.

Of course, an indispensable aspect of any tool is being able to use it. We have developed not only an improved architecture, but also tools to develop systems using this architecture. In developing tools for handling the complexity of modem systems, we had two goals: The tools had to be simple enough to allow a small team, composed of non-specialists, to develop an entire system, and yet they had to be powerful and flexible enough to allow a specialist to optimize the system on a hardware level.

No technology can suddenly require everybody to rewrite everything from scratch. The most successful technologies are ones that do not require people to throw out the tools they already own, but which, instead, can be used alongside those tools, even enhancing their performance. An example of this is Windows 3.1. By allowing DOS applications to run on Windows, Windows was able to attract customers who had no desire to give up programs that they were used to and which worked well for them.

TmX is designed to be used with current technology, so that people can use bits and pieces of TmX technology—whichever suits their needs—while retaining their current system. This will allow a rapid and smooth transition to TmX.

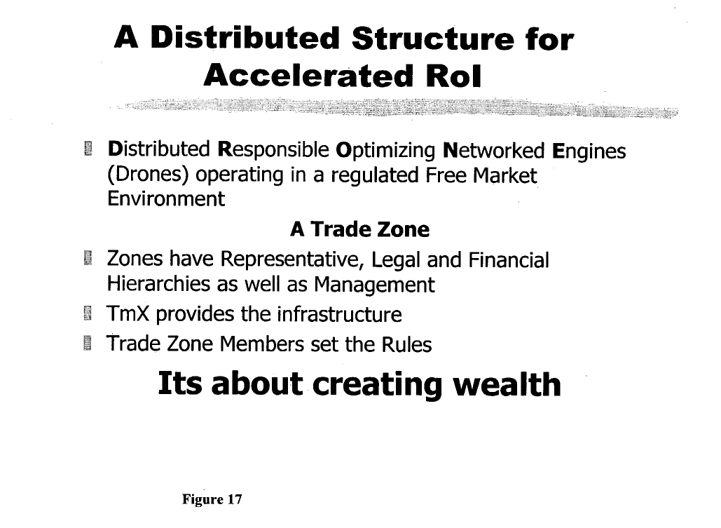

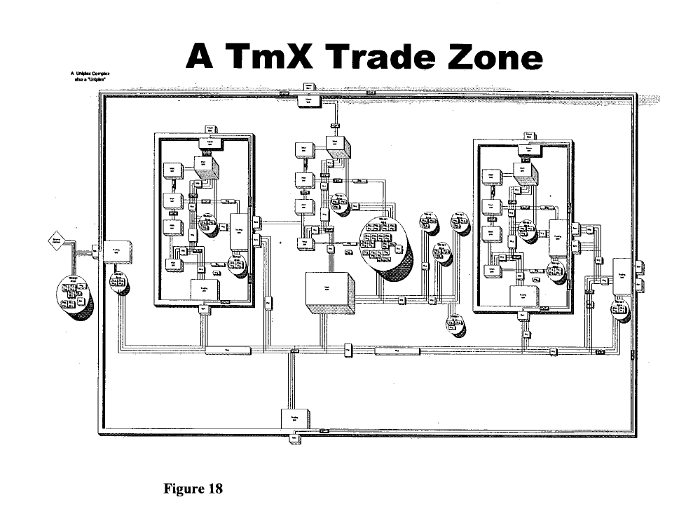

FIG. 17 A Distributed Structure for Accelerated RoI

TmX units are dynamically self-optimizing—that is, instead of a single processor, or multiple processors with little coordination between them, individually going through a series of tasks in the order in which they have been programmed to do, a TmX unit can assign any system resource to any task on a second-to-second basis. Although our innovations in system architecture make this possible, they do not answer a fundamental question. How will these units make their decision? What is the mechanism by which an owner of a TmX system can set his priorities and ensure that the operations of his system accord with those priorities?

In setting up a logic for the self-optimization of TmX systems, we had no desire to re-invent the wheel. Rather than come up with an elegant system and hope it worked in circumstances we could not foresee, we decided to use a model that has proven its ability to work in the messy everyday world and to continue to function despite every challenge that has been thrown at it and every new technology it has had to adapt—in other words, the free market.

A fully functional operator in this market—one which is backed by a responsible human, as well as having the ability to calculate the profitability of a transaction, keep track of the flow of funds, and play by the rules—is known as a drone: a Distributed Responsible Optimizing Networked Engine. A drone provides a service, which is used either by other drones or, ultimately, by the user. The drones have limited freedom of action to select the best method to accomplish their tasks. They will attempt to use the least expensive solution, as it is calculated in Arbitration Units (AUs). Thus each drone not only seeks the cheapest method to accomplish its tasks, it dynamically sets the prices for its own services as well. Optimal algorithms can be marketed and will be incorporated by the drones as soon as they become available. The profit they gain is fed forward to the user, back to the generator, and added to the drone's income. The net result is faster rates of productivity growth, and shorter periods of time from investment to return.

The environment that the drones operate in is known as a Trade Zone, a market which is made possible by TmX infrastructure but whose rules are set by its members.

FIG. 18 A TmX Trade Zone

The diagram shows the basic components of a Trade Zone: storage units, walls providing levels of protection, workunits with memory blocks passing between them, and gates to allow data to enter and leave the trade zone.

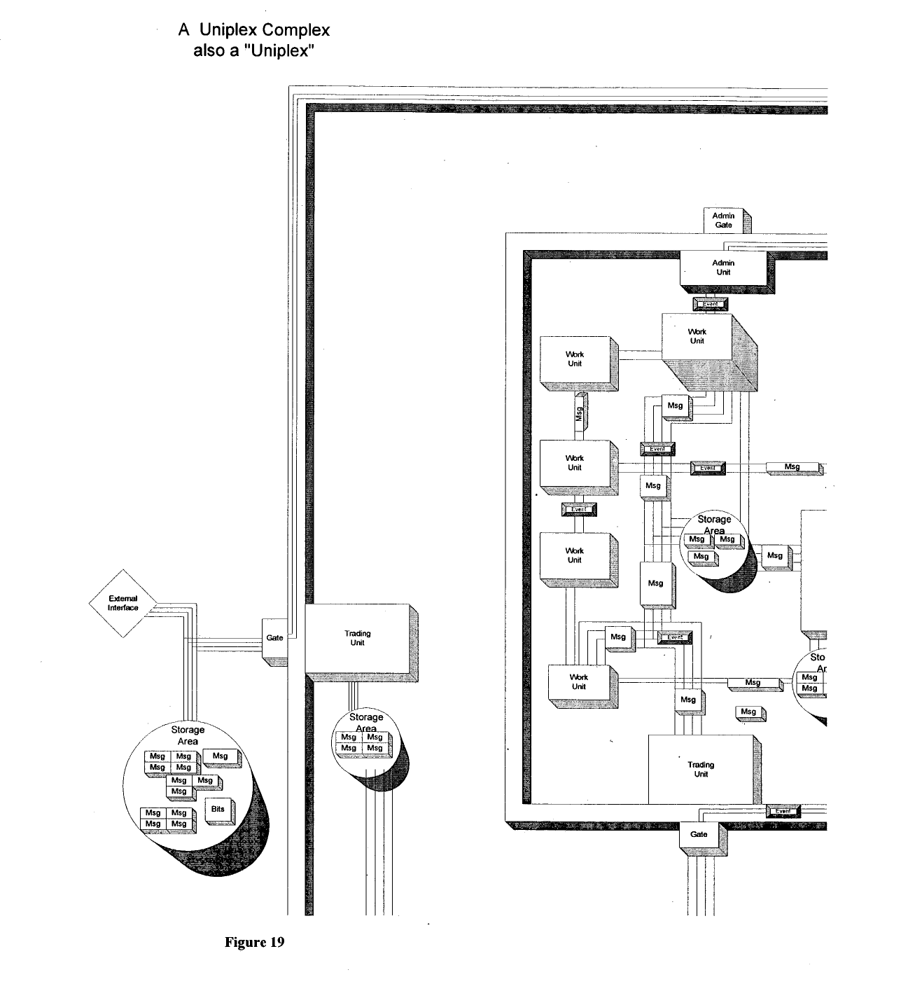

FIGS. 19 to 26 related to drawings which are enlargements of the drawing in FIG. 18

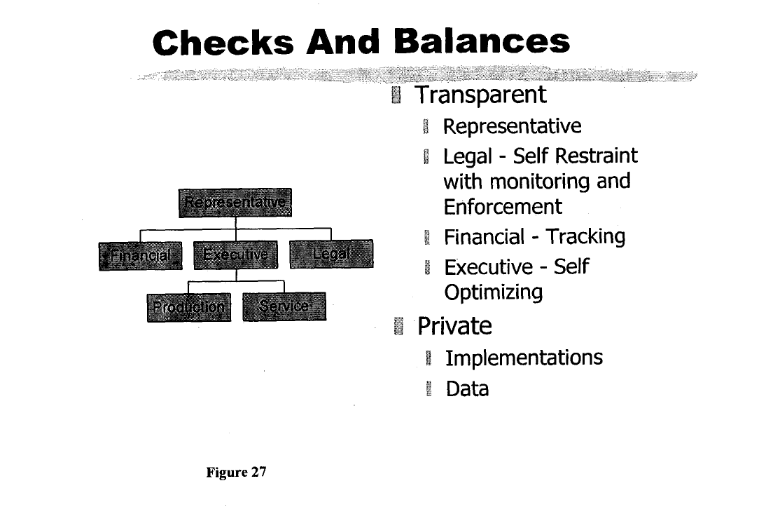

FIG. 27 Checks and Balances

The system is based on the same checks and balances of equivalent fair legal systems.

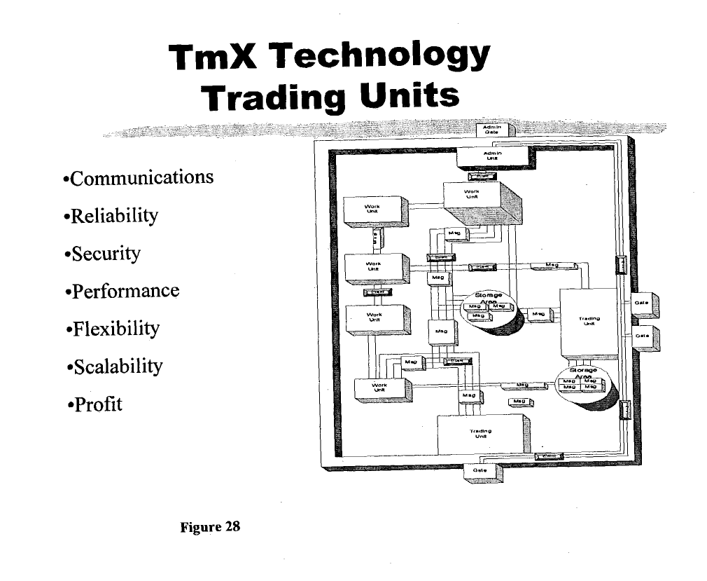

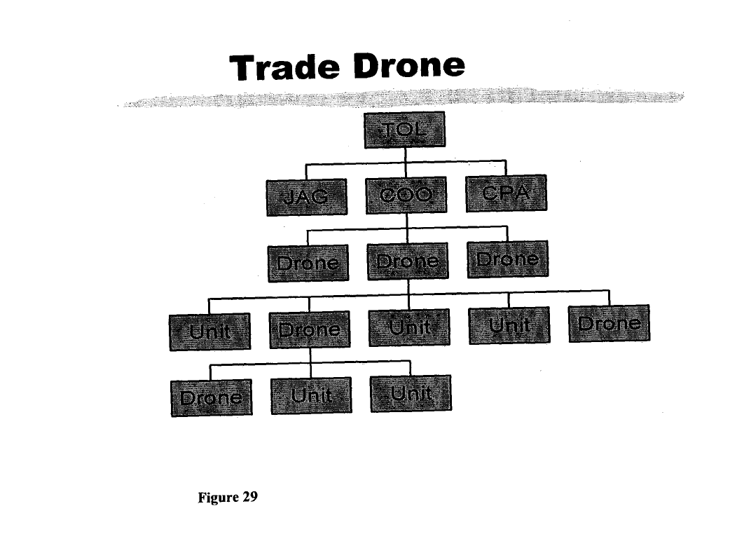

FIG. 28 TmX Technology—Trading Units

A Trading Unit is the basic unit of the TmX economy. If a drone is a special instance—a full economic actor—a Trading Unit is the general case: anything with a commodity to sell. All units that are not drones are controlled by drones. The Trading Units provide optimized secure communications between distributed units, ensure reliability of the system using both simple redundancy and advanced error protection procedures, and provide the processing and storage muscle of the economy. The tasks assigned to a Trading Unit will be assigned to as many physical elements as are available and economical—units can acquire the resources of other units, on a dynamic basis, assuming there is enough value in doing so.

In many cases, resources will be assigned in order to meet nominal requirements and will then be marketed if not fully utilized.

FIG. 29 Trade Drone

Trade drones, whether they are very simple units or a hierarchy of drones, all have the same structure. No drone can operate without a TOL—The Owner Link or Total Obedience Link. This level of operations defines the objectives of the drone, sets the rules by which it must operate, and ensures that there is a human to take responsibility for the drone's actions. In the simplest case the JAG inspects all addresses and is the Justified Address Generator, but it also makes sure that the drone follows the rules set by the TOL. The CPA tracks the drone's resources and authorizes transactions. The COO has a limited number of choices and is responsible for the optimization of the drone.

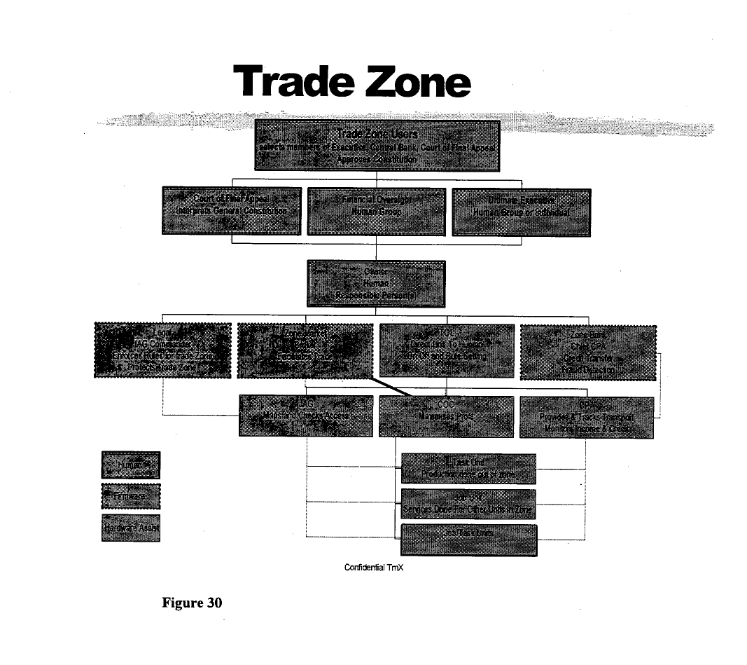

FIG. 30 Trade Zone

Within a trade zone the units are tied together into a matrix, or web, of checks, balances, and mutual benefit. TOLs feed through eventually to responsible humans. JAGs—via higher-level drone arbiters—lead to contract managers and eventually to the legal system. COOs can sell their products and shop for cheaper solutions via markets and brokers. Banks and financial control units are the masters of the CPA hierarchy.

A Trade Zone is a place where thousands of contracts are assigned every second, and millions of transactions occur every millisecond. The structure of the Trade Zone is intended to promote the maximum profit, and to prevent harm.

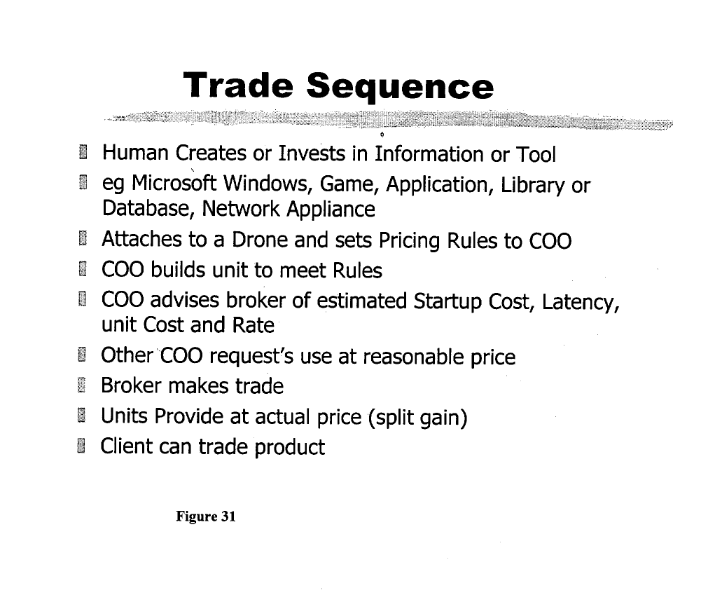

FIG. 31 Trade Sequence

The slide describes a hypothetical sequence of events and transactions, showing an example of how a drone enables its owner to maximize the profit he gets from his system and its resources. The more efficient the system is, the more overall gain the the owner and to the system.

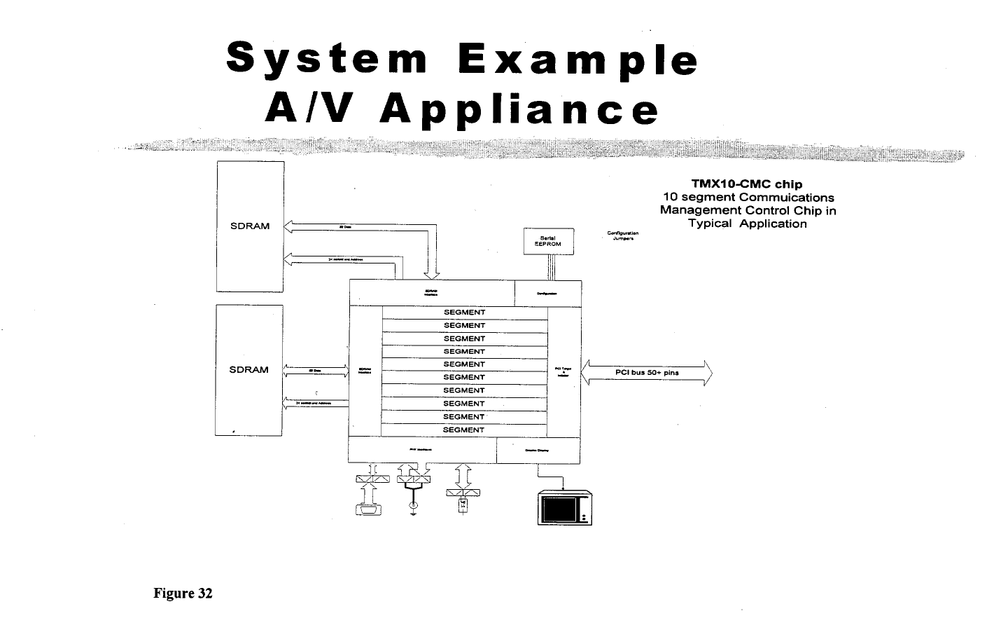

FIG. 32 System Example—A/V Appliance

This is one of the baseline applications for TmX: a completely configurable unit incorporating all the functionality of a PC in an embedded, secure, reliable environment.

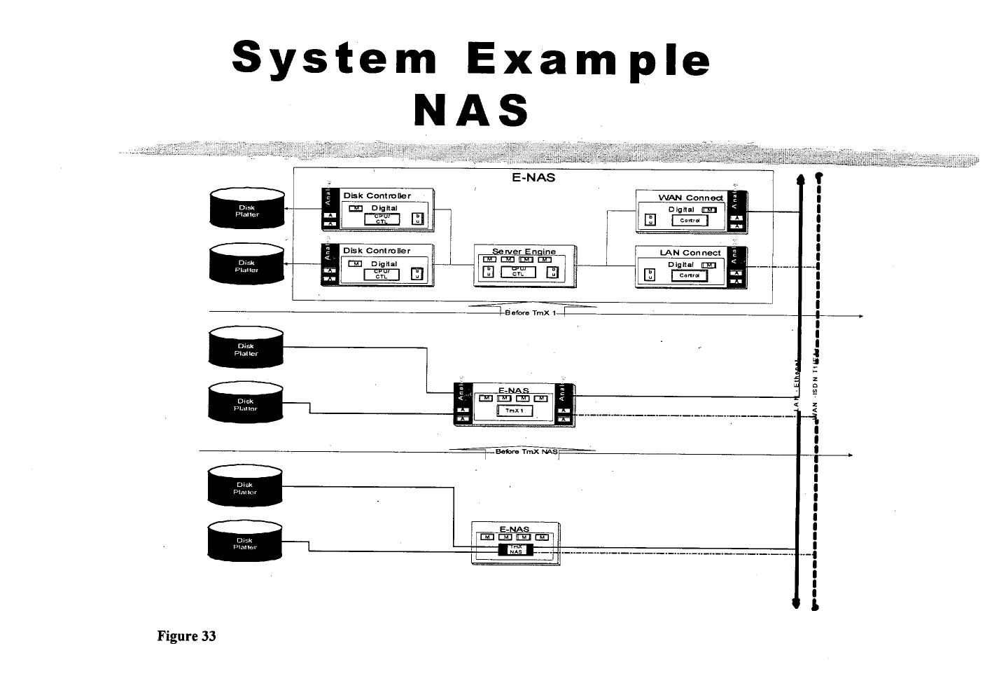

FIG. 33 System Example—NAS

This shows the typical progression of a simple, TmX-based system.

The original, non-TmX implementation is shown on top. It includes the server engine, an ASIC. For simplicity, only four functions are shown, each with a separate digital interface component.

The middle shows a quick redesign which integrates all the digital components into a single TmX component, but leaves the ASIC as a separate component. This allows the manufacturer to incorporate features rapidly in order to increase the value of the device.

Once cost and volume justify it, a special ASIC incorporating the interface circuit but still retaining the flexibility and ROI advantages of TmX architecture can be developed, as seen in the bottom picture.

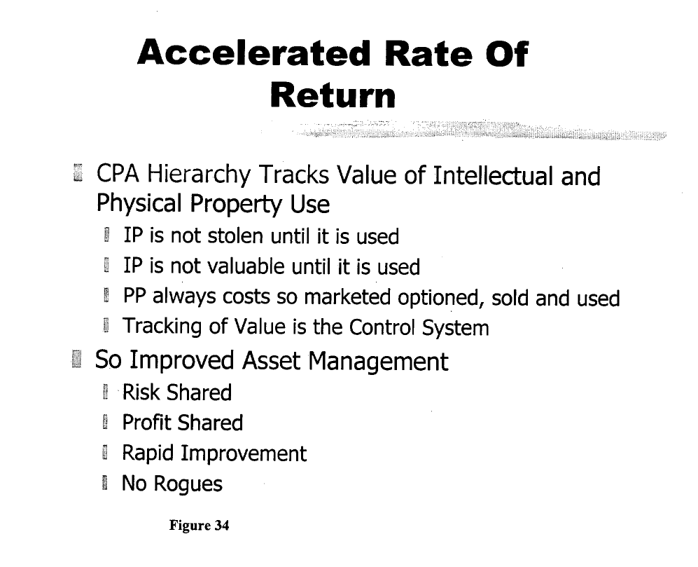

FIG. 34 Accelerated Rate of Return

TmX's direct addressing system is the heart of its communications, cutting through layers of protocol to deliver fast communications between diverse systems. The same system enables intellectual property to be tracked. This makes a new approach to the trade in intellectual property possible.

Our approach to intellectual property is much like our approach to processing: Scalability is key. In the current market, it is difficult to control the use of intellectual property once it has been sold. This means that intellectual property, if it is sold at all, must be sold at prices that assume that it will be used at great volume. Thus, intellectual property that is useful for smaller applications never makes it to the market, and is sometimes developed time and time again by companies that cannot afford to share with each other, to the detriment of all.

Under the TmX system, however, it is possible to track, and therefore to charge for, intellectual property at the point when it becomes valuable—that is, when it is used. This feature makes it possible to market intellectual property profitably on any scale. Because of this, innovations can spread rapidly among those who can use them. This will increase the profit of both the innovators and those who can use the innovations, cut down on the risk inherent in spending money on research and development, and, ultimately, accelerate the rate of improvement across the technology market.

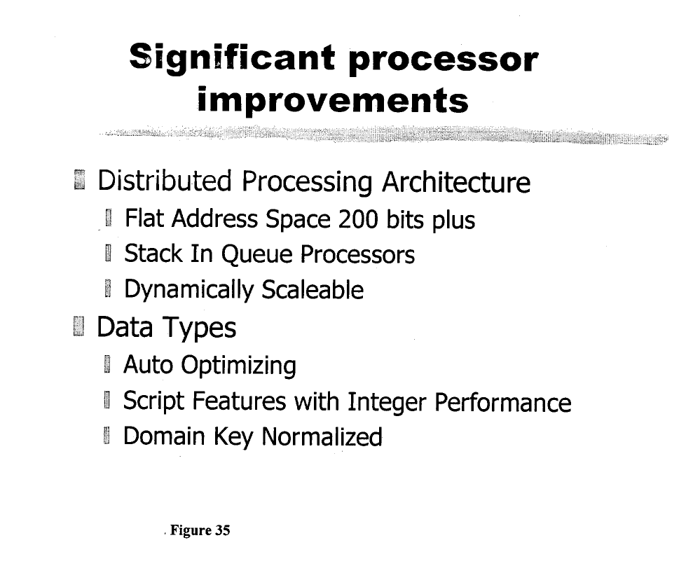

FIG. 35 Significant Processor Improvements

In order to achieve such dramatic improvements it was necessary to rethink the nature of the Central Processing Unit and convert it into a Sequence Execution Unit. The development of SIQ processing enables a smooth transition for applications to the new system. A huge flat address space crushes classical data sharing issues as long as it is melded with a highly optimising implementation. Using true mathematical precision and Domain Key Normalization, TmX is the most theoretically reliable system yet implemented for general use. It provides the ease of use of a script language with the raw performance of tuned machined code and not limited to a single CPU but providing the embedded system designer with a fleet of SXUs.

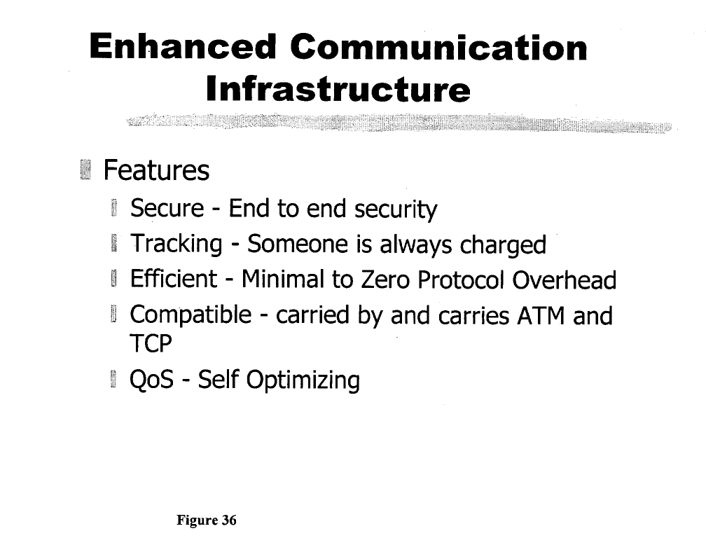

FIG. 36 Enhanced Communication Infrastructure

A Distributed Processing system obviously requires built in features which are expensive add-ons to a conventional system. Virtual Private Network, Quality of service, Information and Interlectually property tracking, self healing networks. As these systems are used for intra-chip, inter-chip, inter board etc., the basic structure had to be significantly more capable than the classical systems. It also had to be able to merge with, and carry classical protocols. We will only be able claim real success when the billionth system has sent its billionth packet and most importantly recvieved payment for it. Everthing in TmX is for profit, and the biggest source of profit is the human talents amplified by the next generation connectivity of a self optimizing, obedient, computing platform TmX.

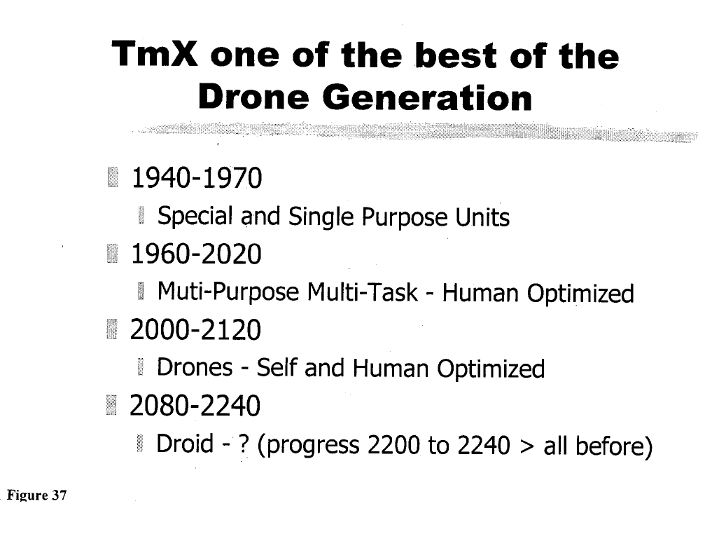

FIG. 37 TmX—One of the Best of the Drone Generation

Since the dawn of computers—machines that could process data using logic—there have been a number of generations, each bringing a dramatic advance in the very idea of what a machine could do, and how it could improve human productivity. The first single purpose units were incredible enough, but the next generation computers could be programmed to interpret data in a number of ways, and the variety of functions a single unit could perform was limited chiefly by the imagination of its programmers.

The next generation has arrived. The drones of today and tomorrow will not only be able to carry out any task programmed into them, they will be the ones making the second-to-second decisions as to what task is the most profitable to carry out now, according to the guidelines set by their operators. And if there are tasks which are beyond its capabilities, it will be able to purchase these capabilities from other systems.

And as for the generation after? The only prediction we can make with confidence is that things which we can barely imagine now will become routine, problems which we never considered will become the new inflexible limits—until they too are broken—and in the forty short years between 2200 and 2240, more progress will be made than all our technological achievement up to that point.

By the end of the twentieth century, it was understood that the way to accelerate growth and profit is to increase the efficiency with which people use their time. This is the basis of all computing. Computers are essentially man-multipliers. This is the basis of TmX as well.

A TmX system is vast computing power managed and focused to enhance productivity using the same mechanisms that are used in human economies. A person who uses a TmX system has large numbers of useful units at his behest, including electronic units that allow him to market and sell assets such as methods, mechanisms, information, processing power, and the capabilities of physical peripherals.

TmX systems communicate in a marketplace where the resources of one system are not the only resources available to the user. The resources of other TmX systems, at the discretion of their own user and to his profit, can be purchased as well. TmX facilitates the communications and profitable trade between all the resources that work with the systems, including the human resources. TmX is not just a way for people to work better, it is away for them to work better together.

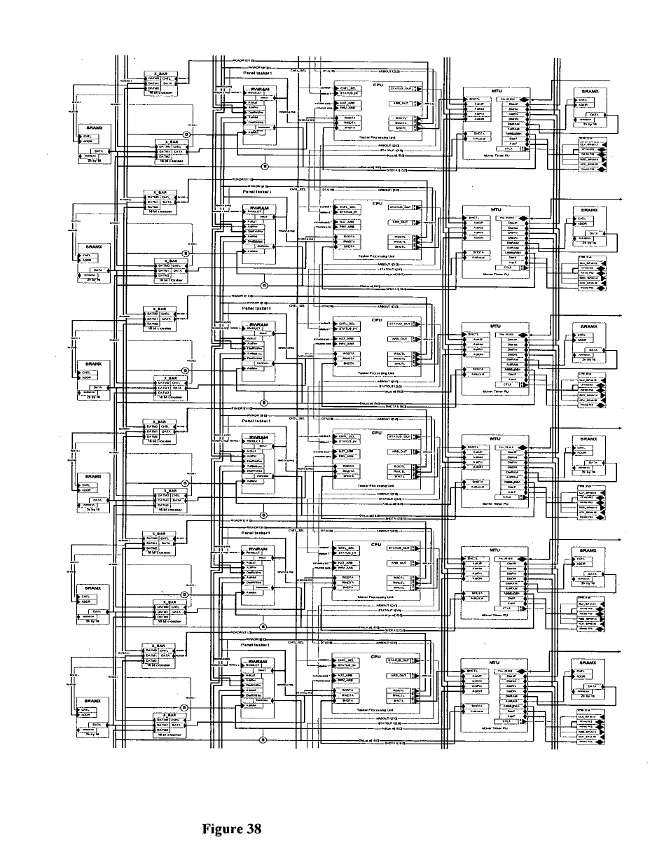

FIGS. 38 to 55 Relate to an implementation of the architecture most closely realted to classical systems.

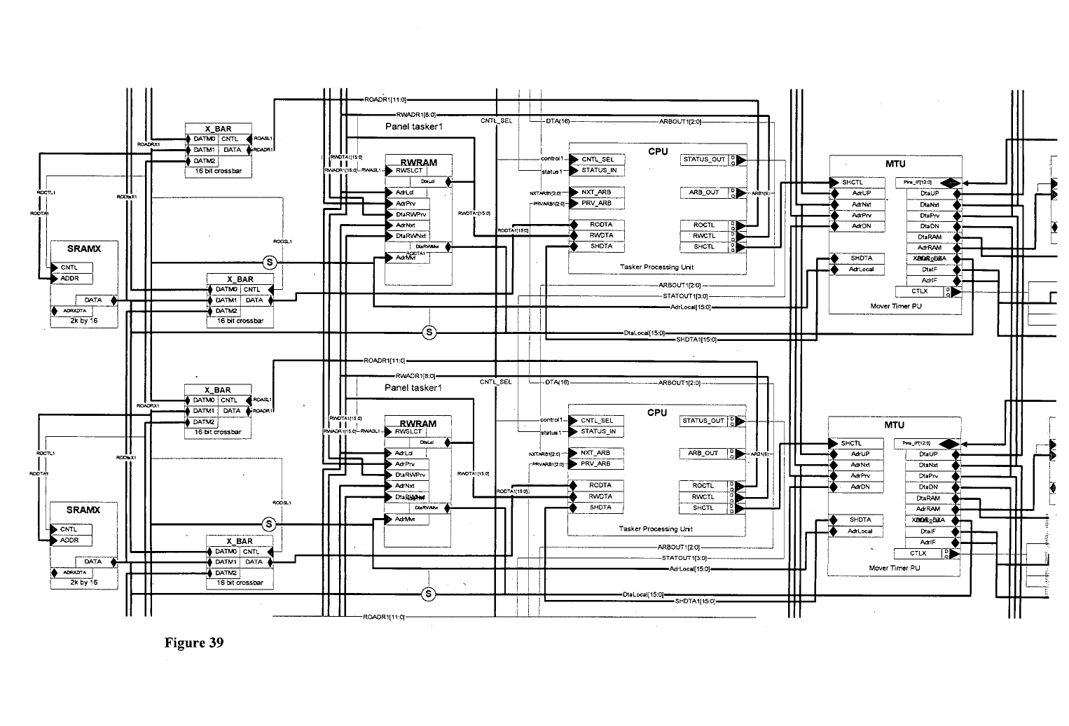

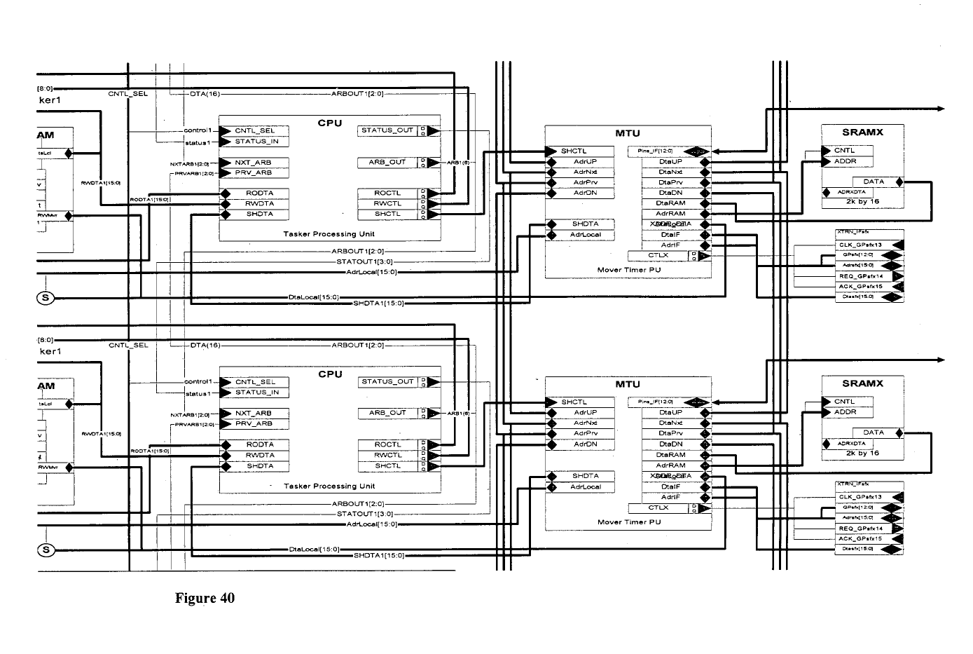

FIGS. 38 to 40 relate to schematic register diagrams of a set of 5 Segments and associated interface modules, for the 5 segment version of the TmX DDOPCASS implementation. In this design most of the Drone features are implemented in firmware. FIGS. 39 and 40 relate to expanded views of 1 of the identical 5 segments.

The major parts of each are the Mover Timer Unit (MTU), the Tasker eXecution Unit (TxU or CPU), (both are instances of an Sequential eXecution Unit (SXU)) the internal RAMs and associted circuitry and the interface units.

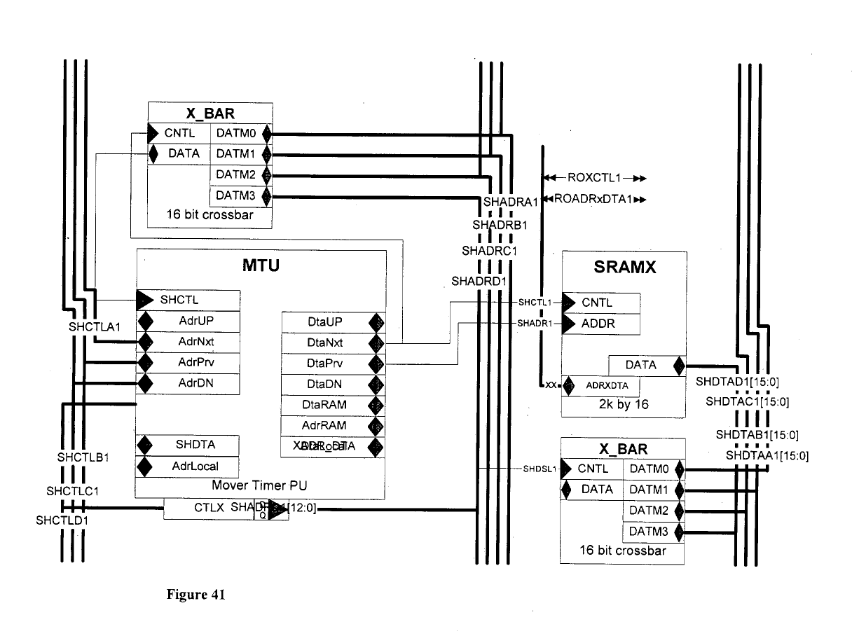

FIG. 41 relates to the placement of an MTU SXU in a typical DDOPCASS processing system, illustrating the paths to the staggered triple buses. The MTU boot function loads the data to the internal RAM block SRAMX and the MTU inializes the segment.

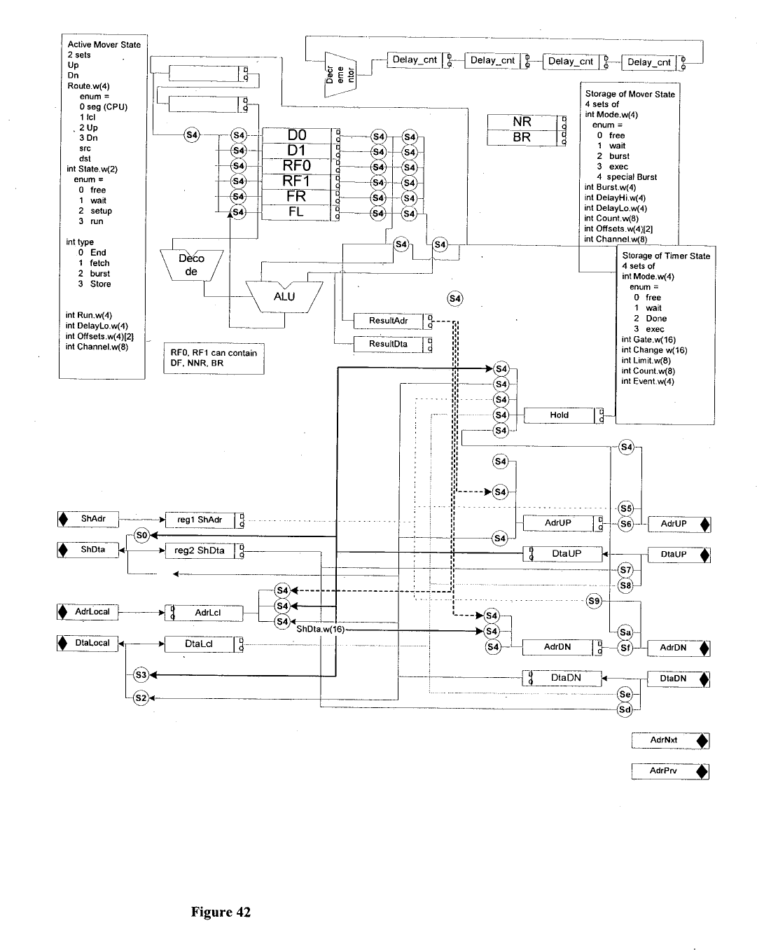

FIG. 42 relates to a register flow diagram of a MTU.

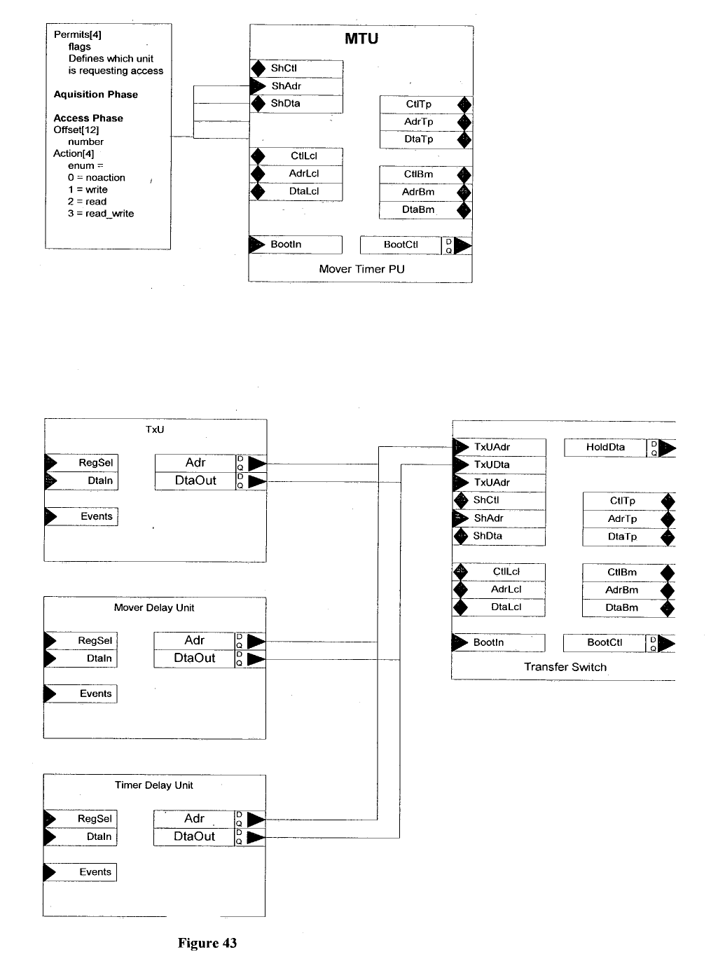

FIG. 43 relates to a block diagram and phase description of the operation of the MTU SXU.

The MTU performs most of the data movement of the segment, with much of the data processing performed by the TxU. The MTU contains a fully capable ALU but the multiply support is minimal.

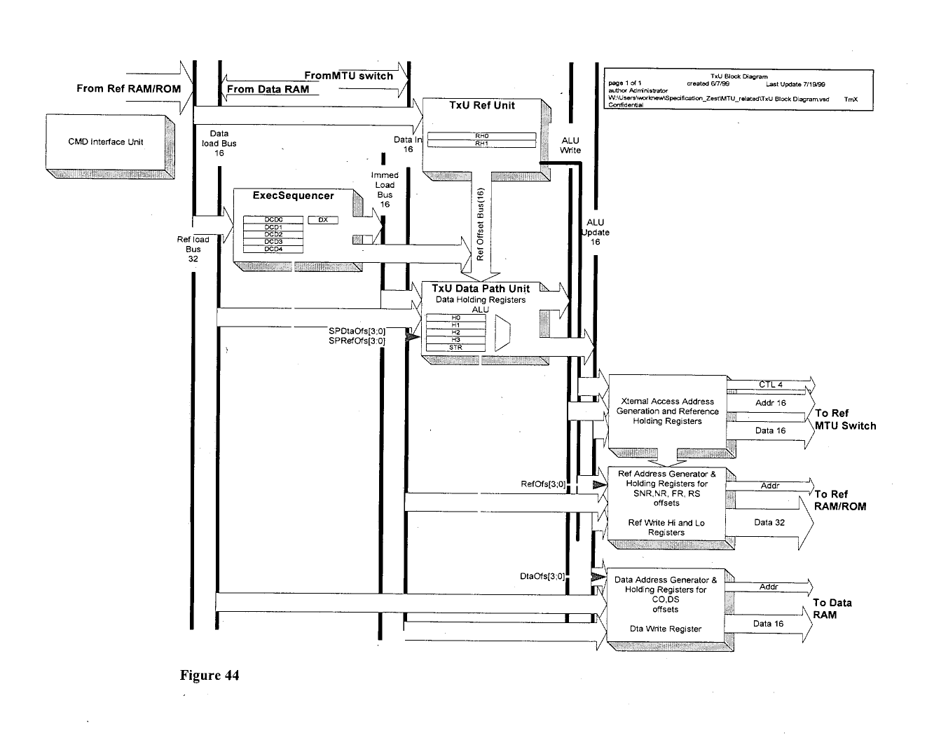

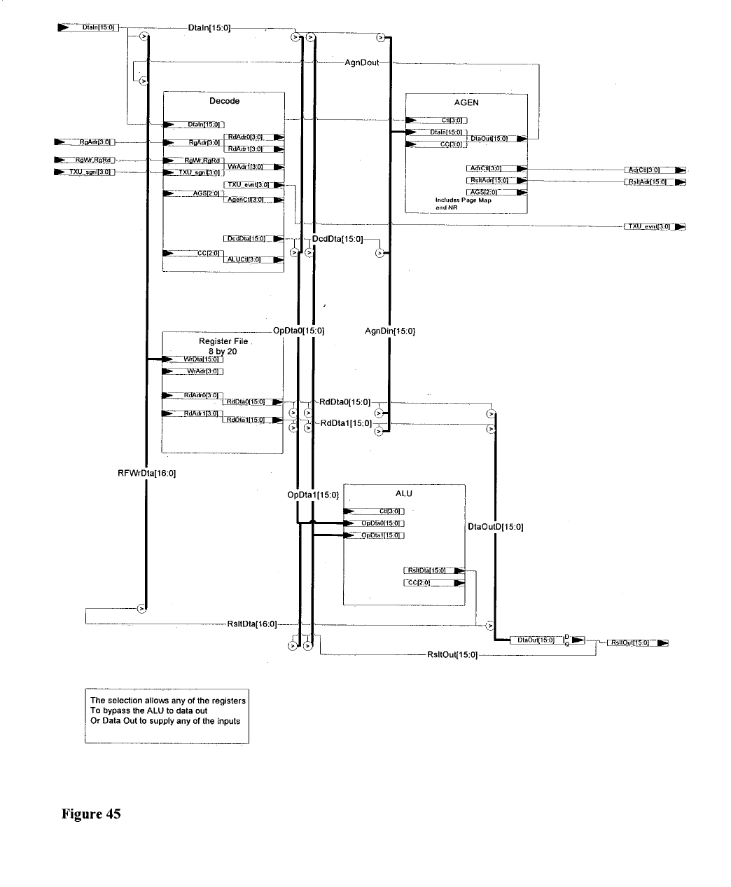

FIG. 44 relates to a pipeline flow diagram of a Tasker Execution Unit (TxU).

FIG. 45 relates to a detail block diagram of a Tasker Execution Unit (TxU).

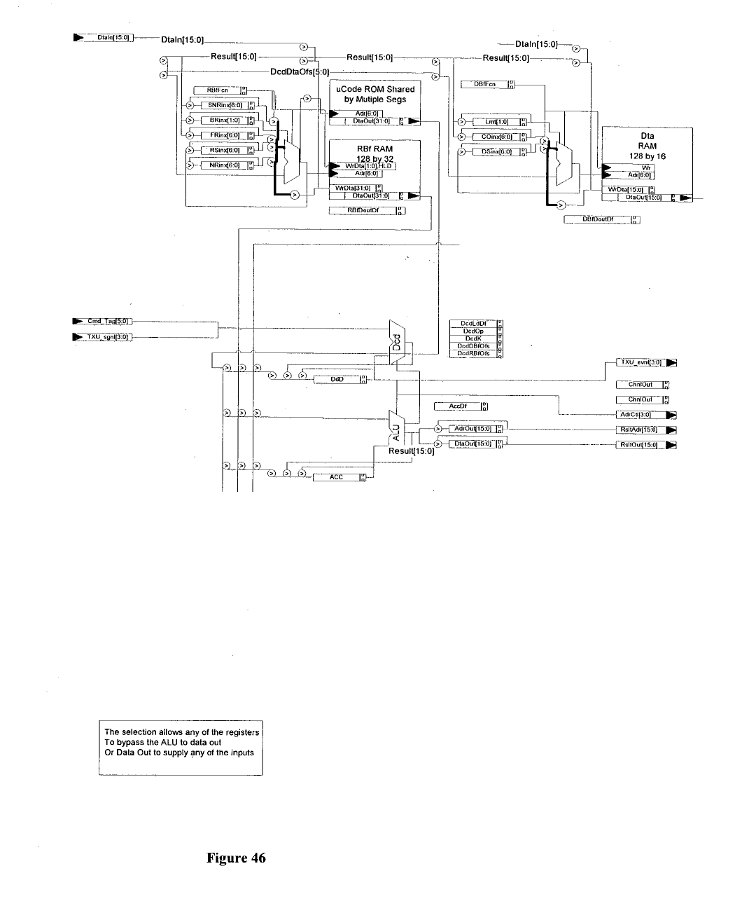

FIG. 46 relates to a detail block diagram showing the data paths relating the TxU to the RAM modules in the Segment.

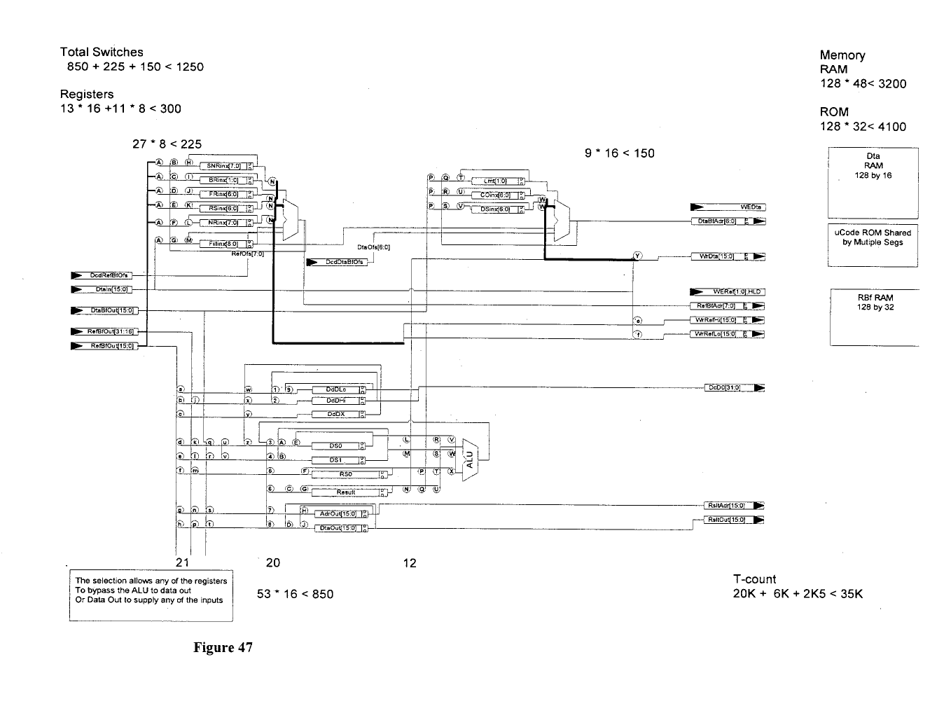

FIG. 47 relates to a detail register diagram showing the data paths within the TxU The TxU is a relatively conventional processor with minimal base register set backed by a memory mapped context.

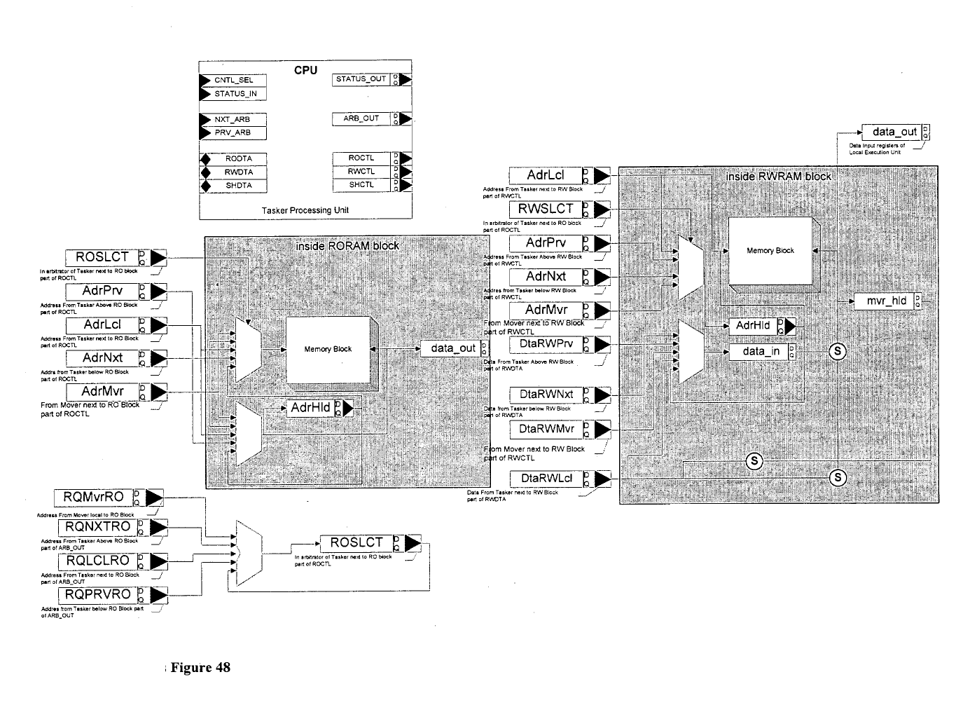

FIG. 48 relates to a register flow diagram of the internal RAM blocks of a segment, both the-Data (RWRAM) and the Control(RORAM) blocks.

Booting the system is handled by the MTU.

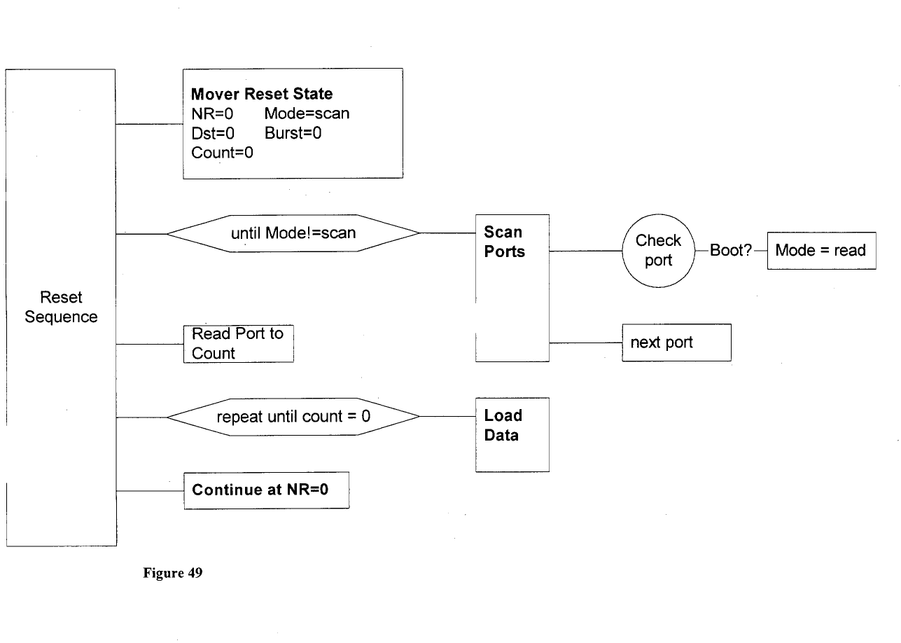

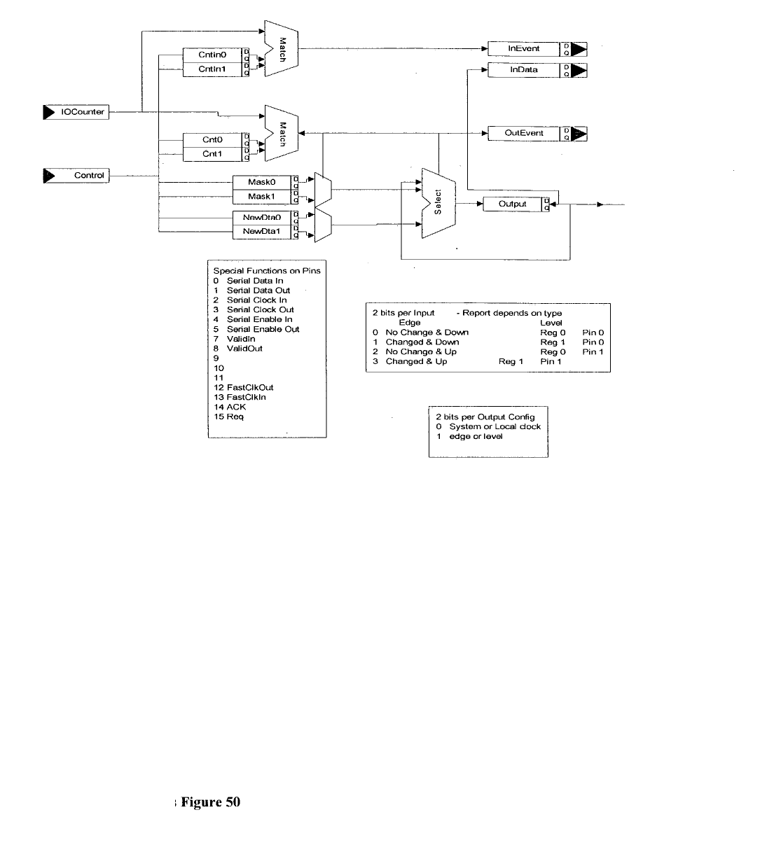

FIG. 49 relates to a flow diagram for initial system boot data. A port is checked for a boot code, which is followed by a count, being the number of words to load. The data is loaded starting at 0 at the completion of the load MTU execution starts at 0.

Interface to external devices is via the interface block which includes Timed Event IO (input ouput) for typical embedded system signal monitoring, and high performance parallel IO for attachment to external Memory and peripherals, with various muliplexed buses.

FIG. 50 relates to a register flow diagram of a timed event data aquistion 10 block, which is used to capture inputs at times set by CntIm[0:1] and ouput NewDta[0:1} at times set by Cnt[0:1], this allows SXU's to operate efficiently. The number of registers can be increased to permit longer operation runs. Also lists the special function bit assignments.

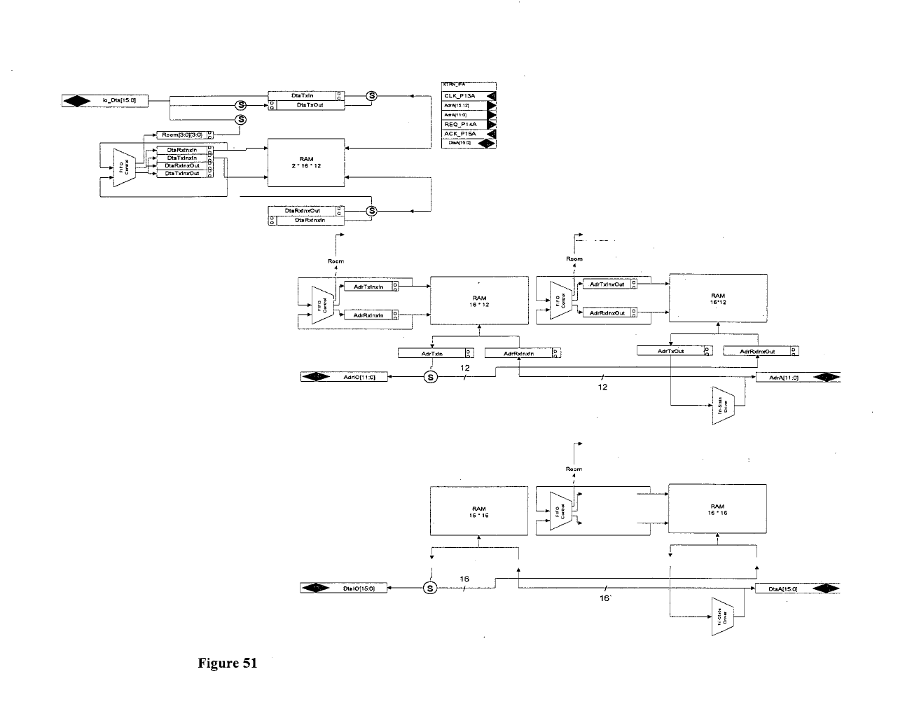

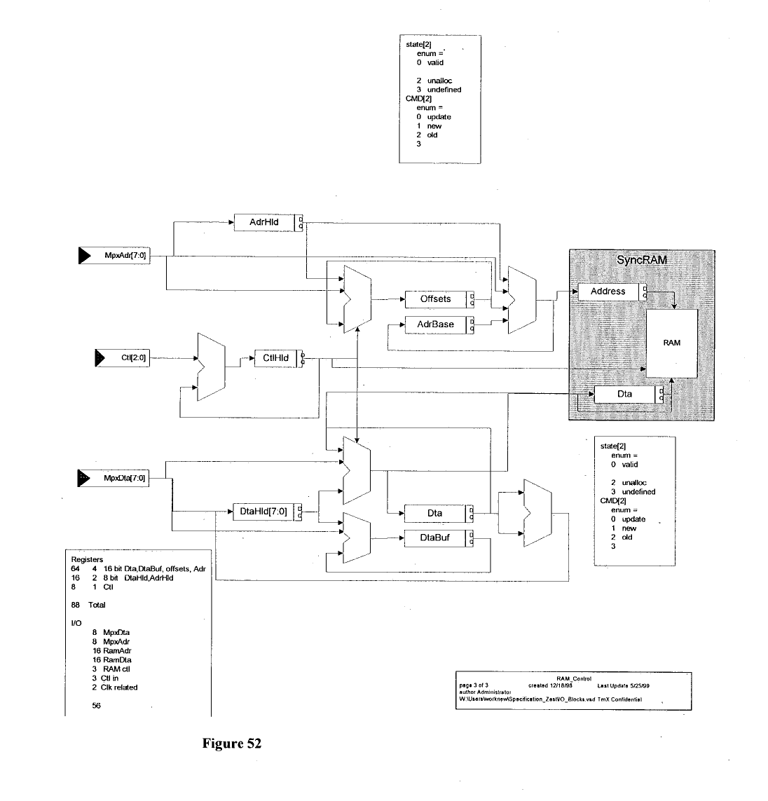

FIG. 51 relates to a register flow diagram for bus interface logic, for high performance parallel input and output.

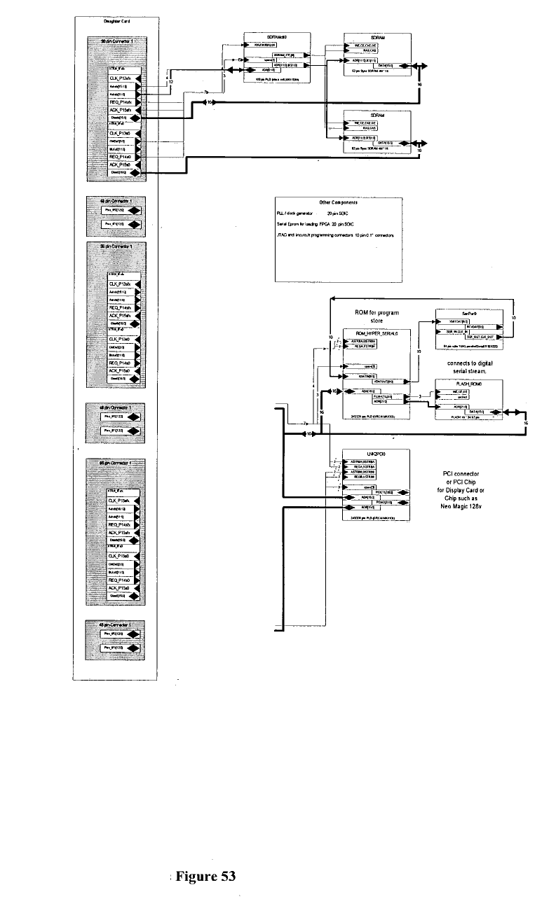

FIG. 52 relates to a register flow diagram of the Syncronous SRAM interface of a DDOPCASS Device using the standard interface block.

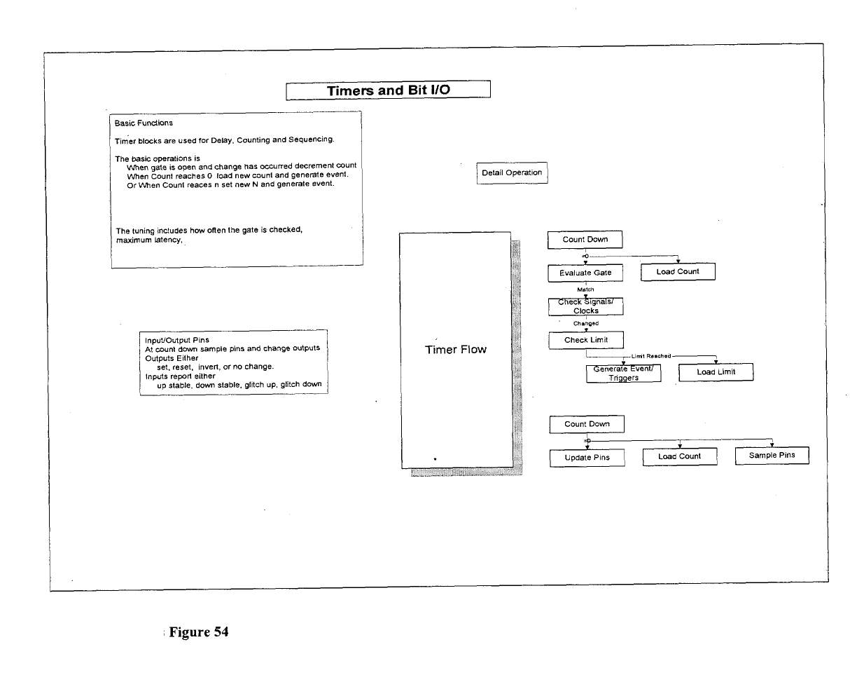

FIG. 53 relates to an interface block and pin diagram for a development system that includes 32 bit SDRAM interface, PCI, FlASH boot and serial digital logic scanner.

FIG. 54 relates to a diagram of the principal parts of a timer unit in a DDOPCASS Device partial implemented in hardware by the MTU.

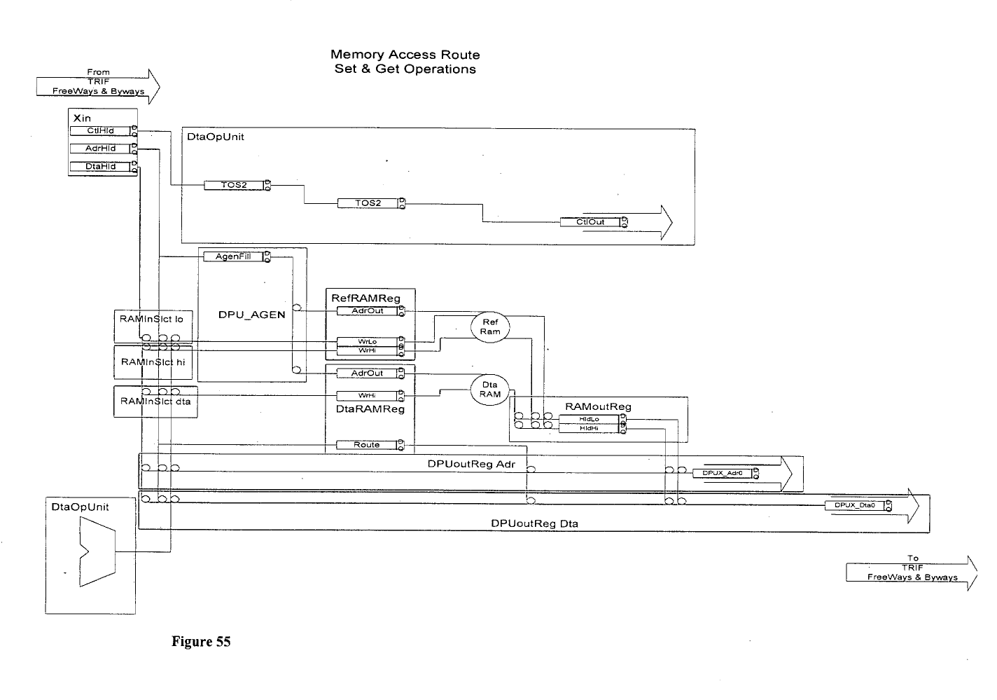

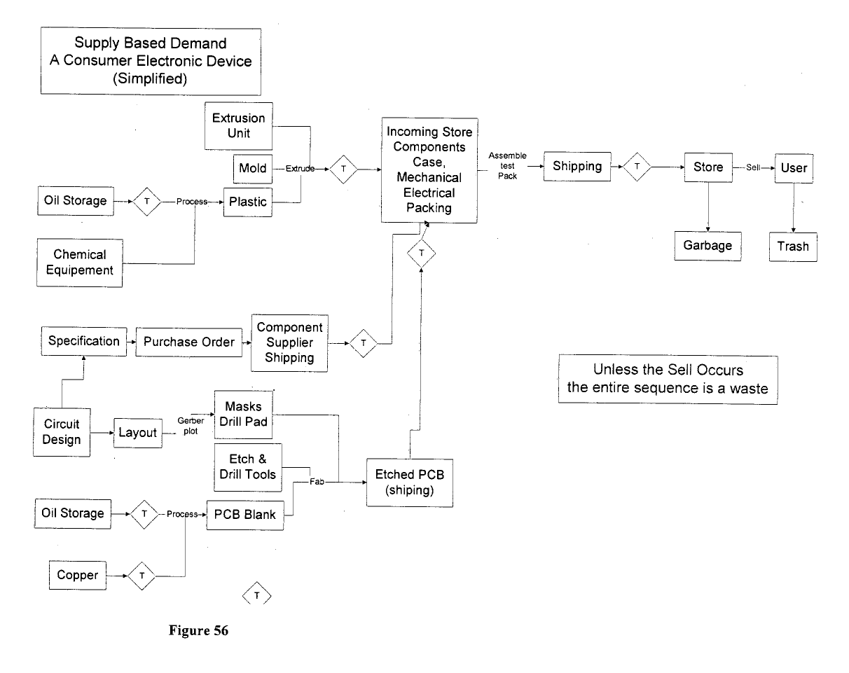

FIG. 55 relates to a register flow diagram definining the typical flow though an SXU/CXU during basic data transfer operations.

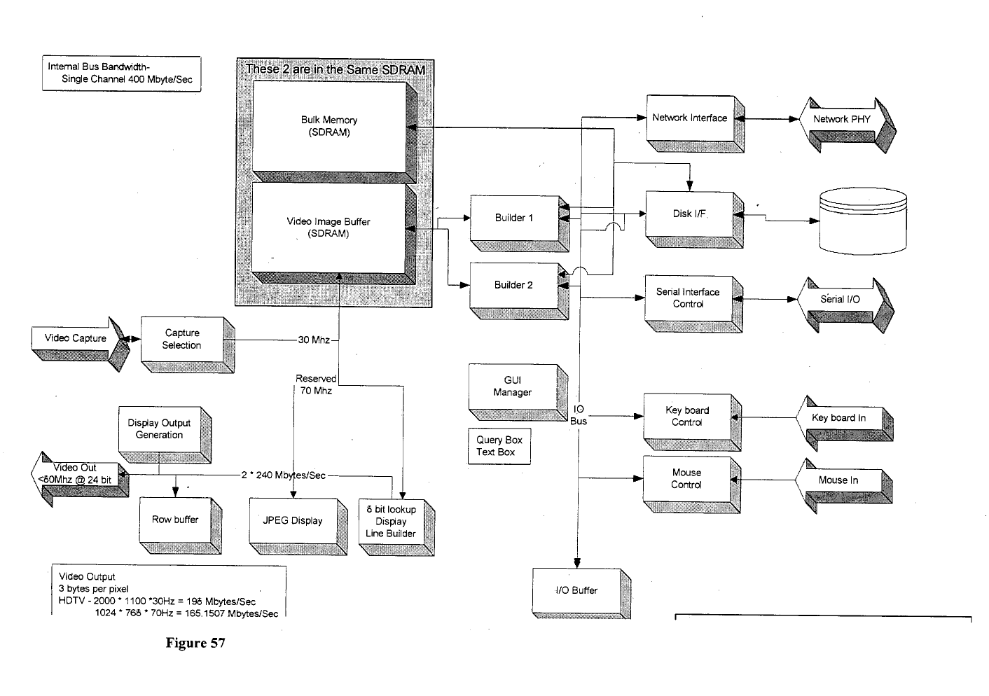

FIGS. 56 to 60 relate to typical Complex systems

FIG. 56 relates to a flow diagram for the production of a consumer electronic device. In the current system all the risk is bourne by the manufacturer which means that the end user cost is higher thus reducing the total market for the product. Consider a typical system

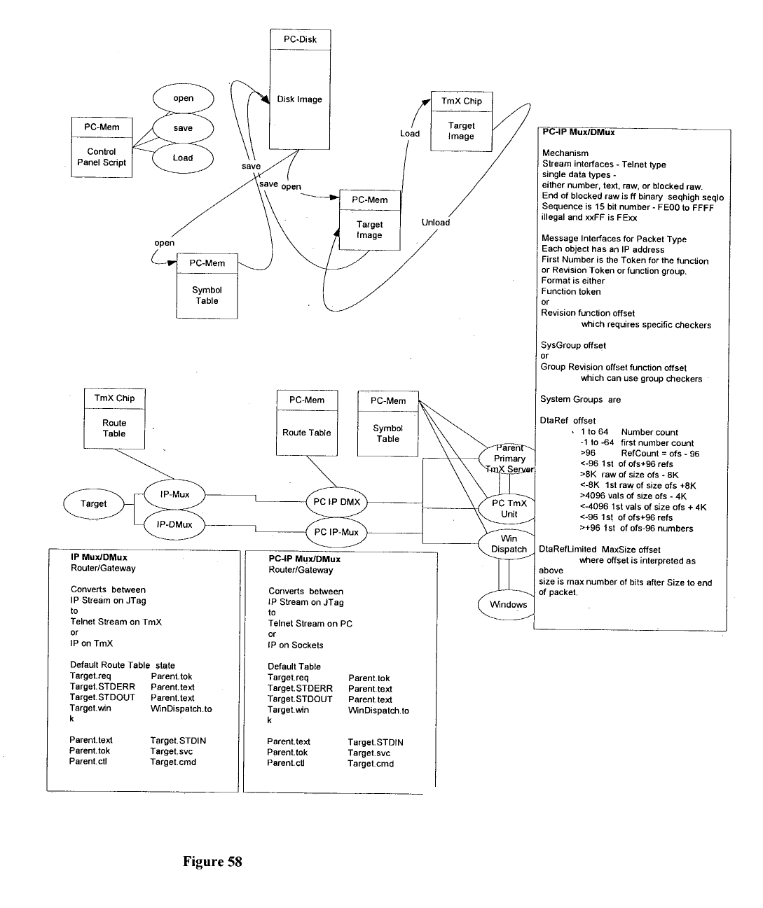

FIG. 57 relates to a block diagram of a typical system. The Square boxes represents modules implemented in DDOPCASS units For example a network storage device.

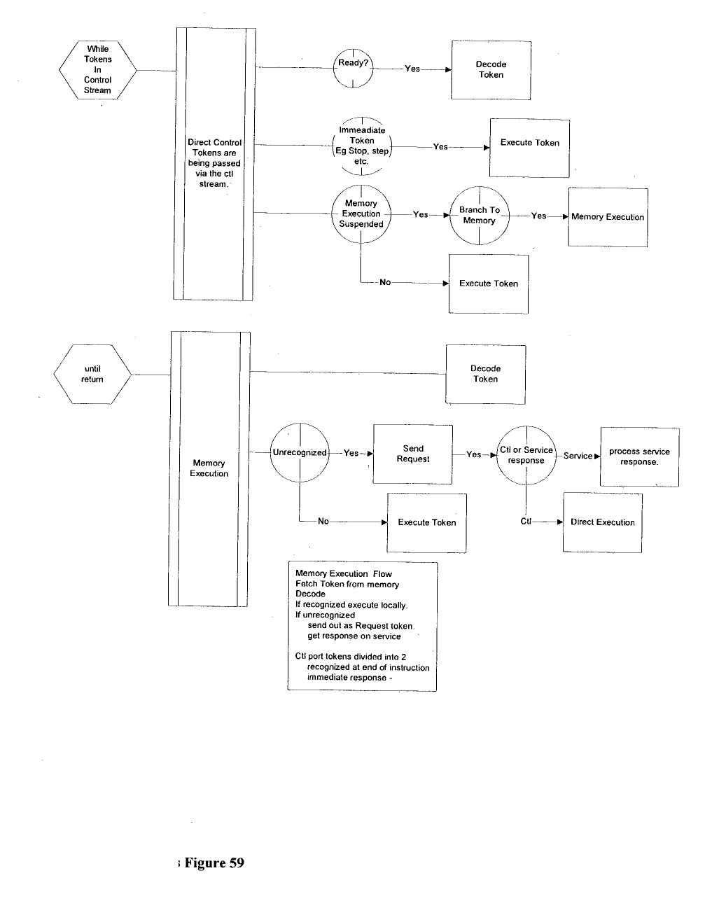

FIG. 58 relates to communications transfer diagram using IP to interface to a DDOPCASS/TmX system. This is used by the NAS system from FIG. 33. The minimal interface is 2 streams, for the TOL for setup and COO for operation. This is adequate for a classic peripheral but the full hierarchy is required for stable distributed operation.

FIG. 59 relates to a flow diagram of dual control streams to a DDOPCASS unit, typically a TOL and COO channel

Another complex system is a PC equivalent.

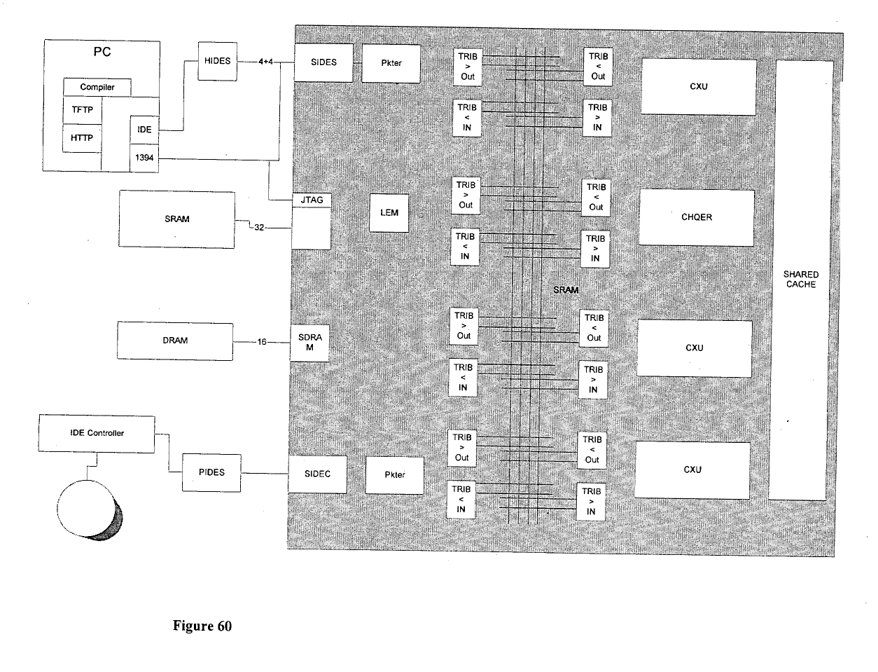

FIG. 60 relates to a block diagram of a SIDE interface based triple segment CXU based implementation of DDOPCASS device, optimised for PC peripheral implementation and suitable for emulatioon on an FPGA.

The present invention has be described with a certain degree of particularity, however those versed in the art will readily appreciate that various modifications and alterations may be carried out without departing from either the spirit or scope, as hereinafter claimed.

Furthermore, in describing the present invention, explanations have been presented in light of currently accepted Technological, or Mercantile theories and models. Such theories and models are subject to changes, both adiabatic and radical. Often these changes occur because representations for fundamental component elements are innovated, because new transformations between these elements are conceived, or because new interpretations arise for these elements or for their transformations. Therefore, it is important to note that the present invention relates to specific technological actualization in embodiments. Accordingly, theory or model dependent explanations herein, related to these embodiments, have been presented for the purpose of teaching, the current man of the art or the current team of the art, how these embodiments may be substantially realized in practice. Alternative or equivalent explanations for these embodiments may neither deny nor alter their realization.

Finally, while the invention has been substantially described with respect to specific examples including presently preferred modes of carrying out the invention, those skilled in the art will appreciate that there are numerous variations and permutations of the above described systems and techniques that fall within the spirit and scope of the invention as set forth in the appended claims.

I/we claim:

1. A distributed dynamically optimizable processing, communications, and storage system, and the system includes
(A) a queue (Qu) based processing and communications hardware environment, capable of emulating sequential and parallel processing, said environment maintaining, in a large address space,
(first) at least three general purpose logical queues wherein the at least three general purpose logical queues are special purpose allocated to be (i) at least one input-storage queue and (ii) at least one processing queue having therein at least one processing element and (iii) at least one output-storage queue, and
(second) an at least minimum connective communications topology distributed there-between, whereby each of the queues has at least one interconnection to at least one of the other queues and the communications topology is capable of interface with communications topologies of at least one input device and of at least one output device; and
(B) substantially-hierarchically above said queue based processing and communications hardware environment, another processing and communications hardware environment having
(first) an input/process/output capability, and
(second) data-communications linked to the queue based processing and communications hardware environment, and
(third) a resource tracker operating task-specifically,
(i) said resource tracker operating being substantially in compliance with an accessible current set of user contracts,
wherein the current user contracts specify virtual payment requirements for each use of a respective subset of allocated resources, and
wherein said resources are in the queue based processing and communications hardware environment, and therein said resources are selected from the list: queues, devices, interconnections, interfaces, functional clusters of the aforesaid, and administrative clusters of the aforesaid, and
(ii) said resource tracker coordinating queue-to-queue communications interconnections and queue-with-device interfaces over the topology by allocation from the current potential set of users to a substantially current set of resources—in accordance with respective resource availability and current user respective contract states.

2. The distributed dynamically optimizable processing, communications, and storage system, according to claim 1 wherein substantially each of the queues is a range of logically substantially-contiguous addresses in address space of the environment.

3. The distributed dynamically optimizable processing, communications, and storage system, according to claim 1 wherein substantially each of the queues has at least three possible states:
(i) at least one state of the three possible states being selected from the list: undefined (UDF), allocated for later use (BSY), and initialized/write-only (INI);
(ii) another state of the three possible states being read/modify/write (MTR); and
(iii) a further at least one state of the three possible states being selected from the list: read-only (FIX), and cancel (CAN).

4. The distributed dynamically optimizable processing, communications, and storage system, according to claim 1 wherein said another processing and communications hardware environment is substantially a queue based processing and communications hardware environment.

5 The distributed dynamically optimizable processing, communications, and storage system, according to claim 1 wherein the processing element is an arithmetic logic unit.

6. The distributed dynamically optimizable processing, communications, and storage system, according to claim 1 wherein a preponderance of the interconnections in the communications topology are encrypted.

7. The distributed dynamically optimizable processing, communications, and storage system, according to claim 1 wherein allocated resources are substantially proximate to their respective queue.

8. A queue (Qu) based processing and communications hardware environment appurtenance, in compliance with claim 1, the appurtenance comprising at least one functional cluster of resources, and said resources include: at least three general purpose logical queues wherein the at least three general purpose logical queues are special purpose allocated to be (i) at least one input-storage queue and (ii) at least one processing queue having therein at least one processing element and (iii) at least one output-storage queue; and interconnections therebetween; and at least one device interface thereto.

9. An article of manufacture including a computer usable medium having computer readable program code embodied therein for coordinating operations between a plurality of queue (Qu) based processing and communications hardware modules including therein at least one minimum connective communications topology distributed there-between and therewith at least one module operating task-specifically as a resource tracker.

10. A program storage device readable by a machine, tangibly embodying a program of instructions executable by the machine to perform, in a distributed dynamically optimizable processing, communications, and storage system, method steps for task-specific resource tracking by coordinating queue-to-queue communications interfaces over a topology by allocation, according to resource availability and current user respective contract states, from a current potential set of users to the resources—according to the current user contracts requiring virtual payment for use of a respective subset of allocated resources, and the steps include, in a large queue processing machine wherein substantially each of the queues therein has at least three possible states, at least one step corresponding to: (i) at least one state of the three possible states being selected from the list: undefined (UDF), allocated for later use (BSY), initialized/write-only (INI), (ii) another state of the three possible states being read/modify/write (MTR), and (iii) a further at least one state of the three possible states being selected from the list: read-only (FIX), and cancel (CAN).

11. A program storage device readable by a machine, tangibly embodying a program of instructions executable by the machine to perform, in a distributed dynamically optimizable processing, communications, and storage system, said method steps including collectively at least ten operation-functions selected from at least one of the lists:
A Qu Location States operation-function selected from the list:
(UDF) undefined for an indefinite period,
(BSY) inaccesible for a specific period,
(INI) iniitialised to a default value, and may be written but not read,
(MTR) readable and writeable,
(FIX) only readable,
(CAN) undefined indefinitely;
A Qu Bounds Groups Qu Locations Before After operation-function selected from the list:
(BOA) Beggining Of Allocation start of region of Qu mapped to physical Memory UDF UDF/BSY,
(EOA) End Of Allocation end of region of Qu mapped to physical Memory FIX/CAN CAN,
(BOW) Beggining Of Write BSY INI,
(EOW) End Of Write MTR FIX,
(BOR) Beggining Of Read BSY/INI MTR,
(EOR) End Of Read FIX CAN;
A Qu Miscellaneous operation-function selected from the list:
(SIQ) Mechanism to provide the advantages of a stack and a Qu.,
(BOQ) default location of primary source of data for Qu processor,
(FOQ) default alternate source primary Destination of data for Qu processor,
(CHQ) encrypted access token for service or resource under specific contract;
A Communications operation-function selected from the list:
(AoI) new ATM over IP implementation of ATM over UDP/IP to implement circuits;
A Control operation-function selected from the list:
Drone basic deployable unit with TOL,
Drone basic deployable unit with JAG,
Drone basic deployable unit with CPA,
Drone basic deployable unit with COO,
(ver) version direct user initiated change event,
(rev) mechanically (often timed) initiated change event,
(IOU) Indebt On Use payment expected only for use,
(TOL) The Owner Link Direct connection to the owner of the unit,
(JAG) Drone Module responsible for permissions,
(CPA) CHQ Processing Arbiter Module responsible for operation finance,
(COO) Module responsible for organization and optimization,
(JOB) General Application module in a drone,
(TSK) General Application module in a drone;
An Implementation operation-function selected from the list:
(add) addition of 2 or more itms such as either nbr or nbr and ref, includes handling for item typically selected from the list: udf, inf, eps;
(by) list vector operator,
(mpy) multiplication of 2 or more itms such as either nbr or nbr and ref, includes handling for item typically selected from the list: udf, inf, eps;
(in) default input sub-context,
(out) default output sub-context,
(and) bit wise and of 2 or more itms such as either nbr or nbr and ref, includes handling for item typically selected from the list: udf, inf, eps, scaled;
(or) bit wise or of 2 or more itms such as either nbr or nbr and ref, includes handling for item typically selected from the list: udf, inf, eps, scaled;
(xor) bit wise exclusive or of 2 or more itms such as either nbr or nbr and ref, includes handling for item typically selected from the list: udf, inf, eps, scaled;
(run) the next position in a sequence
(axn) default action upon entering a context,
(cxu) C execution Unit Implementation of a Qu processing unit configured to execute C derived code,
(sxu) Sequence execution Unit Implementation of a Qu processing unit configured to execute typical sequences,
(“@” alternately “at.”) synchronization in time and time shift alignment,
(iff) if and only if execute only while conditions persists,
(run) next sequence;
A Types operation-function selected from the list:
(itm) universal data type,
(tag) the code for the type of an itm or derived type,
(ixx) Integer type derived from itm where xx=24, 25, 26, 28, 32, 40, 48, 56, 64, 80;
(lbl) label in a sequence,
(vip) very important point co-ordination point for multiple sequences,
(bct) binary coded thousands number format which represents values as groups of 10 bits,
(nbr) derived from itm specifically for arithmetic type operations,
(rel) Operation which produces a relational type of same name comparing two ranges,
(mg) start and size type,
(lst) list of ranges and references,
(cde) context dependent data type which uses position and value to produce usable result,
(fmt) a collection of variables in a specific format,
(seq) a set of operations executed in sequence,
(ctx) an execution context,
(typ) the type of an itm,
(ref) a reference to a variable or value,
(irf) an indirect reference which is transparent,
A “values”—special values operation-function selected from the list:
(inf) infinity a value which behaves like infinity, always greater than the maximum value,
(eps) epsilon a value which behaves like epsilon, always less than the minimum representable value,
(udf) undefined an undefined value,
(can) canceled an inaccessible value,
(abs) absolute the practically infinite address space of DDOPCASS,
(std) standard the default value after a change,
(ini) initial the default value never written,
(bsy) busy value which will be valid soon;
A memstates operation-function selected from the list:
(ABA) Action Before Access Occurs before obtaining the address of a location prior to AOR,
(AOA) Action On Access provides at least the address of a location prior to AAA and ABR or ABW,
(AAA) Action After Access side effect of requesting address,
(ABR) Action Before Read Occurs before getting the value of a location prior to AOR,
(AOR) Action On Read provides at least a value for a location prior to AAR,
(AAR) Action After Read side effect of read,
(ABW) Action Before Write Occurs before setting the value of a location prior to AOW,
(AOW) Action On Write intended to update the value for a location prior to AAW,
(AAW) Action After Write side effect of write,
(AOX) Action On eXception Invitation to retry access after failure,
(AOT) Action On TimeOut complete failure of access,
A Miscallaneous operation-function selected from the list:
(SIDE) Serial IDE simple low code modification of standard IDE/ATA to use fewer wires and increase functionality,
(IDES) IDE Serial inverse of SIDE,
(Cache) DRAM Memory Cell of n bits DRAM and 1 bit SRAM which is refreshed under external control (typically JAG)—Disk Access Optimized Repeated Writing to reduce rotational latency; and
A Security operation-function selected from the list:
(TXP) Terminate eXtreme Prejudice Unit designated as harmful, to be destroyed,
(CAP) Cease All Processing Unit must freeze,
(DevCon1) Defence Condition 1 Units must identify and CAP, TXP may follow,
(DevCon2) Defence Condition 2 Units must identify, TXP on Warning,
(DevCon3) Defence Condition 3 Units must identify, CAP on Warning else TXP,
(DevCon4) Defence Condition 4 Units must identify, possible TXP/CAP on recognition,
(DevCOn5) Defence Condition 5 Units must identify, possible CAP on recognition.

12. The program storage device according to claim 11 wherein the device temporarily resides on a carrier signal located on a media selected from the list:
(a) a connective communications topology distributed between a plurality of queues of a distributed dynamically optimizable processing, communications, and storage system;
(b) an interface with a communications topology of an input device;
(c) an interface with a communications topology of an output device; and
(d) a subset of any of the aforesaid.
